(19) United States
(12) Patent Application Publication
(10) Pub. No.: US 2024/0247104 A1
(43) Pub. Date: Jul. 25, 2024

(54) POLYMER COMPOUND, COMPOSITION, ORGANIC FILM, AND ELECTROLUMINESCENT DEVICE COMPRISING POLYMER COMPOUND, AND METHOD OF PREPARING ELECTROLUMINESCENT DEVICE

(71) Applicant: SAMSUNG ELECTRONICS CO., LTD., Suwon-si (KR)

(72) Inventors: Fumiaki KATO, Yokohama (JP); Masashi TSUJI, Hwaseong-si (KR); Norihito ISHII, Yokohama-shi (JP); Takahiro FUJIYAMA, Yokohama (JP); Naotoshi SUGANUMA, Yokohama-shi (JP); Yusaku KONISHI, Yokohama (JP); Ha Il KWON, Suwon-si (KR); Won Sik YOON, Suwon-si (KR)

(21) Appl. No.: 18/530,783

(22) Filed: Dec. 6, 2023

(30) Foreign Application Priority Data
Dec. 7, 2022 (JP) 2022-195703

(51) Int. Cl. C08G 73/02; H10K 50/15; H10K 71/10; H10K 85/10; H10K 85/60

(52) U.S. Cl. CPC C08G 73/02; H10K 50/15; H10K 71/10; H10K 85/111; H10K 85/615; H10K 85/631; H10K 85/6572

(57) ABSTRACT

A polymer compound including a structural unit represented by formula (1), and at least one of structural units represented by formula (2), formula (3), or formula (4), and a composition, an organic membrane, and an electroluminescence device including the polymer compound, and a method or producing the electroluminescence device are provided:

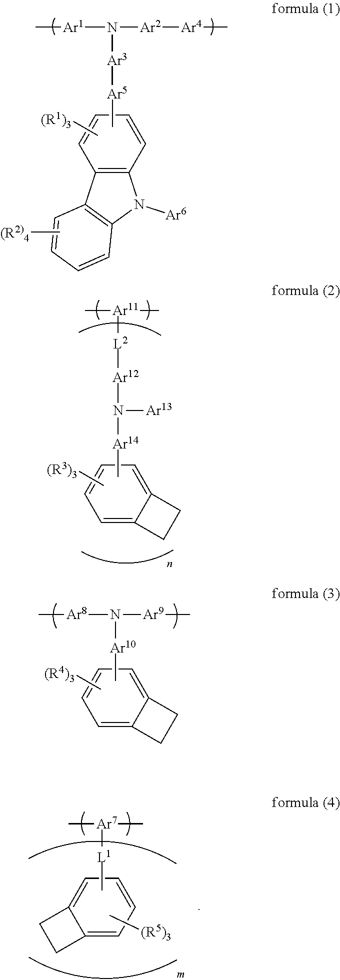

### CROSS-REFERENCE TO RELATED APPLICATION

This application claims priority to Japanese Patent Application No. 2022-195703 filed in the Japanese Patent Office on Dec. 7, 2022, and all the benefits accruing therefrom under 35 U.S.C. § 119, the contents of which are herein incorporated by reference in their entirety.

### BACKGROUND OF THE INVENTION

### 1. Field of the Invention

The present invention relates to a polymer compound, a composition, an organic film, and electroluminescent device comprising the polymer compound, and a method of preparing the electroluminescent device.

### 2. Description of the Related Art

The research and development of electroluminescence devices (EL devices) are ongoing and of current interest. In particular, EL devices show promise as an inexpensive large-area full-color display device of a solid-state light-emitting type or a recording light source array. The EL device may be a light emitting device having a thin film disposed between an anode and a cathode with the thin film having a thickness of several nanometers to several hundred nanometers. In addition, the EL device usually includes a hole transport layer, a light emitting layer, an electron transport layer, and the like.

The light emitting layer may include a fluorescent light emitting material and/or a phosphorescent light emitting material. The phosphorescent light emitting material is a material that may be expected to have higher, for example, about four times higher, luminous efficiency than a fluorescent light emitting material. In addition, because a phosphorescent light emitting material may cover a wide color gamut, an RGB light source typically requires an emission spectrum having a narrow full width at half maximum.

A light emitting device with an inorganic light emitting material may include quantum dots (JP 2010-199067 A). Quantum dots (QD) are semiconductor materials with a nanocrystal structure of several nanometers in size, and therefore, quantum dots have a large surface area per unit volume. For this reason, most of the atoms of the nanocrystal are present at the surface resulting in a quantum confinement effect. Accordingly, one may control or adjust the emission wavelength by adjusting the relative size or the elemental composition of the QDs. QDs may offer EL devices with improved color purity and high PL (photoluminescence) luminous efficiency.

Although a quantum dot electroluminescence device (QD LED, or QLED) with 3 layers, such as, for example, a hole transport layer (HTL), an electron transport layer (ETL), and a quantum dot light-emitting layer disposed between the HTL and ETL, are typical as a basic structure, it is difficult to achieve sufficient durability (for example, luminescence lifespan) or sufficient luminous efficiency in EL devices (for example, quantum dot EL devices).

A need remains for a commercially acceptable quantum dot electroluminescence device, that exhibits improved performance, e.g., lifetime and/or luminous efficiency.

### SUMMARY

According to some embodiments, a polymer compound including a structural unit represented by formula (1), and at least one of structural units represented by formula (2), formula (3), or formula (4) is provided:

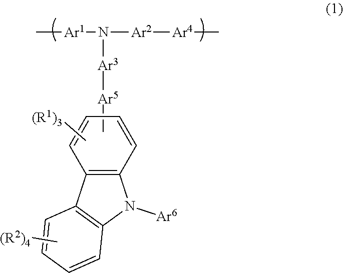

in formula (1) above,
Ar¹ and Ar² are, each independently, a substituted or unsubstituted aromatic hydrocarbon group having 6 to 60 carbon atoms,
Ar³ is a substituted or unsubstituted aromatic hydrocarbon group having 6 to 120 carbon atoms,
Ar⁴ is a substituted or unsubstituted aromatic hydrocarbon group having 6 to 60 carbon atoms, or a substituted or unsubstituted aromatic heterocyclic group having 3 to 60 ring-forming atoms,
Ar⁵ is a single bond or a substituted or unsubstituted aromatic heterocyclic group having 3 to 60 ring-forming atoms,
Ar⁶ is a substituted or unsubstituted aromatic hydrocarbon group having 6 to 60 carbon atoms, or a substituted or unsubstituted aromatic heterocyclic group having 3 to 60 ring-forming atoms,
R¹ is a hydrogen atom, an alkyl group, a hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN), and
R² is a hydrogen atom, an alkyl group, an hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN);

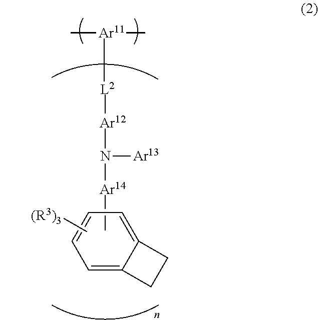

in formula (2) above,
Ar¹¹ is a substituted or unsubstituted aromatic hydrocarbon group having 6 to 60 carbon atoms, or a substituted or unsubstituted aromatic heterocyclic group having 3 to 60 ring-forming atoms,
L² is a single bond or a saturated hydrocarbon group having 2 to 60 carbon atoms,
Ar¹² is a substituted or unsubstituted aromatic hydrocarbon group having 6 to 60 carbon atoms, or a substituted or unsubstituted aromatic heterocyclic group with 3 to 60 ring-forming atoms,
Ar¹³ is a substituted or unsubstituted aromatic hydrocarbon group having 6 to 60 carbon atoms, or a substituted or unsubstituted aromatic heterocyclic group having 3 to 60 ring-forming atoms,
Ar¹⁴ is a single bond, a substituted or unsubstituted aromatic hydrocarbon group having 6 to 60 carbon atoms, or a substituted or unsubstituted aromatic heterocyclic group having 3 to 60 ring-forming atoms,
R³ is a hydrogen atom, an alkyl group, an hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN), wherein R³ can form a ring with another R³ or with a carbon atom in a benzene ring to which R³ is bonded, and
n is 1 or 2;

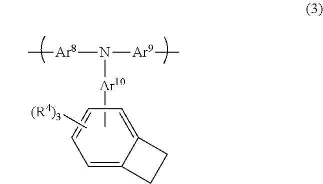

in formula (3) above,
Ar⁸ and Ar⁹ are, each independently, a substituted or unsubstituted aromatic hydrocarbon group having 6 to 60 carbon atoms,
Ar¹⁰ is a single bond, a substituted or unsubstituted aromatic hydrocarbon group having 6 to 60 carbon atoms, or a substituted or unsubstituted aromatic heterocyclic group having 3 to 60 ring-forming atoms, and
R⁴ is a hydrogen atom, an alkyl group, a hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN), wherein R⁴ can form a ring with another R⁴ or with a carbon atom in a benzene ring to which R⁴ is bonded,

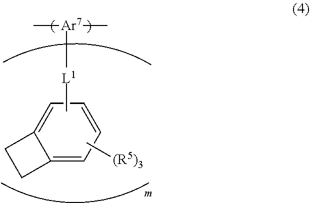

in formula (4) above,
Ar⁷ is a substituted or unsubstituted aromatic hydrocarbon group having 6 to 60 ring atoms, or a substituted or unsubstituted aromatic heterocyclic group having 3 to 60 ring-forming atoms,
L¹ is a single bond or a saturated hydrocarbon group having 2 to 60 carbon atoms,
R⁵ is a hydrogen atom, an alkyl group, a hydroxyalkyl group, an alkoxygroup, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN), wherein R⁵ can form a ring with another R⁵ or with a carbon atom in a benzene ring to which R⁵ is bonded, and
m is 1 or 2.

According to some embodiments, an electroluminescence device, for example, a quantum dot electroluminescence device, having excellent performance, for example, excellent durability (i.e., device lifespan, luminescence lifespan, etc.) is provided.

### BRIEF DESCRIPTION OF THE DRAWINGS

The above and other advantages and features of this disclosure will become more apparent by describing in further detail embodiments thereof with reference to the accompanying drawings, in which:

FIG. 1 is a schematic diagram showing an electroluminescence device according to an exemplary embodiment; and

FIG. 2 is a schematic diagram showing a structure of a blue light-emitting quantum dot having ZnTeSe/ZnSe/ZnS (core/shell/shell) according to an exemplary embodiment.

### DETAILED DESCRIPTION

An electroluminescence device (e.g., quantum dot electroluminescence device) including a hole transport material described in JP 2010-199067 A is understood by those in the art to have insufficient or non-acceptable performance (e.g., poor lifetime). An electroluminescence device using polymer compound (A) described in JP 2014-1349 A as a hole transport material could not achieve sufficient durability (device lifespan).

Alternative hole transport materials are needed, particularly, for an EL device that includes quantum dots. Accordingly, the present invention may provide an EL device, for example, a quantum dot electroluminescence device, that exhibits improved performance, e.g., lifetime and/or luminous efficiency.

As disclosed herein, the above problems can be solved by using a polymer compound that includes a specific structural unit.

Reference will now be made in detail to embodiments, embodiments of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

According to some embodiments, a polymer compound including a structural unit represented by formula (1), and at least one of structural units represented by formula (2), formula (3), or formula (4) is provided:

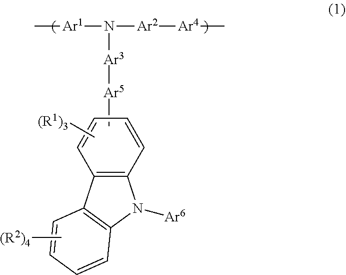

in formula (1) above,
Ar¹ and Ar² are, each independently, a substituted or unsubstituted aromatic hydrocarbon group having 6 to 60 carbon atoms,
Ar³ is a substituted or unsubstituted aromatic hydrocarbon group having 6 to 120 carbon atoms,
Ar⁴ is a substituted or unsubstituted aromatic hydrocarbon group having 6 to 60 carbon atoms, or a substituted or unsubstituted aromatic heterocyclic group having 3 to 60 ring-forming atoms,
Ar⁵ is a single bond or a substituted or unsubstituted aromatic heterocyclic group having 3 to 60 ring-forming atoms,
Ar⁶ is a substituted or unsubstituted aromatic hydrocarbon group having 6 to 60 carbon atoms, or a substituted or unsubstituted aromatic heterocyclic group having 3 to 60 ring-forming atoms,
R¹ is a hydrogen atom, an alkyl group, a hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN), and
R² is a hydrogen atom, an alkyl group, an hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN);

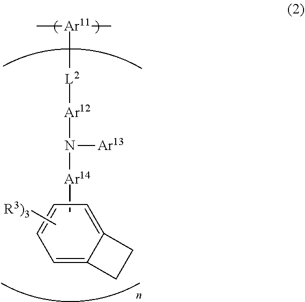

in formula (2) above,
Ar¹¹ is a substituted or unsubstituted aromatic hydrocarbon group having 6 to 60 carbon atoms, or a substituted or unsubstituted aromatic heterocyclic group having 3 to 60 ring-forming atoms,
L² is a single bond or a saturated hydrocarbon group having 2 to 60 carbon atoms,
Ar¹² is a substituted or unsubstituted aromatic hydrocarbon group having 6 to 60 carbon atoms, or a substituted or unsubstituted aromatic heterocyclic group with 3 to 60 ring-forming atoms,
Ar¹³ is a substituted or unsubstituted aromatic hydrocarbon group having 6 to 60 carbon atoms, or a substituted or unsubstituted aromatic heterocyclic group having 3 to 60 ring-forming atoms,
Ar¹⁴ is a single bond, a substituted or unsubstituted aromatic hydrocarbon group having 6 to 60 carbon atoms, or a substituted or unsubstituted aromatic heterocyclic group having 3 to 60 ring-forming atoms,
R³ is a hydrogen atom, an alkyl group, an hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN), wherein R³ can form a ring with another R³ or with a carbon atom in a benzene ring to which R³ is bonded, and
n is 1 or 2;

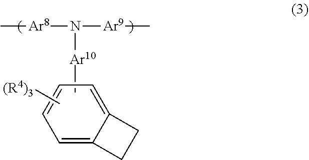

in formula (3) above,
Ar⁸ and Ar⁹ are, each independently, a substituted or unsubstituted aromatic hydrocarbon group having 6 to 60 carbon atoms,
Ar¹⁰ is a single bond, a substituted or unsubstituted aromatic hydrocarbon group having 6 to 60 carbon atoms, or a substituted or unsubstituted aromatic heterocyclic group having 3 to 60 ring-forming atoms, and
R⁴ is a hydrogen atom, an alkyl group, a hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN), wherein R⁴ can form a ring with another R⁴ or with a carbon atom in a benzene ring to which R⁴ is bonded;

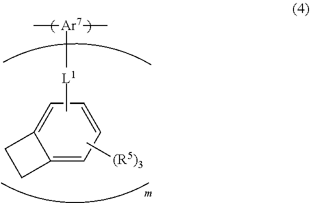

in formula (4) above,
Ar⁷ is a substituted or unsubstituted aromatic hydrocarbon group having 6 to 60 ring atoms, or a substituted or unsubstituted aromatic heterocyclic group having 3 to 60 ring-forming atoms,
L¹ is a single bond or a saturated hydrocarbon group having 2 to 60 carbon atoms,
R⁵ is a hydrogen atom, an alkyl group, a hydroxyalkyl group, an alkoxygroup, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN), wherein R⁵ can form a ring with another R⁵ or with a carbon atom in a benzene ring to which R⁵ is bonded, and
m is 1 or 2.

In the specification herein, a structural unit including the structural unit indicated by formula (1) may simply be referred to as “structure unit” or “structure unit A according to some embodiments”.

Similarly, a structural unit including the structural unit represented by formulas (2) to (4) may simply be referred to as “structural unit B” or “structural unit B according to some embodiments”, “structure unit C” or “structural unit C according to some embodiments”, or “structure unit D” or “structural unit D according to some embodiments”.

Also, the polymer compound that includes structural unit A, and at least one of structural units B to D may simply be referred to as “a polymer compound” or “a polymer compound according to some embodiments”.

According to some embodiments, a composition comprising the polymer compound according to some embodiments and one or more materials selected from hole transport material, electron transport material, and light-emitting material is provided.

According to some embodiments, an organic film containing the polymer compound according to some embodiments is provided.

According to some embodiments, an electroluminescence device comprising a first electrode, a second electrode, and an organic film comprising one or more layers and disposed between the first electrode and the second electrode is provided, wherein at least one of the one or more layers of the organic film includes the polymer compound according to some embodiments.

In some embodiments, the electroluminescence device may also simply be referred to as “LED”.

Quantum dot electroluminescence device may also simply be referred to as “QLED”.

Organic electroluminescence device may also simply be referred to as “OLED”.

According to some embodiments, a method for manufacturing an electroluminescence device that includes a first electrode, a second electrode, and an organic film comprising one or more layers and disposed between the first electrode and the second electrode, wherein at least one of the one or more layers of the organic film includes a polymer compound according to some embodiments is provided, wherein the method for manufacturing an electroluminescence device may include forming the at least one of the one or more layers of the organic film that includes a polymer compound according to some embodiments by applying a liquid composition containing a polymer compound according to some embodiments and a solvent to a layer adjacent to the at least one of the one or more layers of the organic film, and removing the solvent.

The polymer compound according to some embodiments includes structural unit A including a structural unit represented by formula (1), and at least one of structural unit B including a structural unit represented by formula (2), structural unit C including a structural unit represented by formula (3), or structural unit D including a structural unit represented by formula (4). Here, structural unit A may provide hole transport properties to a membrane. In other words, structural unit A may be a holetransporting structural unit.

Also, structural units (B) to structural units (D) may include a crosslinkable group, such as, for example, a group derived from bicyclo[4.2.0]octa-1,3,5-triene, a group derived from 1,2-dihydrocyclobuta[a]naphthalene, a group derived from 1,2-dihydrocyclobuta[b]naphthalene, and the like. That is, structural units (B) to (D) may be crosslinkable structural units.

By including such cross-linkable group, the polymer compound according to some embodiments may include a cross-linked structure. Accordingly, an organic film containing a polymer compound according to some embodiments, for example, hole transport layer or hole injection layer may have increased solvent-resistance, for example, resistance to xylene, cyclohexyl benzene, and the like.

In addition, in the polymer compound according to some embodiments, the hole-transporting structural unit (A) represented by formula (1), and at least one of the crosslinkable structural units represented by one or more of formulas (2) to (4) may be apart from each other. As a result, the crosslinkable site (reaction point) may not inhibit hole transport property, and the hole transport property does not deteriorate even after the crosslinking.

Therefore, an electroluminescence device formed by including the polymer compound according to some embodiments, for example, in a hole transport layer or a hole injection layer, may have increased durability, such as, for example, increased device lifespan, increased luminescence life, etc.

Manufacturing by using solution coating process, such as, for example, using inkjet printing, may be expected to reduce costs. In order to be applied to solution coating process, resistance to solvent is required when applying a layer containing a compound, for example, an upper layer of hole transport layer, and a material that can achieve both resistance to solvent and durability needs to be developed.

The polymer compound according to some embodiments includes at least one of structural units (B) to (D), whereby resistance to solvent, such as, for example, xylene, cyclohexyl benzene, etc. may increase. Due to this, by using the polymer compound according to some embodiments, when a layer is formed by a wet process, for example, a solution application method, for example, an inkjet method, etc., on a layer containing the polymer compound, membrane mixing between the two layers may be suppressed. Therefore, an electroluminescence device formed by forming an organic layer, for example, a hole transport layer or a hole injection layer, by using a solution application method, such as, for example, an inkjet printing method, using a polymer compound according to some embodiments, may exhibit excellent durability.

A ratio of intensity of the reference wavelength of the absorption spectrum after immersion in solvent with respect to intensity of the reference wavelength of the absorption spectrum before immersion in solvent, i.e., (“intensity of the reference wavelength of the absorption spectrum after immersion in solvent”/“intensity of the reference wavelength of the absorption spectrum before immersion in solvent”)×100(%) is defined as the solvent resistance value (%), and the “solvent resistance” may be evaluated from the value.

A method for determining the reference wavelength and a method for evaluating the solvent resistance value are described in detail in the examples.

The solvent resistance value of the polymer compound according to some embodiments is not particularly limited, but may be 75% or more, or for example, 90% or more, up to 100%.

Examples of some embodiments will be described below. Meanwhile, the present invention is not limited to the examples, but may be modified in various ways within the scope of this disclosure. An example embodiment may change to another example embodiment by any combinations of the embodiments.

Also, each drawing may be exaggerated for convenience of explanation and dimensions in each drawing may have a different ratio from the actual one. When referring to the drawing, like elements are given the same reference numerals in the description of the drawings, and overlapping descriptions may be omitted.

In the context of the specification, unless otherwise defined, terms may be understood in the sense commonly used in the field. Accordingly, unless otherwise defined, all technical terms and technologies used in the terms should be understood as having the same meaning as generally understood by those skilled in the art to which the present invention pertains. In case of conflict, the specification (including definitions) shall control.

In the specification of the present application, unless otherwise specified, operations and measurements of physical properties are performed at room temperature (20° C. or more, and 25° C. or less), measured under relative humidity conditions of 40% RH or more and 50% RH or less.

### Polymer Compound

In some embodiment, the polymer compound includes structural unit (A) containing the structural unit represented by formula (1), and at least one of structural unit (B) containing the structural unit represented by formula (2), structural unit (C) containing the structural represented by formula (3), and structural unit (D) containing the structural unit represented by formula (4). In this case, structural units (B) to structural units (D), each independently, may include one type of the structural unit or two or more types. In addition, the polymer compound according to some embodiments may include, in addition to structural unit (A), at least two or more of the structural unit (B), structural unit (C), and structural unit (D). For example, a polymer compound according to some embodiments may include structural unit (A), and a structural unit selected from structural unit (B), structural unit (C), and structural unit (D). For example, the polymer compound according to some embodiments may include structural unit (A) and one structural unit selected from structural unit (B), structural unit (C), and structural unit (D). In this case, the structural units (B) to (D) that exist in combination with structural unit (A), each independently include one type of structural unit, or two or more types. When two or more types of each structural unit exist in combination, each structural unit may be a block (block copolymer), in random (random copolymer), or alternately arranged (alternating copolymer).

### Structural Unit (A)

The polymer compound according to some embodiment includes structural unit (A) containing the structural unit represented by formula (1). The polymer compound containing structural unit (A) may have high hole injection properties into quantum dots, and excellent durability, for example, excellent emission lifetime. In addition, high current efficiency and low driving voltage may be achieved.

The polymer compound according to some embodiments may include one type of structural unit (A), or two or more types. As structural unit (A), the structural unit (A) described in JP2021-138915A can be used, and the above publication are hereby incorporated by reference in its entirety.

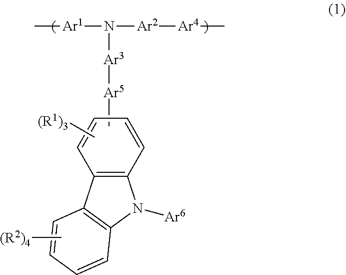

In formula (1) above,
Ar¹ and Ar² may, each independently, be a substituted or an unsubstituted aromatic hydrocarbon group having 6 to 60 carbon atoms. Here, Ar¹ and Ar² may be the same as, or may be different from each other. In one embodiment, Ar¹ and Ar² may be the same as each other.

Aromatic hydrocarbon group is not particularly limited as long as it is an aromatic hydrocarbon group with a number of carbon atoms (ring-forming carbon atoms) of 6 to 60.

Specific examples of unsubstituted Ar¹ and Ar² may include divalent groups derived from aromatic hydrocarbons, such as, for example, benzene, pentalene, indene, naphthalene, anthracene, azulene, heptalene, acenaphthene, phenalene, fluorene, phenanthrene, biphenyl, terphenyl, quarter phenyl, quinquephenyl, sexiphenyl, pyrene, 9,9-diphenyl fluorene, 9,9′-spirobi[fluorene], 9,9-dialkylfluorene, indeno[1,2-b]fluorene, and the like.

Meanwhile, the above examples are for the unsubstituted Ar¹ and Ar², and thus, for example, when one substituent is substituted, Ar¹ and Ar² may, each independently, become a trivalent group.

Among these, Ar¹ and Ar² may, for example, be a group derived from a compound selected from benzene, fluorene, biphenyl, terphenyl, indeno[1,2-b]fluorene, or combination thereof. In one embodiment, Ar¹ and Ar² may, for example, be a group derived from a compound selected from benzene, fluorene, biphenyl and indeno[1,2-b]fluorene, or a combination thereof.

In the above example, Ar¹ and Ar² may, for example, be unsubstituted, or any one hydrogen atom may be substituted with a substituent. For example, Ar¹ and Ar² may, for example, be an unsubstituted phenylene group, m-phenylene group (unsubstituted form), p-phenylene group (unsubstituted form), and the like, or for example, a p-phenylene group (unsubstituted form).

By having these Ar¹ and Ar², higher durability, higher hole injection, and higher triplet energy level, and at least one of lower driving voltage and film forming properties, or balances of two or more thereof, for example, higher durability, may be achieved.

Here, when a hydrogen atom of either Ar¹ or Ar² is substituted, the number of substituent introduced is not particularly limited, but may be, for example, 1 or more and 3 or less, for example, 1 or more and 2 or less, or may be, for example, 1.

In one embodiment, Ar¹ and Ar² may be unsubstituted.

In another embodiment, Ar¹ or Ar² may have one substituent.

When Ar¹ or Ar² possesses a substituent, the bonding position of the substituent is not particularly limited.

The substituent may, for example, be present as far as possible from the nitrogen atom of the main chain to which Ar¹ or Ar² is connected. For example, when Ar¹ or Ar² is a p-phenylene group, the substituent may be present in the meta position with respect to the linking point linked to nitrogen atom in the main chain. By having a substituent in this position, higher durability, higher hole injectability, higher triplet energy level, and at least one of lower driving voltage and film forming properties, or any two or more balances thereof, for example, a balance between hole injection properties and film forming properties may be achieved.

In addition, when Ar¹ or Ar² possesses a substituent, the substituent that may be present is not particularly limited and includes, for example, an alkyl group, cycloalkyl group, hydroxy alkyl group, alkoxyalkyl group, alkoxy group, cycloalkoxy group, alkenyl group, alkynyl group, amino group, aryl group, aryloxy group, alkylthio group, cycloalkylthio group, arylthio group, alkoxy carbonyl group, aryloxycarbonyl group, hydroxyl group (—OH), carboxyl group (—COOH), a thiol group (—SH), cyano group (—CN), and the like.

When two or more than hydrogen atoms are substituted, the types of substituents may be the same or different.

On the other hand, the substituent cannot be the same as the group being substituted. For example, an alkyl group is not substituted with an alkyl group.

Here, the alkyl group may be either straight-chain or branched, but for example, it may be a straight-chain alkyl group with 1 to 18 carbon atoms or a branched alkyl group with 3 to 18 carbon atoms.

For example, methyl group, ethyl group, n-propyl group, isopropyl group, n-butyl group, isobutyl group, sec-butyl group, tert-butyl group, n-pentyl group, isopentyl group, tert-pentyl group, neopentyl group, 1,2-dimethyl propyl group, n-hexyl group, isohexyl group, 1,3-dimethylbutyl group, 1-isopropyl propyl group, 1,2-dimethylbutyl group, n-heptyl group, 1,4-dimethyl pentyl group, 3-ethyl pentyl group, 2-methyl-1-isopropyl propyl group, 1-ethyl-3-methyl butyl group, n-octyl group, 2-ethylhexyl group, 3-Methyl-1-isopropyl butyl group, 2-methyl-1-isopropyl butyl group, 1-tert-butyl-2-methyl propyl group, n-nonyl group, 3,5,5-trimethylhexyl group, n-decyl group, isodecyl group, n-undecyl group, 1-methyldecyl group, n-dodecyl group, n-tridecyl group, n-tetradecyl group, n-pentadecyl group, n-hexadecyl group, n-heptadecyl group, and n-octadecyl group may be included, and it is not limited thereto.

Examples of cycloalkyl groups may include cyclopropyl group, cyclobutyl group, cyclopentyl group, cyclohexyl group, and the like.

Hydroxyalkyl groups may include, for example, the alkyl groups substituted with one or more and 3 or less, For example, 1 or more and 2 or less, for example, one hydroxyl group, for example, hydroxymethyl group, hydroxyethyl group, etc.

Alkoxyalkyl groups may include, for example, the alkyl groups substituted with 1 or more and 3 or less, for example, more than 1 and less than or equal to 2, or, for example, with one of the following alkoxy group.

Examples of alkoxy group may include methoxy group, ethoxy group, propoxy group, isopropoxy group, butoxy group, pentyloxy group, hexyloxy group, heptyloxy group, octyloxy group, nonyloxy group, decyl oxy group, undecyl oxy group, dodecyl oxy group, tridecyl oxy group, tetradecyl oxy group, pentadecyl oxy group, hexadecyl oxy group, heptadecyl oxy group, octadecyl oxy group, 2-ethylhexyloxy group, 3-ethylpentyloxy group, and the like, and it is not limited thereto.

Examples of cycloalkoxy group may include cyclopropyl oxy group, cyclobutyl oxy group, cyclopentyl oxy group, cyclohexyl oxy group, and the like, and it is not limited thereto.

Examples of alkenyl group may include, for example, vinyl group, allyl group, 1-propenyl group, isopropenyl group, 1-butenyl group, 2-butenyl group, 3-butenyl group, 1-pentenyl group, 2-pentenyl group, 3-pentenyl group, 1-hexenyl group, 2-hexenyl group, 3-hexenyl group, 1-heptenyl group, 2-heptenyl group, 5-heptenyl group, 1-octenyl group, 3-octenyl group, 5-octenyl group, and the like, and it is not limited thereto.

Examples of alkynyl group may include, for example, acetylenyl group, 1-propynyl group, 2-propynyl group, 1-butynyl group, 2-butynyl group, 3-butynyl group, 1-pentethyl group, 2-pentethyl group, 3-pentethyl group, 1-hexynyl group, 2-hexynyl group, 3-hexynyl group, 1-heptynyl group, 2-heptynyl group, 5-heptynyl group, 1-octynyl group, 3-octinnyl group, 5-octinnyl group, and the like, and it is not limited thereto.

Examples of aryl group may include, for example, phenyl group, naphthyl group, biphenyl group, fluorenyl group, anthryl group, pyrenyl group, azrenyl group, acenaphthylenyl group, terphenyl group, phenanthryl, and the like, and it is not limited thereto.

Examples of aryloxy group may include, for example, phenoxy group and naphthyloxy group, and it is not limited thereto.

Examples of alkylthio group may include, for example, methylthio group, ethylthio group, propylthio group, pentylthio group, hexylthio group, octylthio group, dodecylthio group, and the like, and it is not limited thereto.

Examples of cycloalkylthio group may include, for example, cyclopentyl thio group, cyclohexyl thio group, and the like, and is not limited thereto.

Examples of arylthio group may include, for example, phenylthio group and naphthylthio group, and it is not limited thereto.

Examples of alkoxy carbonyl group may include, for example, methyloxy carbonyl group, ethyl oxycarbonyl group, butyl oxycarbonyl group, octyl oxycarbonyl group, dodecyl oxycarbonyl group, and the like, and it is not limited thereto.

Examples of aryloxycarbonyl group may include, for example, phenyloxycarbonyl group and naphthyloxycarbonyl group, and it is not limited thereto.

Among these, a hydrogen atom of either Ar¹ or Ar² is substituted, the substituent that may be introduced may be a straight-chain or branched alkyl group having 1 to 8 carbon atoms, for example, a straight-chain or branched alkyl group having 1 to 3 carbon atoms, or for example, it may be a methyl group.

Among those described above, Ar¹ and Ar² may, each independently, be a group selected from the group (II′) below.

In group (II′), R^{211′} to R^{232′} may, each independently, be a hydrogen atom, or a straight-chain or branched hydrocarbon group having 1 to 18 carbon atoms, for example, R^{211′} to R^{232′} may, each independently, be a hydrogen atom or a methyl group.

Additionally, * indicates bonding position with an adjacent atom.

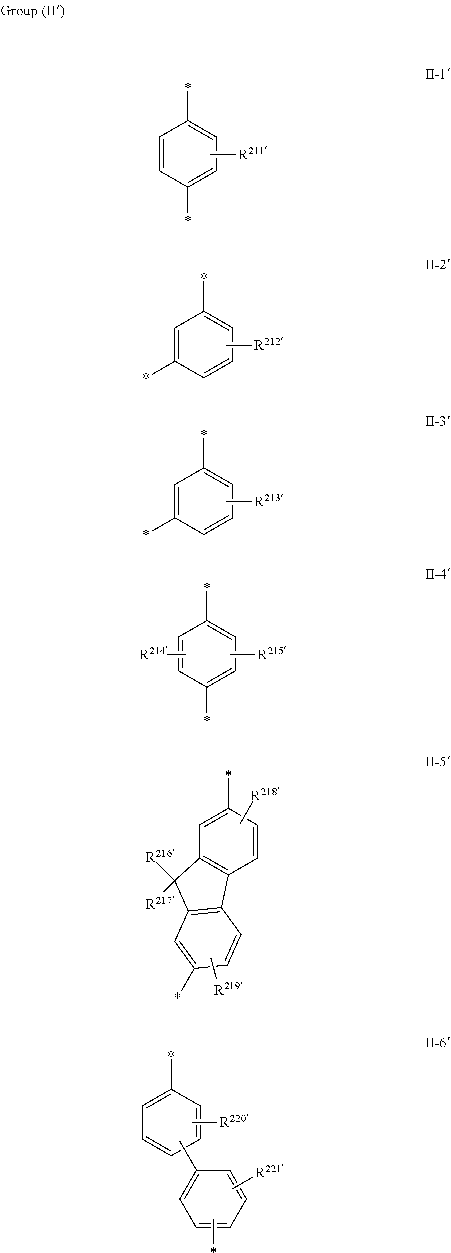

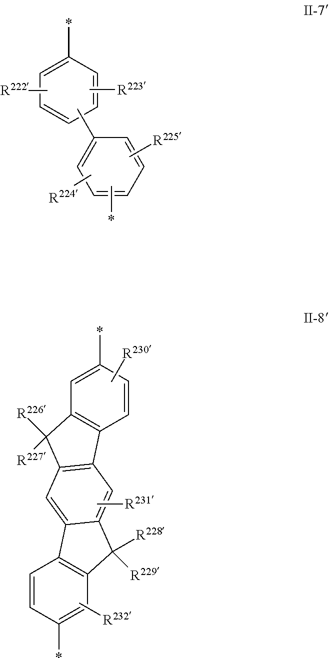

In formula (1), Ar³ may be a substituted or unsubstituted aromatic hydrocarbon group having 6 to 120 carbon atoms, for example, a substituted or unsubstituted aromatic hydrocarbon group having 6 to 60 carbon atoms.

Here, the aromatic hydrocarbon group is defined the same as for Ar¹ and Ar².

Among these, Ar³ may be a group derived from a compound, for example, benzene, fluorene, biphenyl, indeno[1,2-b]fluorene, or a combination thereof. For example, Ar³ may be a group derived from a compound selected from benzene, fluorene, and biphenyl.

Meanwhile, in the above examples, Ar³ may be unsubstituted, or any hydrogen atom of Ar³ may be substituted with a substituent.

Ar³ may be a phenylene group (unsubstituted form), for example, an m-phenylene group, a p-phenylene group (unsubstituted form), for example, a p-phenylene group (may be in an unsubstituted form).

By having the above Ar³, higher durability, higher hole injection, higher triplet energy level, and at least one or more of lower driving voltage and film forming properties, or a balance of any two or more thereof, for example, higher durability may be achieved.

Here, when any one hydrogen atom of Ar³ is substituted, the number of substitution is not particularly limited, but may be, for example, 1 or more and 3 or less, for example, 1 or more and 2 or less, or, for example, 1.

In one embodiment, Ar³ is unsubstituted.

In another embodiment, Ar³ has one substituent.

When Ar³ has a substituent, the bonding position of the substituent is not particularly limited.

The substituent may be present as far as possible from the nitrogen atom of the main chain to which Ar³ is connected.

For example, if Ar³ is a p-phenylene group, the substituent is in meta position with respect to the bonding hand connected to the nitrogen atom of the main chain. By having a substitution in this position, higher durability, higher hole injection, higher triplet energy level, and at least one of lower driving voltage and film forming properties, or any two or more balances thereof, for example, a balance between hole injection properties and film forming properties may be achieved.

Additionally, when Ar³ has a substituent, the substituent that may be present is not particularly limited, and examples of the substituent groups defined in Ar¹ and Ar² may be included.

Among those described above, Ar³ may be a divalent substituent selected from the following group. That is, in one embodiment, Ar³ in formula (1) may be a group selected from group (I) below.

Meanwhile, in group (I) below, R¹¹¹ to R¹³⁰ may, each independently, be a hydrogen atom, or a straight-chain or branched hydrocarbon group having 1 to 18 carbon atoms, for example, R¹¹¹ to R¹³⁰ may, each independently, be a hydrogen atom or a methyl group.

Additionally, * indicates a bonding position with an adjacent atom.

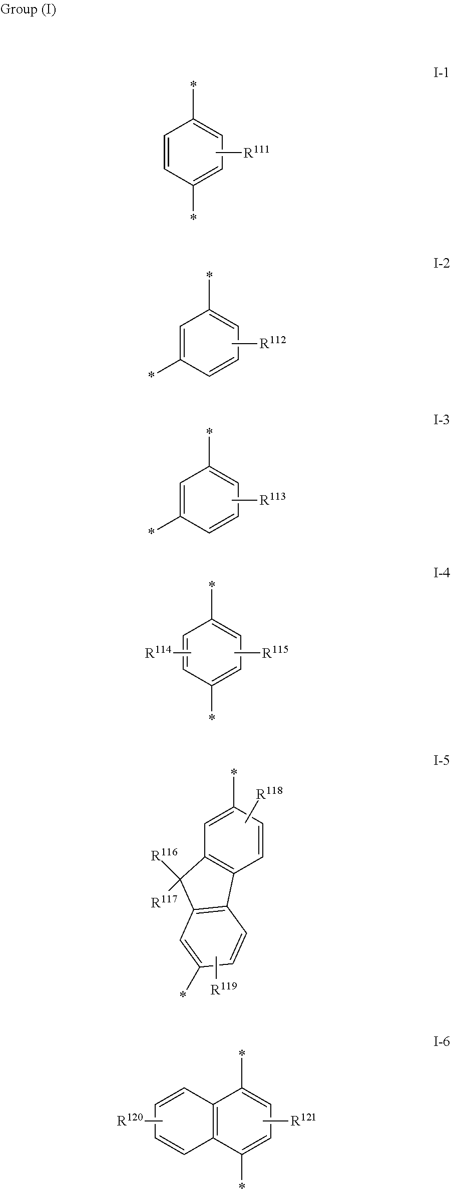

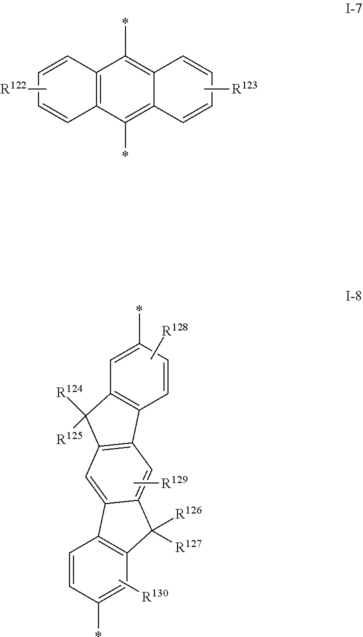

In the above formula (1), Ar⁴ may be a substituted or unsubstituted aromatic hydrocarbon group having 6 to 60 carbon atoms, or a substituted or unsubstituted aromatic heterocyclic group having 3 to 60 ring-forming atoms.

Here, the aromatic hydrocarbon group is the same as those defined in Ar¹ or Ar².

Additionally, the aromatic heterocyclic group is not particularly limited.

Examples of Ar⁴, which is not substituted, may include a divalent group derived from an aromatic heterocyclic compound, for example, acridine, phenazine, benzoquinoline, benzoisoquinoline, phenanthridine, phenanthroline, anthraquinone, fluorenone, dibenzofuran, dibenzothiophene, carbazole, imidazophenanthridine, benzimidazophenanthridine, azadibenzofuran, 9-phenylcarbazole, azacarbazole, azadibenzothiophene, diazia dibenzofuran, diazacarbazole, heterocyclic cyclic aromatic compounds such as dibenzothiophene, xanthone, thioxanthone, pyridine, quinoline, anthraquinoline, and the like, and is not limited thereto.

The above examples are when Ar⁴ is in an unsubstituted form. For example, when it is monosubstituted, Ar⁴ may become a trivalent group.

In the present specification, the number of “ring-forming atom” refers to number of atoms that form a ring itself, in which the atoms are bonded each other to form a ring, such as, for example, a monocyclic ring, a condensed ring, a ring assembly crosslinked, carbocyclic ring, heterocyclic ring, and the like. Atoms that do not make up the ring, such as, for example, hydrogen atoms that terminate the bond of the atoms that make up the ring, or a substituent-based atom when a ring is substituted, are not included in the number of the ring-forming atoms.

The number of ring-forming atoms described below is the same unless otherwise specified. For example, a benzene ring has 6 ring-forming atoms, a naphthalene ring has 10 ring-forming atoms, a pyridine ring has 6 ring-forming atoms, and a furan ring has 5 ring-forming atoms.

When a benzene ring is substituted with an alkyl group, the number of carbon atoms of the alkyl group is not included in the number of ring-forming atoms of the benzene ring. Therefore, the number of ring atoms of the benzene ring substituted by an alkyl group is 6.

In addition, when a naphthalene ring is substituted by, for example, an alkyl group as a substituent, the number of atoms of the alkyl group is not included in the number of ring-forming atoms of the naphthalene ring. For this reason, the number of ring-forming atoms of the naphthalene ring substituted by an alkyl group is 10.

For example, the hydrogen atoms bonded to a pyridine ring or the number of atoms constituting a substituent is not included in the number of ring-forming atoms of the pyridine ring. For this reason, the number of ring-forming atoms of the pyridine ring to which the hydrogen atoms or a substituent is bonded is 6.

Among these, Ar⁴ may, for example, be a group derived from a compound selected from benzene, fluorene, biphenyl, indeno[1,2-b]fluorene, dibenzofuran, dibenzothiophene, or a combination thereof.

In the examples above, Ar⁴ may be unsubstituted, or any hydrogen atom of Ar⁴ may be substituted with a substituent. For example, Ar⁴ may be a substituted or unsubstituted group derived from benzene, fluorene, biphenyl, indeno[1,2-b] fluorene, or a combination thereof.

In one embodiment, Ar⁴ may be selected from group (II′) below.

Additionally, in another embodiment, Ar¹, Ar², and Ar⁴, may each independently be selected from the group (II′) below.

In group (II′) below, R^{211′} to R^{232′} may, each independently, be a hydrogen atom, or a straight-chain or branched hydrocarbon group having 1 to 18 carbon atoms.

For example, R^{211′} to R^{215′}, R^{218′} to R^{225′}, and R^{230′} to R^{232′} may, each independently, be a hydrogen atom or a methyl group, For example, R^{211′} to R^{215′} R^{218′} to R^{225′}, and R^{230′} to R^{232′} may, each independently, be a hydrogen atom.

R^{216′} to R^{217′}, and R^{226′} to R^{229′} may, each independently, be an alkyl group having 5 to 60 carbon atoms, for example, a straight-chain or branched alkyl group having 8 to 30 carbon atoms, or a straight-chain alkyl group having 9 to 18 carbon atoms, or, for example, a straight-chain alkyl group having 10 to 12 carbon atoms, and it is not limited thereto.

Additionally, * indicates a bonding position with an adjacent atom.

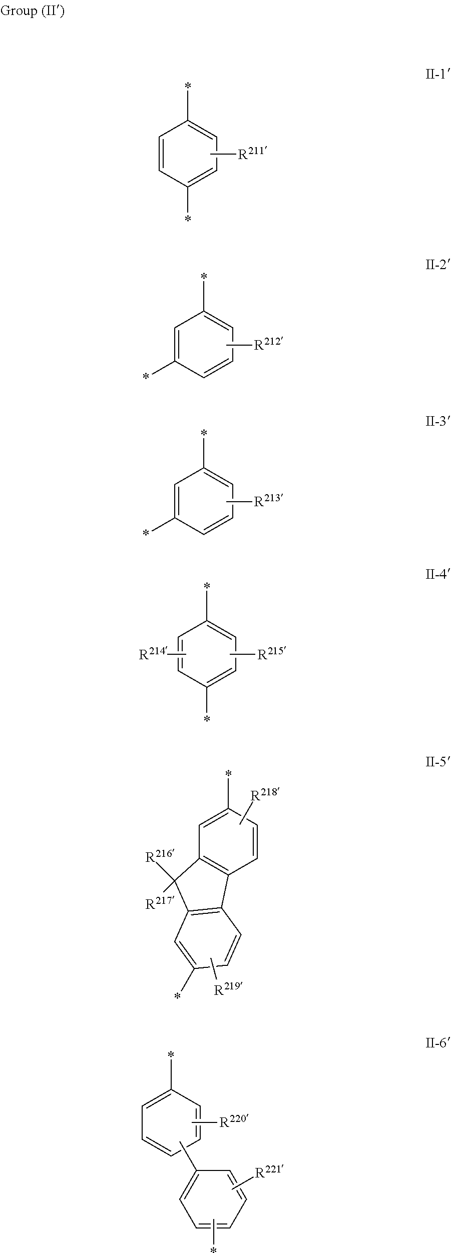

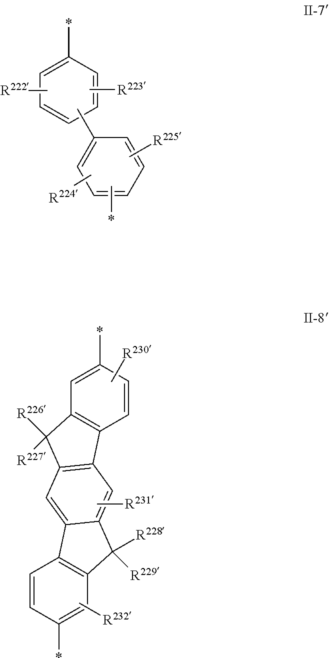

For example, Ar⁴ may be a group derived from a substituted or unsubstituted fluorene (fluorenylene group), or a substituted or unsubstituted indeno[1,2-b]fluorene (indeno[1,2-b]fluorenylene group). Further, for example, Ar⁴ may be a group derived from a substituted fluorene (fluorenylene group), or derived from a substituted indeno[1,2-b]fluorene (indeno [1,2-b]fluorenylene group). For example, Ar⁴ may be a group derived from a fluorene (a fluorenyl group) or indeno[1,2-b]fluorene (indeno[1,2-b]fluorenylene group) substituted with a straight-chain or branched alkyl group of 8 to 30 carbon atoms (or a straight-chain alkyl group of 9 to 18 carbon atoms, or a straight-chain alkyl group of 10 to 12 carbon atoms).

By including the above Ar⁴, higher durability, higher hole injection, and higher triplet energy level, and at least one of lower driving voltage or film forming properties, or any two or more balances thereof, for example, higher durability may be achieved.

In one embodiment, Ar⁴ may be a substituted or unsubstituted fluorenylene group (group derived from fluorene) containing the below structure:

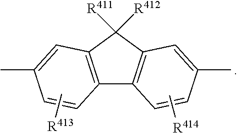

In another embodiment, Ar⁴ may be a group derived from a substituted or unsubstituted indeno[1,2-b]fluorene (indeno[1,2-b]fluorenylene group) containing the structure below:

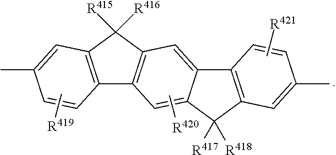

In the above structures, R⁴¹¹ and R⁴¹², and R⁴¹⁵ to R⁴¹⁸ may, each independently, be a hydrogen atom, or a hydrocarbon group of 1 to 30 atoms, and at least one of R⁴¹¹ and R⁴¹², and at least one of R⁴¹⁵ to R⁴¹⁸ may, each independently, be a straight-chain or branched alkyl group having 8 to 30 carbon atoms (or a straight-chain alkyl group having 9 to 18 carbon atoms, or a straight-chain alkyl group having 10 to 12 carbon atoms).

Here, R⁴¹¹ and R⁴¹² may be the same as or different from each other.

For example, R⁴¹¹ and R⁴¹² may be identical to each other.

Likewise, R⁴¹⁵ to R⁴¹⁸ may be the same as or different from each other.

For example, R⁴¹⁵ to R⁴¹⁸ may be identical to each other.

Additionally, R⁴¹³ and R⁴¹⁴, and R⁴¹⁹ to R⁴²¹ may, each independently, be a hydrogen atom, or a hydrocarbon group having 1 to 30 carbon atoms.

Here, R⁴¹³ and R⁴¹⁴ may be the same as or different from each other.

For example, R⁴¹³ and R⁴¹⁴ may be identical to each other.

Likewise, R⁴¹⁹ to R⁴²¹ may be the same as, or different from each other.

For example, R⁴¹⁹ to R⁴²¹ may be identical to each other.

R⁴¹³ and R⁴¹⁴, and R⁴¹⁹ to R⁴²¹ may, for example, be a hydrogen atom.

Hydrocarbon groups having 1 to 30 carbon atoms of R⁴¹¹ and R⁴¹², or of R⁴¹⁵ to R⁴¹⁸ are not particularly limited, but may include, for example, straight-chain or branched alkyl groups, alkenyl groups, alkynyl groups, and cycloalkyl groups. etc.

Meanwhile, when R⁴¹¹ and R⁴¹², or R⁴¹⁵ to R⁴¹⁸ are an alkenyl group or an alkynyl group, the number of carbon atoms of R⁴¹¹ and R⁴¹², and R⁴¹⁵ to R⁴¹⁸, may be 2 or more and 30 or less.

Similarly, when R⁴¹¹ and R⁴¹², or R⁴¹⁵ to R⁴¹⁸ are cycloalkyl groups, the number of carbon atoms of R⁴¹¹ and R⁴¹², and R⁴¹⁵ to R⁴¹⁸ may be 3 to 30.

Examples of alkyl group having 1 to 30 carbon atoms may include, for example, methyl group, ethyl group, n-propyl group, isopropyl group, n-butyl group, isobutyl group, sec-butyl group, tert-butyl group, n-Pentyl group, isopentyl group, tert-pentyl group, neopentyl group, 1,2-dimethyl propyl group, n-hexyl group, isohexyl group, 1,3-dimethylbutyl group, 1-isopropyl propyl group, 1, 2-dimethylbutyl group, n-heptyl group, 1,4-dimethyl pentyl group, 3-ethyl pentyl group, 2-methyl-1-isopropyl propyl group, 1-ethyl-3-methyl butyl group, n-octyl group, 2-ethylhexyl group, 3-methyl-1-isopropyl butyl group, 2-methyl-1-isopropyl butyl group, 1-tert-butyl-2-methyl propyl group, n-nonyl group, 3,5,5-trimethylhexyl group, n-decyl group, isodecyl group, n-undecyl group, 1-methyldecyl group, n-dodecyl group, n-tridecyl group, n-tetradecyl group, n-pentadecyl group, n-hexadecyl group, and the like, and it is not limited thereto.

Examples of alkenyl group having 2 to 30 carbon atoms may include, for example, vinyl group, allyl group, 1-propenyl group, 2-butenyl group, 1,3-butadienyl group, 2-pentenyl group, iso-propenyl group, and the like, and it is not limited thereto.

Examples of alkynyl group having 2 to 30 carbon atoms may include, for example, ethynyl group, propargyl group, and the like, and it is not limited thereto.

Examples of cycloalkyl group having 3 to 30 carbon atoms may include, for example, cyclopropyl group, cyclobutyl group, cyclopentyl group, cyclohexyl group, and the like, and it is not limited thereto.

Among these, in a view point of higher durability, higher hole injection, higher triplet energy level, and at least one of lower driving voltage and film forming ability, or any 2 or more balances thereof, R⁴¹¹ and R⁴¹², and R⁴¹⁵ to R⁴¹⁸ may, each independently, be a straight-chain or branched alkyl group having 8 to 30 carbon atoms, for example, a straight-chain alkyl group having 9 to 18 carbon atoms, or, for example, a straight-chain alkyl group having 10 to 12 carbon atoms.

Additionally, in a view point of higher durability, higher hole injection, higher triplet energy level, and at least one of lower driving voltage and film forming ability, or any 2 or more balances thereof (e.g., balance of hole injection property and film forming property), R⁴¹³ and R⁴¹⁴, and R⁴¹⁹ to R⁴²¹ may, for example, be a hydrogen atom (i.e., unsubstituted), or a straight-chain or branched alkyl group having 1 to 8 carbon atoms, or hydrogen atom (i.e., unsubstituted) or a straight-chain alkyl group having 3 to 6 carbon atoms, or for example, a hydrogen atom (i.e., unsubstituted).

In other words, in one embodiment, in formula (1), Ar¹ and Ar² may be a group derived from a compound selected from benzene, fluorene, or a combinations thereof; Ar³ may be a group derived from a compound selected from benzene, fluorene, or a combinations thereof; Ar⁴ may be a group derived from substituted or unsubstituted fluorene (fluorenyl group), or a group derived from substituted or unsubstituted indeno[1,2-b]fluorene (indeno[1,2-b]fluorenyl group).

In another embodiment, in formula (1), Ar¹ and Ar² may be an m-phenylene group (unsubstituted form) or a p-phenylene group (unsubstituted form) (e.g., a p-phenylene group (unsubstituted form)); Ar³ may be an m-phenylene group (unsubstituted form) or a p-phenylene group (unsubstituted form) (e.g., a p-phenylene group (unsubstituted form)); Ar⁴ may be a group derived from substituted fluorene (fluorenylene group) including below structures [R⁴¹¹ and R⁴¹² are each independently a straight-chain or branched alkyl group having 8 to 30 carbon atoms (or a straight-chain alkyl group having 9 to 18 carbon atoms, or a straight-chain alkyl group with 10 to 12 carbon atoms); R⁴¹³ to R⁴¹⁴ are each independently a hydrogen atom], or a group derived from substituted indeno[1,2-b]fluorene (indeno[1,2-b]fluorenylene group) including below structure [R⁴¹⁵ to R⁴¹⁸ are each independently a straight-chain or branched alkyl group with 8 to 30 carbon atoms (or a straight-chain alkyl group with 9 to 18 carbon atoms, or a straight-chain alkyl group with 10 to 12 carbon atoms), R⁴¹⁹ to R⁴²¹ are hydrogen atoms].

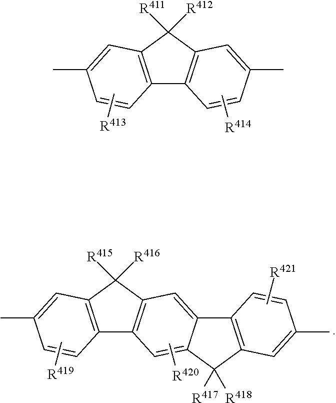

In the above formula (1), Ar⁵ may be a single bond or a substituted or unsubstituted aromatic heterocyclic ring having 3 to 60 ring-forming atoms.

Here, the aromatic heterocyclic ring group is the same as those defined for Ar⁴ above.

For example, Ar⁵ may be a single bond, or a substituted or unsubstituted p-phenylene group, or for example, Ar⁵ may be a single bond.

Ar⁶ may be a substituted or unsubstituted aromatic hydrocarbon group having 6 to 60 carbon atoms, or a substituted or unsubstituted aromatic heterocyclic ring having 3 to 60 ring-forming atoms.

Here, the aromatic hydrocarbon group is the same as those defined for Ar¹ and Ar².

Additionally, the aromatic heterocyclic ring group is the same as those defined for Ar⁴ above.

For example, Ar⁶ may be an aromatic hydrocarbon group having 6 to 25 carbon atoms substituted with a straight-chain hydrocarbon group having 1 to 12 carbon atoms or a branched hydrocarbon group having 3 to 12 carbon atoms, an unsubstituted aromatic hydrocarbon group having 6 to 25 carbon atoms, an aromatic heterocyclic ring group substituted with a straight-chain hydrocarbon group having 1 to 12 carbon atoms or a branched hydrocarbon group having 3 to 12 carbon atoms, or an unsubstituted aromatic heterocyclic ring group.

Among these, Ar⁶ (unsubstituted form) may be a group derived from benzene, biphenyl, terphenyl, quarterphenyl, fluorene, dibenzofuran, dibenzothiophene, indeno[1,2-b]fluorene, or a combination thereof. For example, Ar⁶ (unsubstituted form) may be a group derived from benzene or terphenyl.

By having the above Ar⁶ (unsubstituted form), higher durability, higher hole injection, higher triplet energy level, and at least one of lower driving voltage or film forming properties, or any two or more of balances thereof may be achieved.

Additionally, when Ar⁶ is a group derived from a benzene ring, it may have a straight-chain hydrocarbon group having 1 to 12 carbon atoms or a branched hydrocarbon group having 3 to 12 carbon atoms as a substituent.

By arranging the hydrocarbon group at an end of the structural unit (A), the polymer compound according to some embodiments contained in a hole transport layer may interact closely with the quantum dots in a light emitting layer, whereby holes can be efficiently injected into the quantum dots (high hole injection properties) and durability (luminescence lifetime) nay be improved.

Here, the hydrocarbon group having 1 to 12 carbon atoms is not particularly limited, but may include a straight-chain or branched alkyl group, alkenyl group, alkynyl group, cycloalkyl group, and the like.

Meanwhile, when the substituent present in Ar⁶ is an alkenyl group or an alkynyl group, the number of carbon atoms of the substituent present in Ar⁶ may be 2 or more and 6 or less.

Similarly, when the substituent present in Ar⁶ is a cycloalkyl group, the number of carbon atoms of the substituent present in Ar⁶ may be 3 or more and 6 or less.

Examples of alkyl group having 1 to 12 carbon atoms may include methyl group, ethyl group, n-propyl group, isopropyl group, n-butyl group, isobutyl group, sec-butyl group, tert-butyl group, n-Pentyl group, isopentyl group, tert-pentyl group, neopentyl group, 1,2-dimethyl propyl group, n-hexyl group, isohexyl group, 1,3-dimethylbutyl group, 1-isopropyl propyl group, 1, 2-dimethylbutyl group, n-heptyl group, 1,4-dimethyl pentyl group, 3-ethyl pentyl group, 2-methyl-1-isopropyl propyl group, 1-ethyl-3-methyl butyl group, n-octyl group, 2-ethylhexyl group, 3-methyl-1-isopropyl butyl group, 2-methyl-1-isopropyl butyl group, 1-tert-butyl-2-methyl propyl group, n-nonyl group, 3,5,5-trimethylhexyl group, n-decyl group, isodecyl group, n-undecyl group, 1-methyldecyl group, n-dodecyl group, and the like, and it is not limited thereto.

Examples of alkenyl group having 2 to 6 carbon atoms may include vinyl group, allyl group, 1-propenyl group, 2-butenyl group, 1,3-butadienyl group, 2-pentenyl group, iso-propenyl group, and the like, and it is not limited thereto.

Examples of alkynyl group having 2 to 6 carbon atoms may include ethynyl group and propargyl group, and are not limited thereto.

Examples of cycloalkyl group having 3 to 6 carbon atoms may include, for example, cyclopropyl group, cyclobutyl group, cyclopentyl group, cyclohexyl group, and the like, and are not limited thereto.

Among these, from the viewpoint of higher durability, higher hole injection, higher triplet energy level, and at least one of lower driving voltage and film forming property, or the balance of any two or more thereof (e.g., balance of hole injection property and film forming property), hydrocarbon group that may be present in Ar⁶ (a group derived from a benzene ring) may, for example, be a straight-chain alkyl group having 4 to 10 carbon atoms, or a branched alkyl group having 5 to 7 carbon atoms.

By increasing the number of carbon atoms of the hydrocarbon group present in Ar⁶ (making it long chain), a distance between the polymer compound and the quantum dots becomes closer, and the interaction between the quantum dots in a light-emitting layer and the polymer compound present in a hole transport layer becomes stronger, whereby hole injection properties (and thus, durability (light emission lifetime)) may further be improved.

In other words, in one embodiment of the present invention, Ar⁶ may be a group derived from benzene, terphenyl, biphenyl, dibenzofuran, fluorene, or a combination thereof, which is substituted with a straight-chain alkyl group having 4 to 10 carbon atoms or a branched alkyl group having 4 to 10 carbon atoms.

In one embodiment of the present invention, Ar⁶ may be a group derived from a benzene substituted with a straight-chain alkyl group having 5 to 7 carbon atoms, or an unsubstituted terphenyl.

Meanwhile, the position of the hydrocarbon group present in Ar⁶ is not particularly limited, but it may be as far as possible from the nitrogen atom of the carbazole ring to which Ar⁶ is connected. For example, when Ar⁶ is a phenyl group, the hydrocarbon group may be present at a para position with respect to the nitrogen atom of the carbazole.

By having this arrangement, a distance between the polymer compound according to some embodiments and quantum dots becomes closer, and the interaction between the polymer compound in the hole transport layer and the quantum dots in the light-emitting layer becomes stronger, whereby hole injection properties (and thus, durability (emission lifetime)) may further improve.

In other words, in one embodiment, Ar⁶ in formula (1) may be selected from Group (III) below.

In Group (III), R³¹¹ to R³³⁹ may, each independently, be a hydrogen atom, or a straight-chain or branched hydrocarbon group having 1 to 18 carbon atoms.

For example, R³¹¹ to R³³⁹ may, each independently, be a hydrogen atom, or a straight alkyl group having 4 to 10 carbon atoms or a branched alkyl group having 4 to 10 carbon atoms. For example, R³¹¹ to R³³⁹ may, each independently, be a hydrogen atom, or a straight-chain alkyl group having 5 to 7 carbon atoms.

X may be oxygen atom or sulfur atom.

* indicates a bonding position with an adjacent atom.

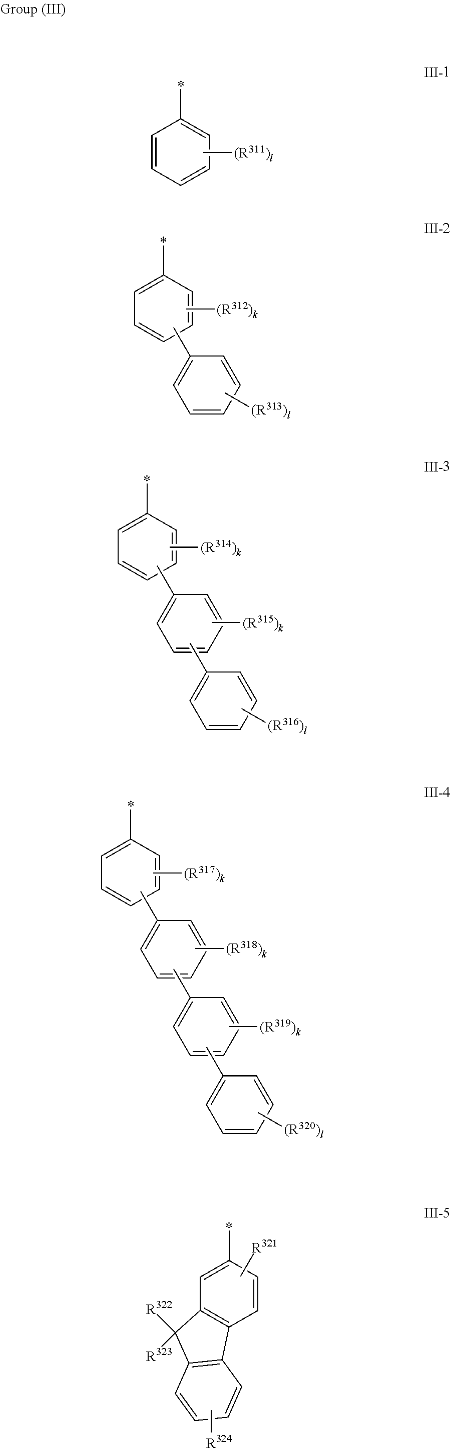

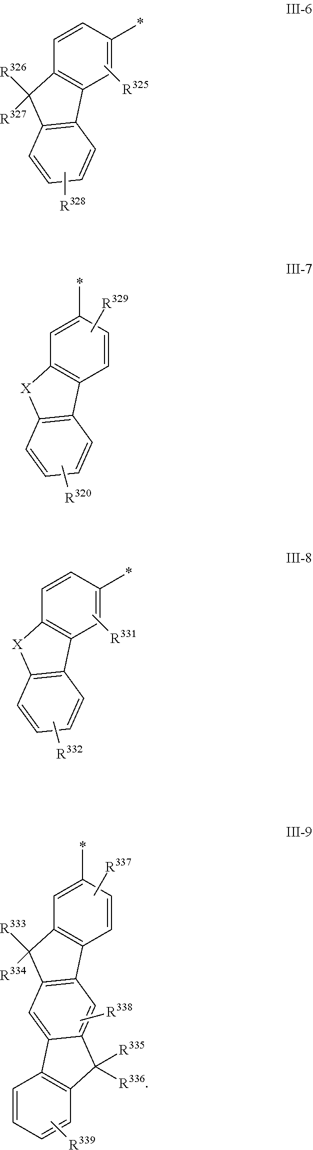

In one embodiment, the Ar³ in formula (1) may be selected from Group (I) below:

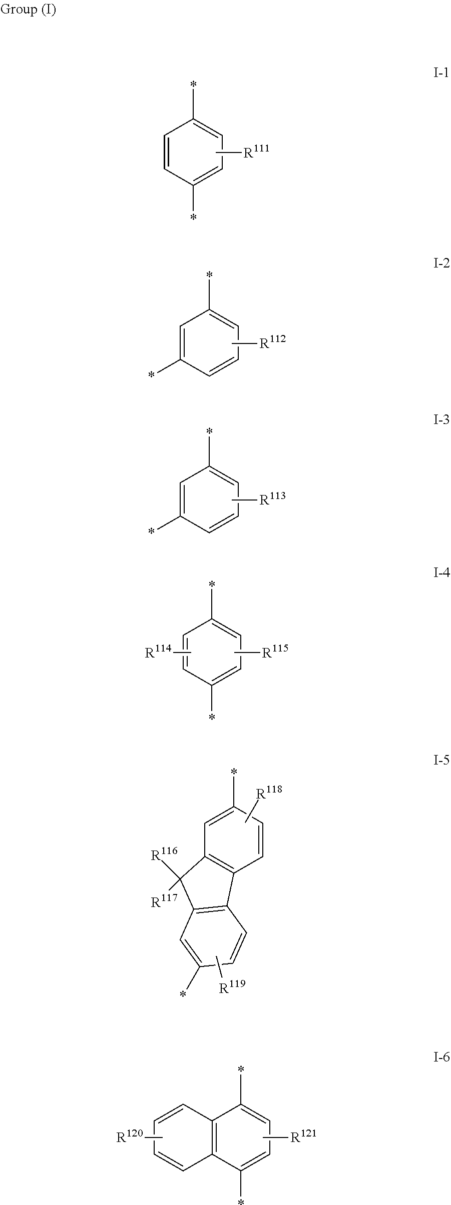

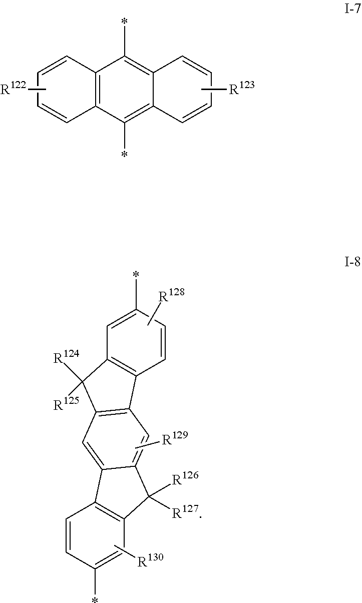

In Group (1) above,
R¹¹¹ to R¹³⁰ may, each independently, be a hydrogen atom, or a straight-chain or branched hydrocarbon group having 1 to 18 carbon atoms, and * indicates a bonding position with an adjacent atom, and
Ar¹, Ar², and Ar⁴ may, each independently, be selected from the following Group (II′):

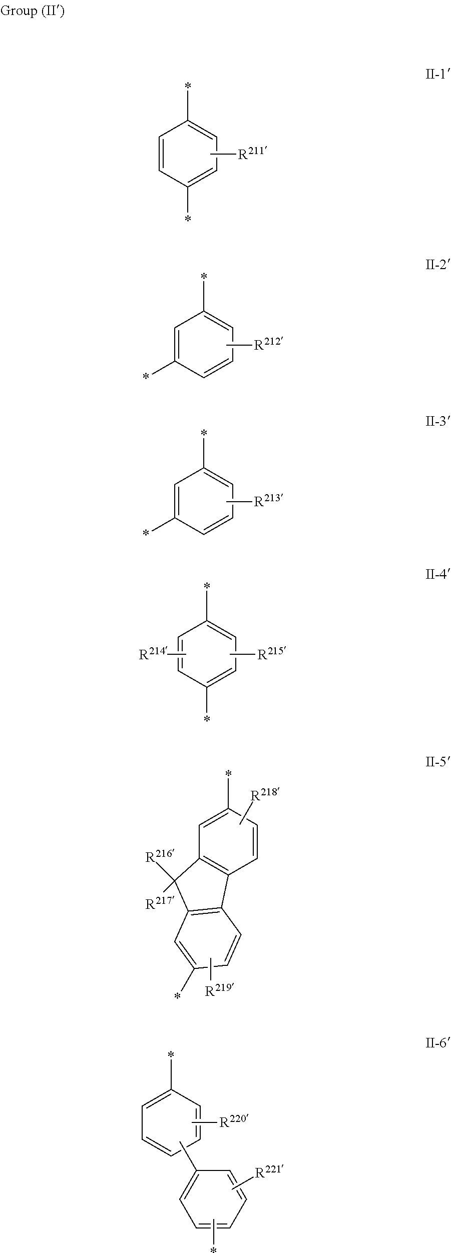

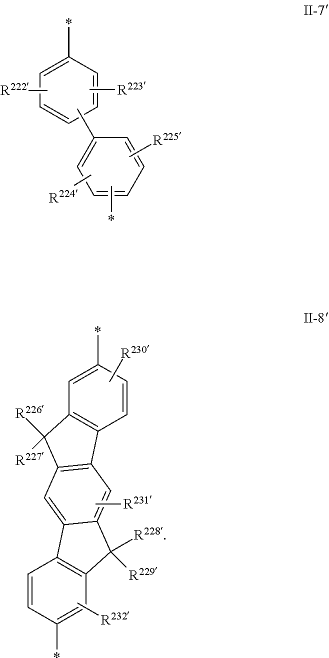

In Group (II′) above,

R^{211′} to R^{232′} may, each independently, be a hydrogen atom, or a straight-chain or branched hydrocarbon group having 1 to 18 carbon atoms, and * indicates a bonding position with an adjacent atom, and
Ar⁶ may be a group selected from the following Group (III):

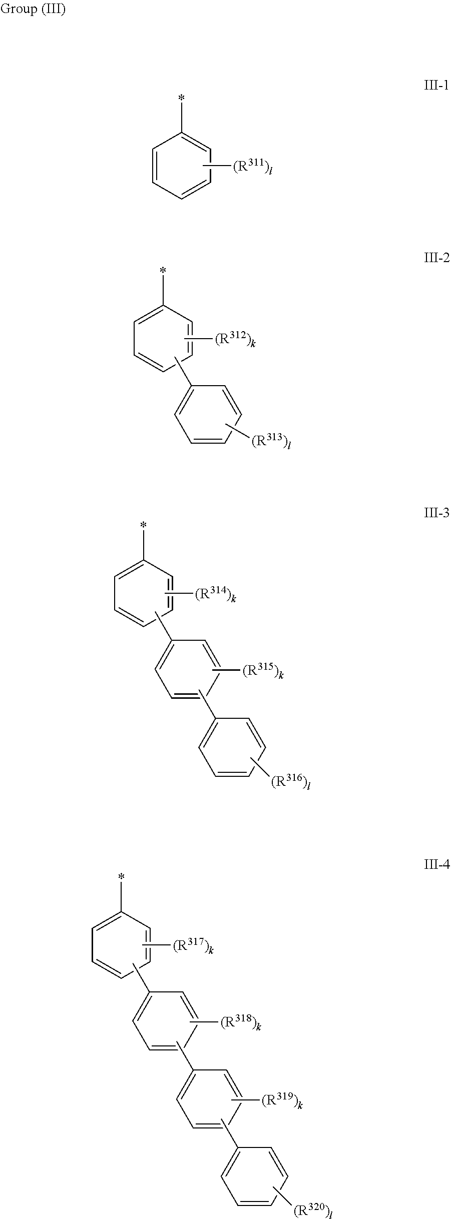

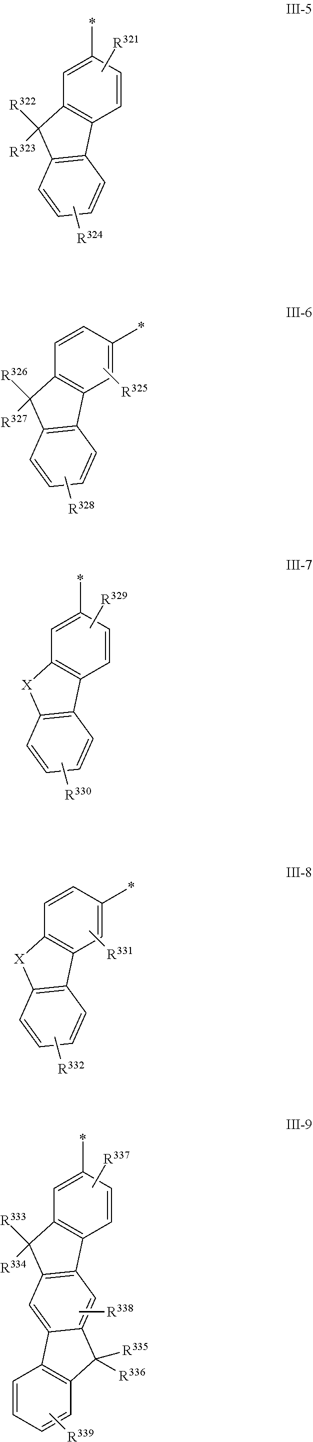

In Group (III),
R³¹¹ to R³³⁹ may, each independently, be a hydrogen atom, or a straight-chain or branched hydrocarbon group having 1 to 18 carbon atoms,
X indicates oxygen atom or sulfur atom, and
* indicates a bonding position with an adjacent atom.

In formula (1), R¹ may independently be a hydrogen atom, an alkyl group, a hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN).

For example, R¹ may be a hydrogen atom, an alkyl group, or an alkoxycarbonyl group.

For example, R¹ may be a hydrogen atom.

In formula (1), R² may independently be a hydrogen atom, alkyl group, hydroxyalkyl group, alkoxy group, alkoxyalkyl group, alkenyl group, alkynyl group, alkylthio group, alkoxycarbonyl group, hydroxyl group (—OH), carboxyl group (—COOH), thiol group (—SH), or cyano group (—CN).

For example, R² may be a hydrogen atom, an alkyl group, or an alkoxycarbonyl group.

For example, R² may be a hydrogen atom.

In one embodiment, if Ar³ is a p-phenylene group and Ar⁵ is a single bond, then Ar³ may be linked to a carbazole ring as below. In the structure below, Ar⁶, R¹, and R² may respectively be as defined above.

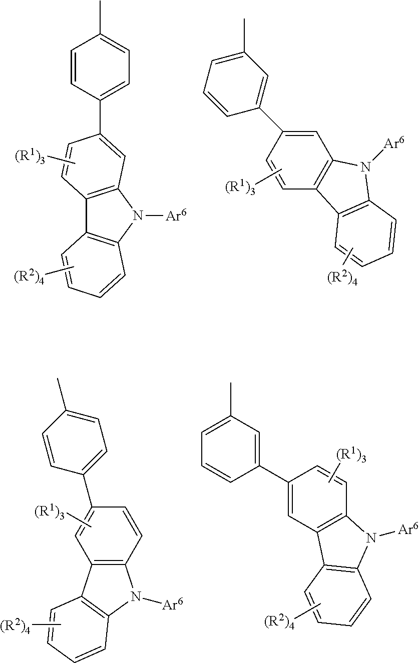

In one embodiment, if Ar³ is a p-phenylene group and Ar⁵ is a single bond, then Ar³ is linked to a carbazole ring as below.

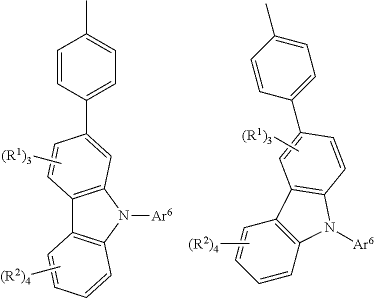

For example, structural unit (A) may be selected from the group below:

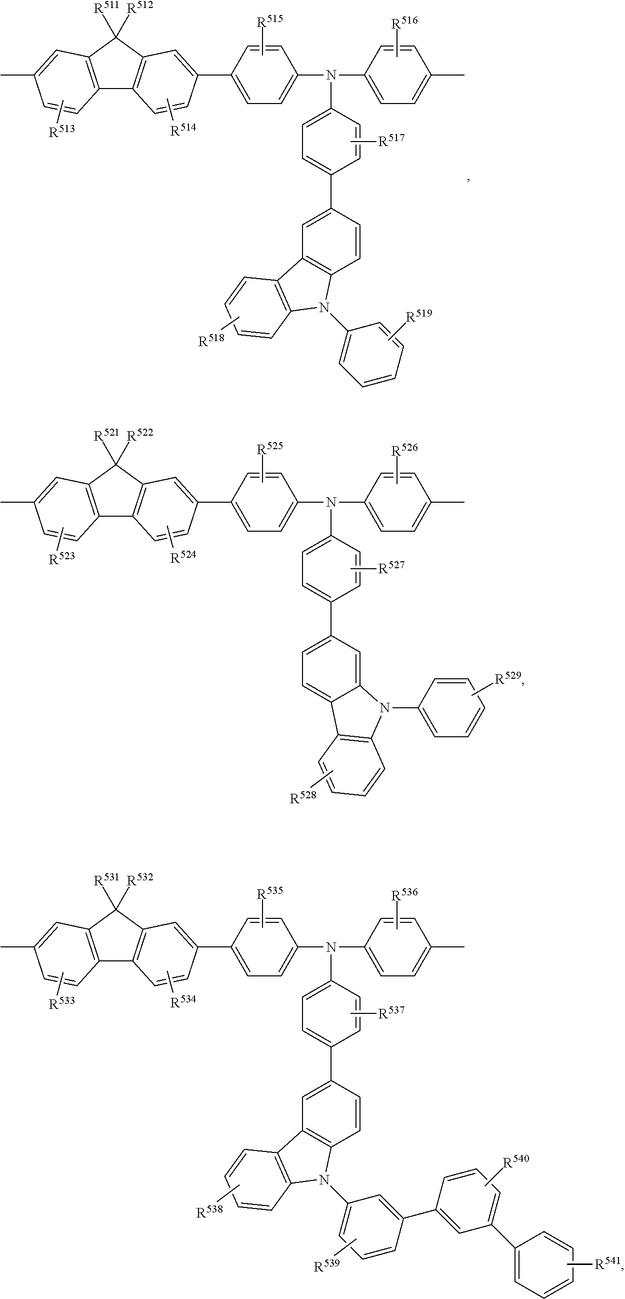

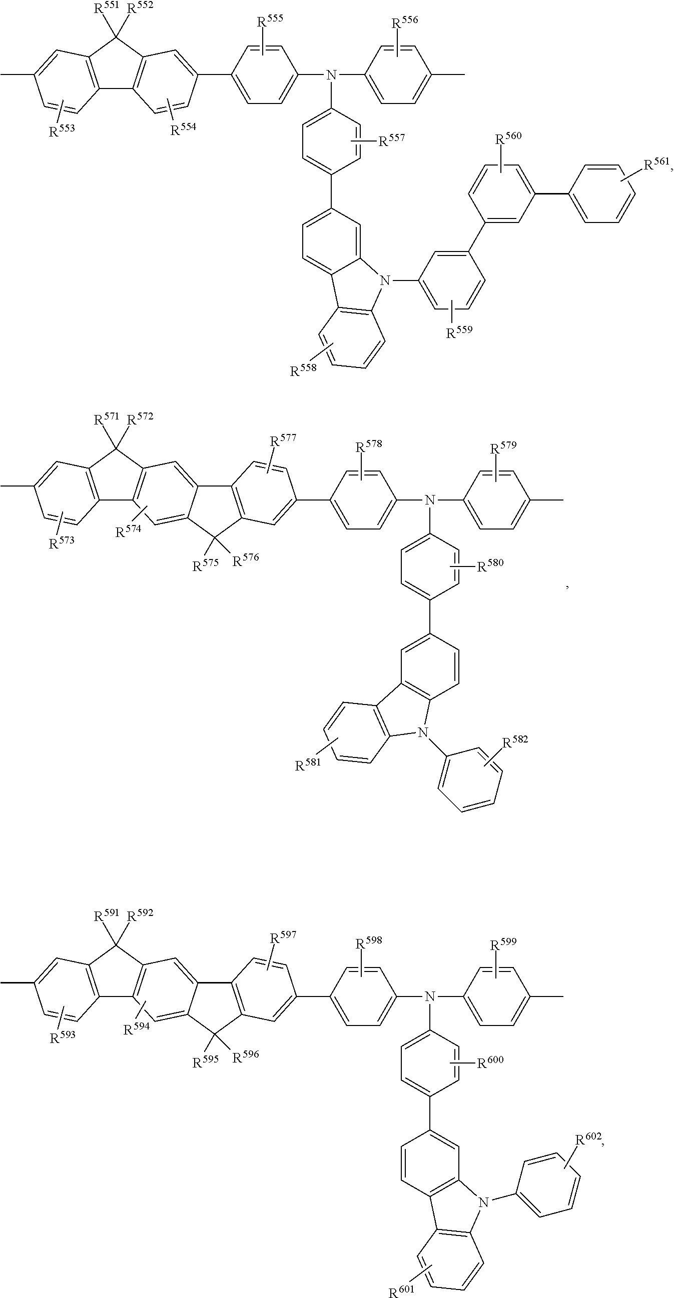

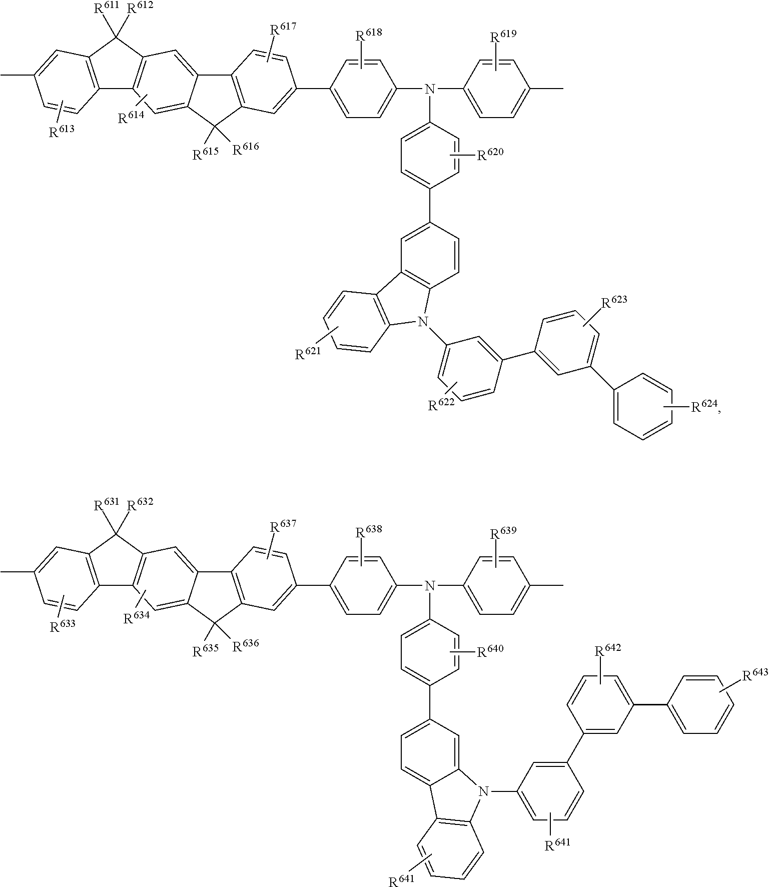

In the above formulas, R⁵¹¹ and R⁵¹², R⁵²¹ and R⁵²², R⁵³¹ and R⁵³², and R⁵⁵¹ and R⁵⁵² may, each independently, be a straight-chain or branched alkyl group having 8 to 30 carbon atoms. For example, R⁵¹¹ and R⁵¹², R⁵²¹ and R⁵²², R⁵³¹ and R⁵³², and R⁵⁵¹ and R⁵⁵² may, each independently, be a straight-chain alkyl group having 9 to 18 carbon atoms. For example, R⁵¹¹ and R⁵¹², R⁵²¹ and R⁵²², R⁵³¹ and R⁵³², and R⁵⁵¹ and R⁵⁵² may, each independently, be a straight-chain alkyl group having 10 to 12 carbon atoms.

R⁵¹⁹ and R⁵²⁹ may, each independently, be a straight-chain alkyl group having 1 to 12 carbon atoms or a branched alkyl group having 3 to 12 carbon atoms. For example, R⁵¹⁹ and R⁵²⁹ may, each independently, be a straight-chain alkyl group having 4 to 10 carbon atoms or a branched alkyl group having 4 to 10 carbon atoms. For example, R⁵¹⁹ and R⁵²⁹ may, each independently, be a straight-chain alkyl group having 5 to 7 carbon atoms.

R⁵¹³ to R⁵¹⁸, R⁵²³ to R⁵²⁸, R⁵³³ to R⁵⁴¹, and R⁵⁵³ to R⁵⁶¹ may, each independent, be a hydrogen atom, a straight-chain alkyl group having 1 to 12 carbon atoms or a branched alkyl groups having 3 to 12 carbon atoms. For example, R⁵¹³ to R⁵¹⁸, R⁵²³ to R⁵²⁸, R⁵³³ to R⁵⁴¹, and R⁵⁵³ to R⁵⁶¹ may, each independently, be a hydrogen atom, or an alkyl group having 1 to 3 carbon atoms. For example, R⁵¹³ to R⁵¹⁸, R⁵²³ to R⁵²⁸, R⁵³³ to R⁵⁴¹, and R⁵⁵³ to R⁵⁶¹ may, each independently, be a hydrogen atom.

A terminal of the polymer compound according to some embodiments is not particularly limited and is appropriately defined depending on the type of raw material used, but may usually be hydrogen atom, phenyl group, biphenyl group, phenyl fluorenyl group, phenylindeno fluorenyl group, or a group represented by —Ar⁴—Y(Ar⁴ has the same definition as Ar⁴ in formula (1), for example, is the same as Ar⁴ in formula (1); and Y is hydrogen atom, phenyl group, biphenyl group, or fluorenyl group).

### Structural Unit (B)

The polymer compound according to some embodiments may, in addition to structural unit (A), include a structural unit (B) containing a structural unit represented by formula (2):

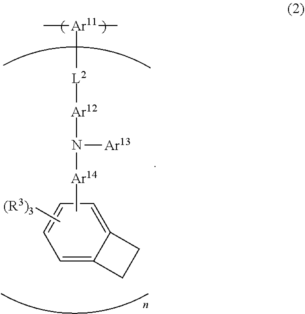

In formula (2) above,
Ar¹¹ may be a substituted or unsubstituted aromatic hydrocarbon group having 6 to 60 carbon atoms, or a substituted or unsubstituted aromatic heterocyclic ring group having 3 to 60 ring atoms.

Here, the aromatic hydrocarbon group has the same definition as in Ar¹ and Ar².

Additionally, the aromatic heterocyclic ring group has the same definition as in Ar⁴.

For example, Ar¹¹ may be a substituted or unsubstituted aromatic hydrocarbon group having 6 to 20 carbon atoms. For example, Ar¹¹ may be a group derived from a compound selected from benzene, fluorene, biphenyl, indeno[1,2-b]fluorene, dibenzofuran, dibenzothiophene, or a combination thereof. For example, Ar¹¹ a group derived from a compound selected from benzene, fluorene, biphenyl, indeno[1,2-b]fluorene, or combinations thereof.

In the above example, Ar¹¹ may be unsubstituted, or any hydrogen atom of Ar¹¹ may be substituted with a substituent. For example, Ar¹¹ may be a fluorene-derived group, of may be a group derived from indeno[1,2-b]fluorene, and for example, Ar¹¹ may be a fluorene-derived group.

In formula (2) above,
L² may be a single bond or a saturated hydrocarbon group having 2 to 60 carbon atoms.

Here, the saturated hydrocarbon group is the same as defined in L¹ below.

Among these, L² may be a single bond, straight-chain or branched saturated hydrocarbon group having 4 to 12 carbon atoms, or an unsubstituted, straight-chain alkylene group having 5 to 8 carbon atoms (for example, a hexamethylene group).

In formula (2) above,
Ar¹² may be a substituted or unsubstituted aromatic hydrocarbon group having 6 to 60 carbon atoms, or a substituted or unsubstituted aromatic heterocyclic ring group having 3 to 60 ring-forming atoms.

Here, the aromatic hydrocarbon group has the same definition as in Ar¹ and Ar².

Additionally, the aromatic heterocyclic ring group has the same definition as in Ar⁴.

For example, Ar¹² may be a substituted or unsubstituted aromatic hydrocarbon group having 6 to 20 carbon atoms. For example, Ar¹² may be a group derived from a compound selected from benzene, fluorene, biphenyl, indeno[1,2-b]fluorene, or a combination thereof. For example, Ar¹² may be a group derived from benzene, fluorene, or biphenyl.

In the above embodiment, Ar¹² may be unsubstituted, or any hydrogen atom of Ar¹² may be substituted with a substituent.

Ar¹² may be a phenylene group (unsubstituted form), for example, an m-phenylene group, a p-phenylene group (unsubstituted form), or, for example, a p-phenylene group (may be in an unsubstituted form).

By having the above Ar¹², higher durability, higher hole injection, higher triplet energy level, and at least one of lower driving voltage and film forming properties, or a balance of any two or more thereof (e.g., high durability) may be achieved.

In formula (2) above,
Ar¹³ may be a substituted or unsubstituted aromatic hydrocarbon group having 6 to 60 carbon atoms, or a substituted or unsubstituted aromatic heterocyclic ring group having 3 to 60 ring atoms.

Here, the aromatic hydrocarbon group has the same definition as in Ar¹ and Ar².

Additionally, the aromatic heterocyclic ring group has the same definition as in Ar⁴.

For example, Ar¹³ may be a substituted or unsubstituted aromatic hydrocarbon group having 6 to 20 carbon atoms. For example, Ar¹³ may be a group derived from a compound selected from benzene, fluorene, biphenyl and indeno[1,2-b]fluorene, or a combination thereof. For example, Ar¹³ may be a group derived from benzene, fluorene, or biphenyl.

In the above embodiment, Ar¹³ may be unsubstituted, or any hydrogen atom of Ar¹³ may be substituted with a substituent.

Ar¹³ may be a phenyl group (unsubstituted form), an unsubstituted biphenyl group or a biphenyl group substituted with an alkyl group, or a fluorenyl group substituted with an alkyl group or a phenyl group, or for example, may be a phenyl group unsubstituted form).

By having the above Ar¹³, higher durability, higher hole injection, higher triplet energy level, and at least one of lower driving voltage and film forming properties, or a balance of any two or more thereof (e.g., high durability) may be achieved.

In formula (2) above,
Ar¹⁴ may be a single bond, a substituted or unsubstituted aromatic hydrocarbon group having 6 to 60 carbon atoms, or a substituted or unsubstituted aromatic heterocyclic ring group having 3 to 60 ring atoms.

Here, the aromatic hydrocarbon group has the same definition as in Ar¹ and Ar².

Additionally, the aromatic heterocyclic ring group has the same definition as in Ar⁴.

For example, Ar¹⁴ may be a single bond, or a substituted or unsubstituted aromatic hydrocarbon group having 6 to 20 carbon atoms. For example, Ar¹⁴ may be a single bond or a phenylene group, or for example, Ar¹⁴ may be a single bond.

By having the above Ar¹⁴, higher durability, higher hole injection, higher triplet energy level, and at least one of lower driving voltage and film forming properties, or a balance of any two or more thereof (e.g., high durability) may be achieved.

In formula (2),
R³ may independently be a hydrogen atom, an alkyl group, a hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN).

Examples of substituents of R³ may be the same as those of the substituents that may be present in Ar¹ or Ar². For example, R³ may independently be a hydrogen atom, an alkyl group, or an alkenyl group, and in this time, R³ may from a ring with another R³ or with a carbon atom in a benzene ring to which R³ is bonded (substituted by R³).

R³ may be a hydrogen atom (crosslinkable group is derived from bicyclo[4.2.0]octa-1,3,5-triene), or may form a crosslinkable group derived from 1,2-dihydrocyclobuta[a]naphthalene or 1,2-dihydrocyclorobuta[b]naphthalene formed by linking 1,3-butadienyl group to the benzene ring, for example, R³ may be a hydrogen atom, or may form a crosslinkable group derived from 1,2-dihydrocyclobuta[a]naphthalene by linking 1,3-butadienyl group to the benzene ring. The crosslinkable group may include, for example, the following structures:

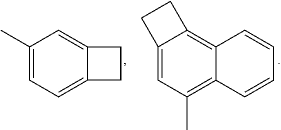

In the present specification, a group derived from bicyclo[4.2.0]octa-1,3,5-triene, a group derived from 1,2-dihydrocyclobuta[a]naphthalene, and a group derived from 1, 2-dihydrocyclobuta[b]naphthalene as a crosslinkable group are as below:
Groups derived from bicyclo[4.2.0]octa-1,3,5-triene:

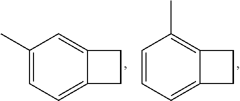

Groups derived from 1,2-dihydrocyclobuta[a]naphthalene:

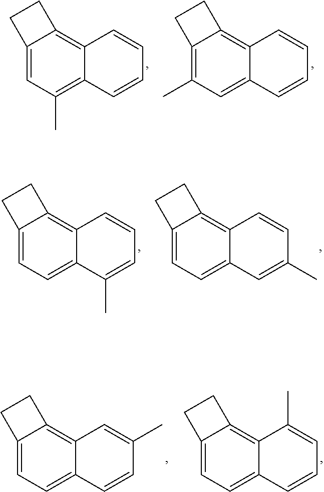

Groups derived from 1,2-dihydrocyclobuta[b]naphthalene:

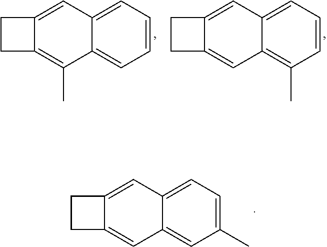

In formula (2), n is 1 or 2, and, for example, 2.

In one embodiment, the polymer compound includes a structural unit represented by formula (1), and a structural unit represented by formula (2), wherein in formula (2), Ar¹¹ may be a substituted or unsubstituted aromatic hydrocarbon group having 6 to 20 carbon atoms, L² may be a single bond, or a straight-chain or branched saturated hydrocarbon group having 4 to 12 carbon atoms, Ar¹² may be a substituted or unsubstituted aromatic hydrocarbon group having 6 to 20 carbon atoms, Ar¹³ may be a substituted or unsubstituted aromatic hydrocarbon group having 6 to 20 carbon atoms, Ar¹⁴ may be a single bond or a substituted or unsubstituted aromatic hydrocarbon group having 6 to 20 carbon atoms, R³ may independently be a hydrogen atom, an alkyl group, or an alkenyl group, where R³ may form a ring with another R³ or with a carbon atom in a benzene ring to which R³ is bonded (i.e., substituted by R³), and n may be 1 or 2.

The polymer compound according to some embodiments may further include a structural unit represented below, in addition to the structural unit represented by formula (2), as structural unit (B):

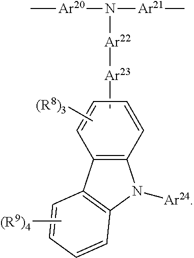

In other words, the polymer compound according to some embodiments may include a structural unit represented by formula (1), and a structural unit represented by formula (5) below:

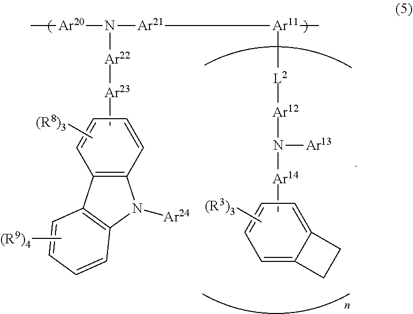

In formula (5) above, Ar¹¹, L², Ar¹², Ar¹³, Ar¹⁴, R³, and n are the same as defined in formula (2).

In formula (5) above, Ar²⁰ and Ar²¹ may each independently be a substituted or unsubstituted aromatic hydrocarbon group having 6 to 60 carbon atoms.

Here, Ar²⁰ and Ar²¹ may be the same as or different from each other. At this time, Ar²⁰ and Ar²¹ may have the same examples as Ar¹ and Ar² in formula (1), respectively. For example, Ar²⁰ and Ar²¹ may be the same as Ar¹ and Ar² in formula (1), respectively.

In formula (5), Ar²² may be a substituted or unsubstituted aromatic hydrocarbon group having 6 to 120 carbon atoms, for example, a substituted or unsubstituted aromatic hydrocarbon group having 6 to 60 carbon atoms. At this time, Ar²² may have the same example as Ar³ in formula (1). For example, Ar²² may be the same as Ar³ in formula (1).

In formula (5), Ar²³ may be a single bond, or a substituted or unsubstituted aromatic heterocyclic ring group having 3 to 60 ring-forming atoms. At this time, Ar²³ may have the same examples as Ar⁵ in formula (1). For example, Ar²³ may be the same as Ar⁵ in formula (1).

In formula (5), Ar²⁴ may be a substituted or unsubstituted aromatic hydrocarbon group having 6 to 60 carbon atoms, or a substituted or unsubstituted aromatic heterocyclic ring having 3 to 60 ring-forming atoms. At this time, Ar²⁴ may have the same example as Ar⁶ in formula (1). For example, Ar²⁴ may be the same as Ar⁶ in formula (1).

In formula (5), R⁸ may independently be a hydrogen atom, an alkyl group, a hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN). R⁸ may have the same examples as R¹ in formula (1). For example, R⁸ may be the same as R¹ in formula (1).

In formula (5), R⁹ may independently be a hydrogen atom, an alkyl group, a hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN). R⁹ may have the same example as R² in formula (1). For example, R⁹ may be the same as R² in formula (1).

For example, structural unit (B) may be selected from the following groups:

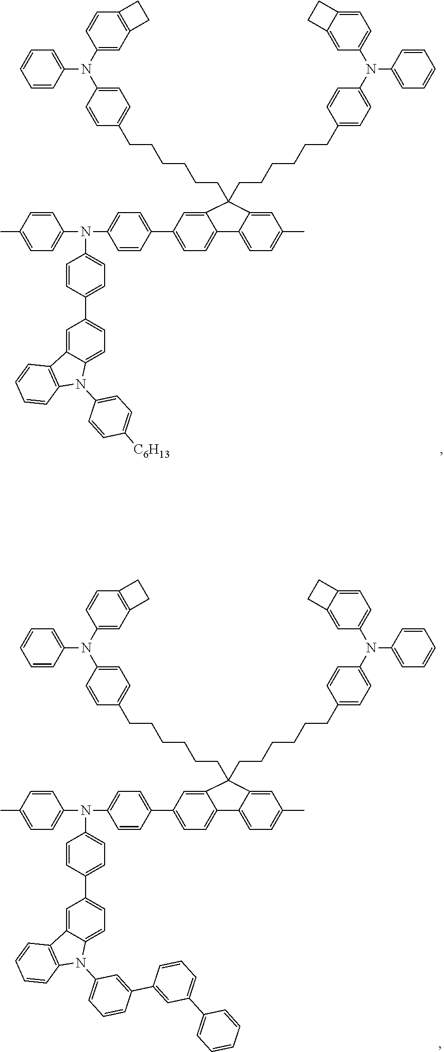

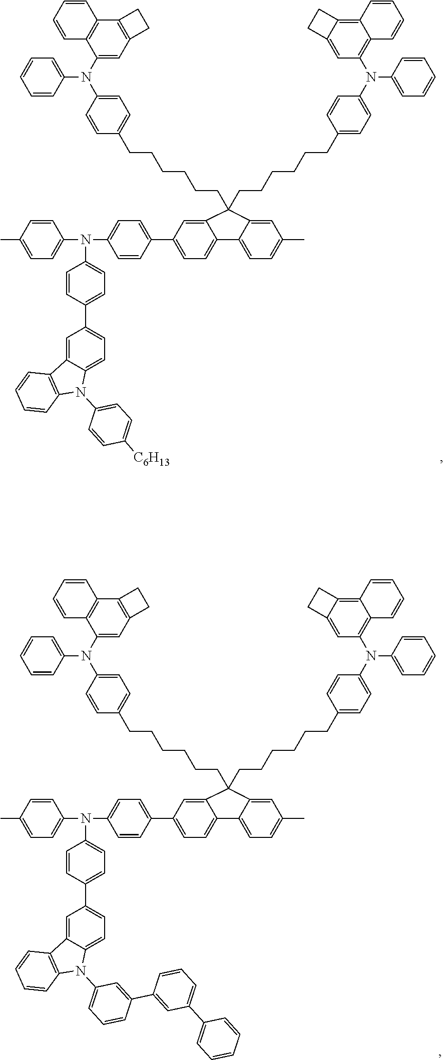

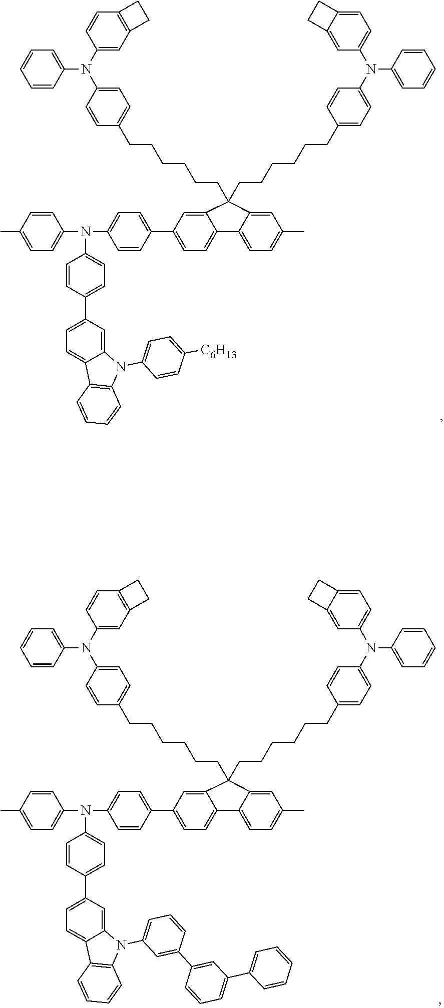

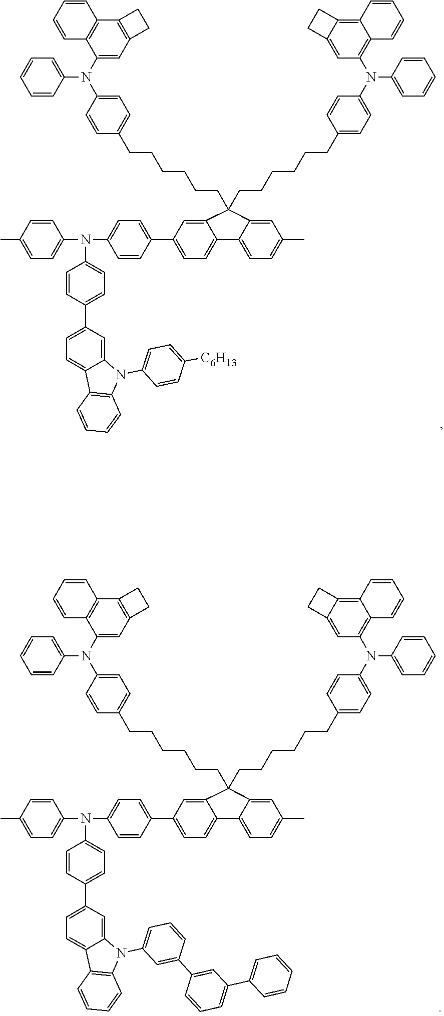

A terminal end of the main chain of the polymer compound according to some embodiments is not particularly limited and is appropriately defined depending on the type of raw material used, but may usually be hydrogen atom, phenyl group, biphenyl group, phenyl fluorenyl group, phenyl indeno fluorenyl group, a group represented by —Ar⁴—Y {Ar⁴ has the same definition as Ar⁴ in formula (1), for example, the same as Ar⁴ in formula (1); and Y is hydrogen atom, phenyl group, biphenyl group, or fluorenyl group}, or a group having Y′ at a terminal end thereof (Y′ is hydrogen atom, a phenyl group, a biphenyl group, or a fluorenyl group).

A mole ratio of the structural unit (B) of the polymer compound according to some embodiments is not particularly limited.

From a view point of improving durability (emission lifetime) or any improved effects of hole transport properties of the layer formed by using the obtained polymer compound according to some embodiments, such as, for example, hole transport layer or hole injection layer, the mole ratio of structural unit (B) may be configured to have the mole ratio of structural unit (A) and structural unit (B) (molar ratio of the structural unit (A): structural unit (B)) of, for example, from about 50:50 to about 99:1, for example, from about 80:20 to about 97:3, for example, from about 85:15 to about 95:5.

If the polymer compound comprises two or more types of structural units (A), the amount of structural units (A) may be a total amount of structural units (A).

Likewise, if the polymer compound comprises two or more types of structural units (B), the amount of structural units (B) may be a total amount of structural units (B).

### Structural Unit (C)

The polymer compound according to some embodiment may further include, in addition to structural unit (A), structural unit (C) that contains structural unit represented by formula (3) below.

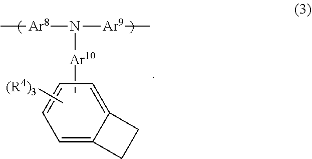

In formula (3) above, Ar⁸ and Ar⁹ may, each independently, be a substituted or unsubstituted aromatic hydrocarbon group having 6 to 60 carbon atoms.

Here, Ar⁸ and Ar⁹ may be the same as or different from each other.

The aromatic hydrocarbon group may have the same definition as in Ar¹ and Ar².

For example, Ar⁸ and Ar⁹ (unsubstituted forms) may, each independently, be a group derived from a compound selected from benzene, fluorene, biphenyl, indeno[1,2-b]fluorene, dibenzofuran, dibenzothiophene, or a combination thereof.

For example, Ar⁸ and Ar⁹ (unsubstituted forms) may, each independently, be a group derived from a compound selected from benzene, fluorene, biphenyl, indeno[1,2-b]fluorene, or a combination thereof.

Meanwhile, in an embodiment, hydrocarbon group as Ar⁸ or Ar⁹ may, each independently, be unsubstituted or may contain a substituent that substitutes a hydrogen atom of Ar⁸ or Ar⁹.

For example, at least one of Ar⁸ or Ar⁹ may have an aromatic hydrocarbon group substituted with an alkyl group having 9 to 60 carbon atoms. In other words, in one embodiment, at least one of Ar⁸ or Ar⁹ may include an aromatic hydrocarbon group having 6 to 60 carbon atoms substituted with an alkyl group having 9 to 60 carbon atoms.

For example, Ar⁸ may be a group derived from benzene, a group derived from substituted or unsubstituted fluorene, or a group derived from substituted or unsubstituted indeno[1,2-b]fluorene, and Ar⁹ may be a group derived from benzene, a group derived from fluorene in which any one hydrogen atom is substituted with an alkyl group having 9 to 60 carbon atoms, or a group derived from indeno[1,2-b]fluorene in which any one hydrogen atom is substituted with an alkyl group having 9 to 60 carbon atoms.

For example, Ar⁸ may be an unsubstituted phenylene group, and in this case, Ar⁹ may be a combination of a substituted or unsubstituted phenylene group and a group derived from fluorene substituted with an alkyl group having 9 to 20 carbon atoms, or a combination of a substituted or unsubstituted phenylene group and a group derived from indeno[1,2-b]fluorene in which any one hydrogen atom is substituted with an alkyl group having 9 to 20 carbon atoms.

For example, Ar⁸ may be an unsubstituted p-phenylene group, and in this case, Ar⁹ may be a combination of unsubstituted p-phenylene group and a group derived from fluorene substituted with an alkyl group having 10 to 15 carbon atoms, or a combination of unsubstituted p-phenylene group and a group derived from indeno[1,2-b]fluorene in which any one hydrogen atom is substituted with an alkyl group having 10 to 15 carbon atoms.

In formula (3), Ar¹⁰ may be a single bond, a substituted or unsubstituted aromatic hydrocarbon group having 6 to 60 carbon atoms, or a substituted or unsubstituted aromatic heterocyclic ring group having 3 to 60 ring-forming atoms.

Here, the aromatic hydrocarbon group may have the same definition as in Ar¹ and Ar².

Additionally, the aromatic heterocyclic ring group may have the same definition as in Ar⁴.

For example, Ar¹⁰ may be a group derived from a compound selected from benzene, fluorene, biphenyl, indeno[1,2-b]fluorene, or a combination thereof.

For example, Ar¹⁰ may be a group derived from a compound selected from benzene, fluorene, or biphenyl.

Meanwhile, in one embodiment, Ar¹⁰ may be unsubstituted, or may have a substituent that replaces any hydrogen atom of Ar¹⁰.

For example, Ar¹⁰ may be a phenylene group (unsubstituted form), for example, an m-phenylene group, a p-phenylene group (unsubstituted form), or, for example, p-phenylene group (unsubstituted form).

By having the Ar¹⁰, higher durability, higher hole injection, higher triplet energy level, at least one of lower driving voltage and film forming properties, or a balance of any two or more thereof (e.g., higher durability) may be achieved.

In formula (3), R⁴ may, independently, be a hydrogen atom, an alkyl group, a hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN).

Specific examples as R⁴ may be the same as those for substituents that may exist when Ar¹ or Ar² possesses a substituent.

In addition, R⁴ may form a ring with another R⁴ or with a carbon atom in a benzene ring to which R⁴ is bonded (i.e., substituted by R⁴).

R⁴ may be a hydrogen atom, or may form a crosslinkable group derived from 1,2-dihydrocyclobuta[a]naphthalene or 1,2-dihydrocyclobuta[b]naphthalene formed by linking 1,3-butadienyl group to the benzene ring, for example, R⁴ may be a hydrogen atom, or may form a crosslinkable group derived from 1,2-dihydrocyclobuta[a]naphthalene by linking 1,3-butadienyl group to the benzene ring. The crosslinkable group may include, for example, the following structures:

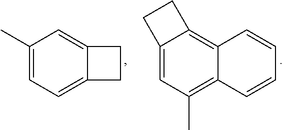

In some embodiments, a terminal end of the main chain of the polymer compound (for example, a terminal end of the main chain near structural unit (C)) according to some embodiments is not particularly limited and is appropriately defined by the type of raw material used.

For example, a terminal end of the main chain of the polymer compound (for example, a terminal end of the main chain near structural unit (C)) according to some embodiments may be represented by formula (6) below.

Accordingly, higher durability, higher hole injection, higher triplet energy level, at least one of lower driving voltage and film forming properties, or any two or more balances thereof (e.g., higher durability) may be achieved.

In other words, in some embodiments of the present invention, the polymer compound according to some embodiments may include a structural unit represented by formula (1), a structural unit represented by formula (3), and a structural unit represented by formula (6) below:

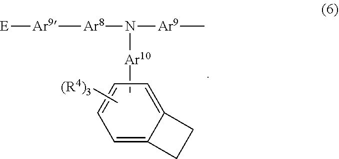

In formula (6), Ar⁸ to Ar¹⁰, and R⁴ may be the same as defined in formula (3).

Ar^{9′} may be a substituted or unsubstituted aromatic hydrocarbon group having 6 to 60 carbon atoms.

Here, the aromatic hydrocarbon group may be the same as defined in Ar¹ and Ar².

For example, Ar⁸ in formula (6) and Ar⁸ in formula (3) may be the same as, or different from each other, but, for example, they may be identical to each other.

Ar⁹ in formula (6) and Ar⁹ in formula (3) may be the same as, or different from each other.

For example, Ar⁹ in formula (6) may be a group derived from a substituted or unsubstituted benzene, a group derived from a substituted or unsubstituted fluorene, or a group derived from a substituted or unsubstituted indeno[1,2-b]fluorene. For example, Ar⁹ in formula (6) may be a phenylene group (e.g., a p-phenylene group) (unsubstituted form).

Ar¹⁰ in formula (6) and Ar¹⁰ in formula (3) may be the same as, or different from each other, and for example, may be the same as each other.

Ar^{9′} in formula (6) may be a substituted or unsubstituted aromatic hydrocarbon group having 6 to 60 carbon atoms.

Here, the aromatic hydrocarbon group may be the same as defined in Ar¹ and Ar².

For example, Ar^{9′} may be a group derived from benzene, a group derived from a substituted or unsubstituted fluorene, a group derived from a substituted or unsubstituted indeno[1,2-b]fluorene, or a combination thereof.

For example, Ar^{9′} may be a p-phenylene group, a group derived from a fluorene substituted with an alkyl group having 9 to 20 carbon atoms, or a group derived from indeno[1,2-b]fluorene substituted by an alkyl group having 9 to 20 carbon atoms.

For example, Ar^{9′} may be a group derived from a fluorene in which two hydrogen atoms of —CH₂— are replaced with an alkyl group having 10 to 18 carbon atoms (or 10 to 15 carbon atoms), or a group derived from indeno[1,2-b]fluorene in which two hydrogen atoms of —CH₂— are replaced with an alkyl group having 10 to 18 carbon atoms (or 10 to 15 carbon atoms).

In formula (6), E may be a substituted or unsubstituted aromatic hydrocarbon group having 6 to 60 carbon atoms.

Here, the aromatic hydrocarbon group may be the same as defined for Ar¹ and Ar².

For example, E may be a group derived from a compound selected from benzene, fluorene, biphenyl and indeno[1,2-b]fluorene, or a combination thereof. For example, E may be a group derived from a compound selected from benzene, fluorene, or biphenyl.

Meanwhile, in some embodiments, E may be unsubstituted, or any one hydrogen atom may be substituted with a substituent.

E may be a phenyl group (in unsubstituted form), a biphenyl group (in unsubstituted form), or a fluorenyl group substituted with an alkyl group or a phenyl group, for example, a phenyl group (in unsubstituted form), or a biphenyl group (unsubstituted form).

By having the E, higher durability, higher hole injection, higher triplet energy level, at least one of lower driving voltage and film forming properties, or any two or more balances thereof (e.g., higher durability) may be achieved.

For example, structural unit (C) may be selected from the following group:

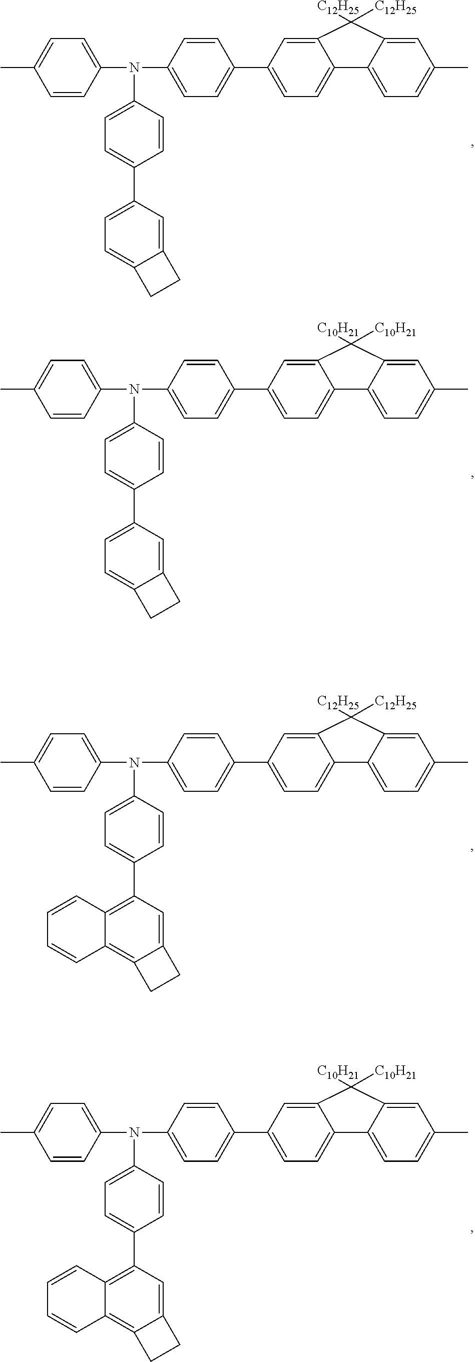

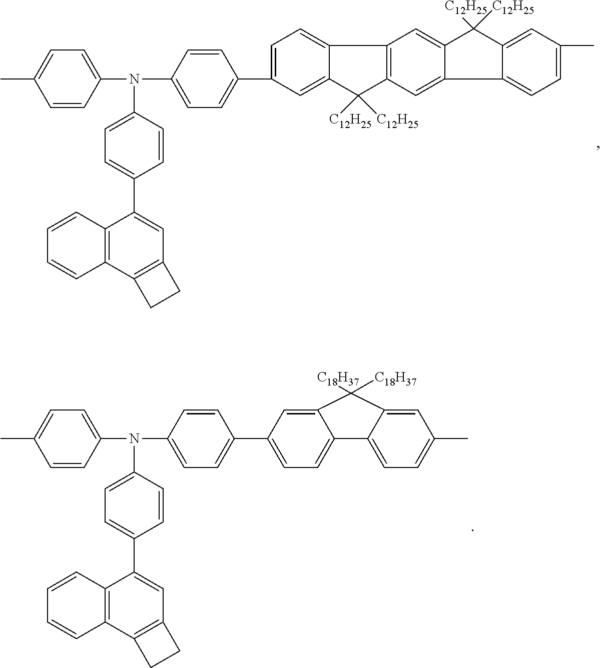

A mole ratio of the structural unit (C) of the polymer compound according to some embodiments is not particularly limited.

From a view point of improving durability (emission lifetime) or any improved effects of hole transport properties of the layer formed by using the obtained polymer compound according to some embodiments, such as, for example, hole transport layer or hole injection layer, the mole ratio of structural unit (C) may be configured to have the mole ratio of structural unit (A) and structural unit (C) (molar ratio of the structural unit (A): structural unit (C)) of, for example, from about 50:50 to about 99:1, for example, from about 80:20 to about 97:3, for example, from about 85:15 to about 95:5.

Meanwhile, if the polymer compound comprises two or more types of structural units (A), the amount of structural units (A) may be a total amount of structural units (A).

Likewise, if the polymer compound comprises two or more types of structural units (C), the amount of structural units (C) may be a total amount of structural units (C).

A terminal end of the main chain of the polymer compound according to some embodiments, for example, at a side near structural unit (A), is not particularly limited and is appropriately defined depending on the type of raw material used, but may usually be a hydrogen atom, a phenyl group, a biphenyl group, a phenyl fluorenyl group, a phenyl indeno fluorenyl group, a group represented by —Ar⁴—Y {Ar⁴ has the same definition as Ar⁴ in formula (1), for example, the same as Ar⁴ in formula (1); and Y is hydrogen atom, phenyl group, biphenyl group, or fluorenyl group}.

### Structural Unit (D)

The polymer compound according to some embodiments may include, in addition to structural unit (4), a structural unit (D) containing structural unit represented by formula (4).

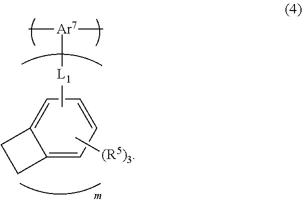

In formula (4), Ar⁷ may be a substituted or unsubstituted aromatic hydrocarbon group having 6 to 60 carbon atoms, or a substituted or unsubstituted aromatic heterocyclic ring group having 3 to 60 ring-forming atoms.

Here, the aromatic hydrocarbon group may be the same as defined in Ar¹ and Ar².

In addition, the aromatic heterocyclic ring group may be the same as defined in Ar⁴.

For example, Ar⁷ may be a group derived from a compound selected from benzene, fluorene, biphenyl, indeno[1,2-b]fluorene, dibenzofuran, dibenzothiophene, or a combination thereof. For example, Ar⁷ may be a group derived from a compound selected from benzene, fluorene, biphenyl, indeno[1,2-b]fluorene, or a combination thereof.

Meanwhile, in some embodiments, Ar⁷ may be unsubstituted, or any one hydrogen atom of Ar⁷ may be substituted with a substituent. For example, Ar⁷ may be a fluorene-derived group, or a group derived from indeno[1,2-b]fluorene, and, for example, may be a fluorene-derived group.

In other words, in some embodiments, Ar⁷ may be selected from Group (II) below:

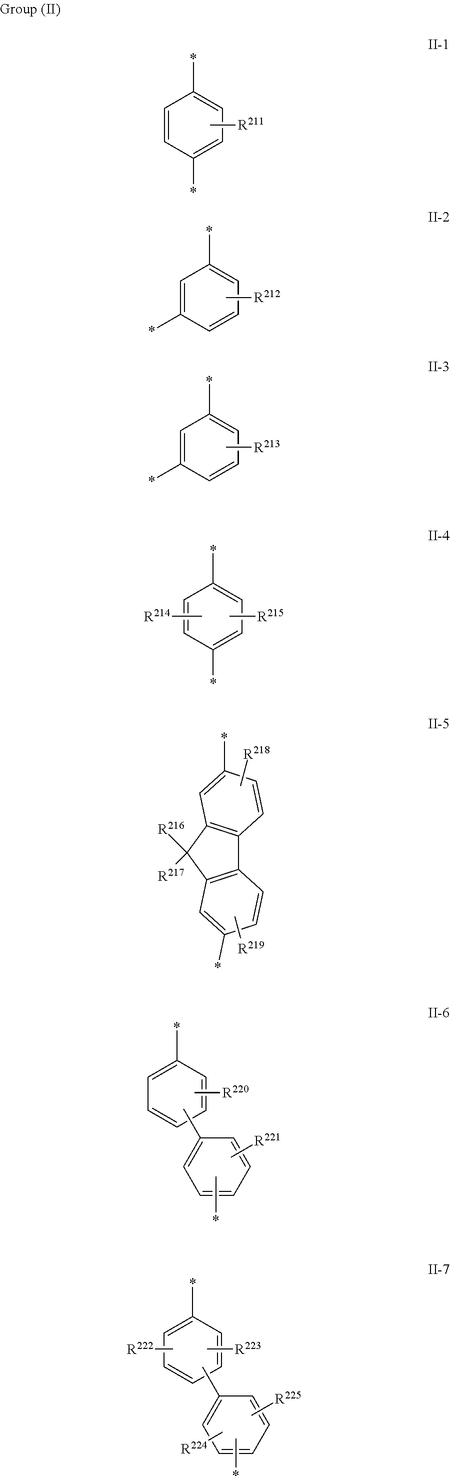

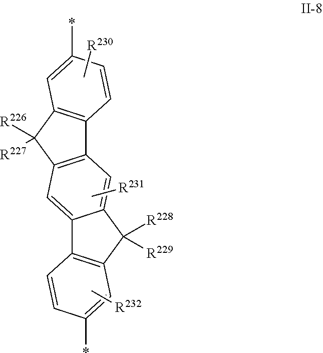

In Group (II), R²¹¹ to R²³² may, each independently, be a hydrogen atom, a straight-chain or branched hydrocarbon group having 1 to 18 carbon atoms, or a group represented by formula (4′) below, as a part of formula (4).

In Group (II) above, II-1 to II-8 should have the group represented by formula (4′).

Additionally, * indicates a bonding position with an adjacent atom.

In formula (4′) below, L¹ and R⁵ may be the same as defined in formula (4).

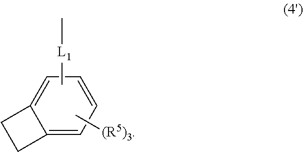

In formula (4′), L¹ may be a single bond, or a saturated hydrocarbon group having 2 to 60 carbon atoms.

Here, the saturated hydrocarbon group having 2 to 60 carbon atoms is not particularly limited.

Specific examples of L¹ (unsubstituted form) may include ethylene group, trimethylene group, propylene group, tetramethylene group, pentamethylene group, hexamethylene group, heptamethylene group, octamethylene group, and the like, and is not limited thereto.

For example, L¹ may be a single bond, or an unsubstituted straight-chain or branched alkylene group with 3 to 12 carbon atoms, for example, a single bond, or an unsubstituted straight-chain alkylene group with 5 to 8 carbon atoms (e.g., for example, it may be a hexamethylene group).

In formula (4′), R⁵ may each independently be a hydrogen atom, an alkyl group, a hydroxyalkyl group, an alkoxy group, an alkoxyalkyl group, an alkenyl group, an alkynyl group, an alkylthio group, an alkoxycarbonyl group, an hydroxyl group (—OH), a carboxyl group (—COOH), a thiol group (—SH), or a cyano group (—CN).

Specific examples as R⁵ may be the same as those for substituents that may exist when Ar¹ or Ar² possesses a substituent.

In addition, R⁵ may form a ring with another R⁵ or with a carbon atom in a benzene ring to which R⁵ is bonded (i.e., substituted by R⁵).

Also, R⁵ may be a hydrogen atom or an alkenyl group, and may also form a ring with a carbon atom in a benzene ring.

R⁵ may be a hydrogen atom (crosslinkable group is a group derived from bicyclo[4.2.0]octa-1,3,5-triene), or may form a crosslinkable group derived from 1,2-dihydrocyclobuta[a]naphthalene or 1,2-dihydrocyclorobuta[b]naphthalene formed by linking 1,3-butadienyl group to the benzene ring, for example, R⁵ may be a hydrogen atom (crosslinkable group is a group derived from bicyclo[4.2.0]octa-1,3,5-triene), or may form a crosslinkable group derived from 1,2-dihydrocyclobuta[a]naphthalene by linking 1,3-butadienyl group to the benzene ring. The crosslinkable group may include, for example, the following structures:

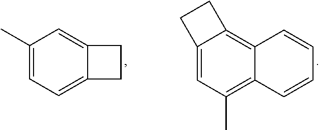

In formula (4), m may be 1 or 2, and for example, m may be 2.

The polymer compound according to some embodiments may include, in addition to structural unit represented by formula (4) as a structural unit (D), a structural unit represented by the following formula:

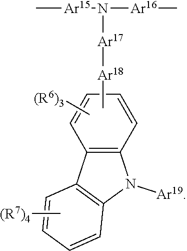

In one embodiment, the polymer compound according to some embodiments may include a structural unit represented by formula (1), and a structural unit represented by formula (7) below:

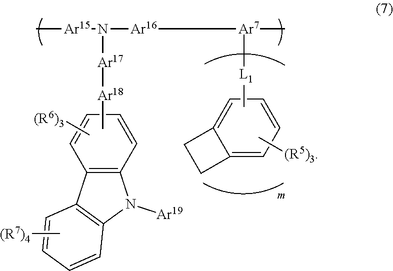

In formula (7) above, L¹, R⁵, and m may be the same as defined in formula (4).

Ar⁷ may be selected from Group (II) below. For example, Ar⁷ may be II-5 below, where R²¹⁶ and R²¹⁷ may, each independently, be a crosslinkable group, and R²¹⁸ and R²¹⁹ may, each independently, be hydrogen atoms.

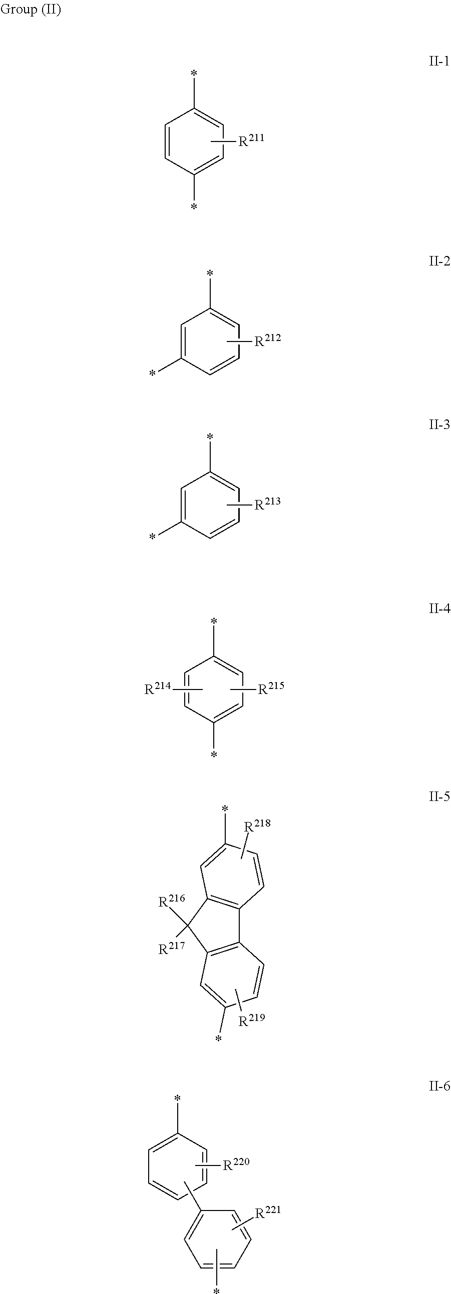

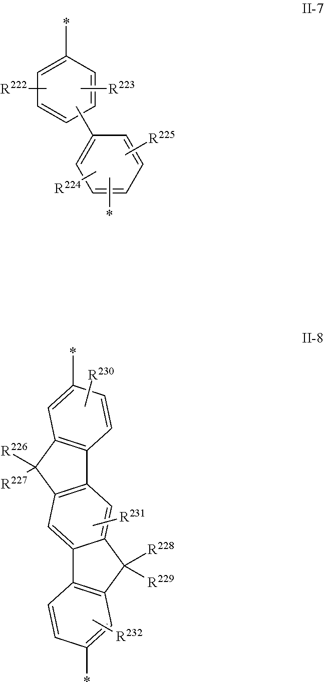

In Group (II), R²¹¹ to R²³² may, each independently, be a hydrogen atom, a straight-chain or branched hydrocarbon group having 1 to 18 carbon atoms, or a part of formula (4).

In one embodiment, R²¹¹ to R²³² may, each independently, be a hydrogen atom, or a straight-chain or branched hydrocarbon group having 1 to 18 carbon atoms.

In one embodiment, R²¹¹ to R²³² may, each independently, be a part of formula (4).

In the above Group (II), II-1 to II-8 must include the structure below.

Additionally, * indicates a bonding position with an adjacent atom.

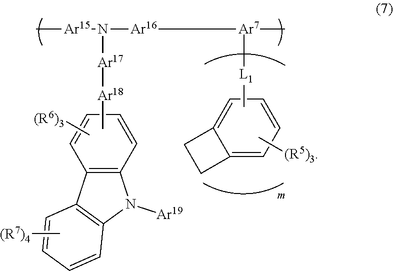

In formula (7) above, Ar¹⁵ and Ar¹⁶ may, each independently, be a substituted or unsubstituted aromatic hydrocarbon group having 6 to 60 carbon atoms.

Here, Ar¹⁵ and Ar¹⁶ may be the same as or different from each other. At this time, Ar¹⁵ and Ar¹⁶ may have the same examples as Ar¹ and Ar². For example, Ar¹⁵ and Ar¹⁶ may be the same as Ar¹ and Ar².

In formula (7), Ar¹⁷ may be a substituted or unsubstituted aromatic hydrocarbon group having 6 to 120 carbon atoms, for example, a substituted or unsubstituted aromatic hydrocarbon group having 6 to 60 carbon atoms. Ar¹⁷ may have the same examples as Ar³ in formula (1). For example, Ar¹⁷ may be the same as Ar³ in formula (1).

In formula (7), Ar¹⁸ may be a single bond, or a substituted or unsubstituted aromatic heterocyclic ring having 3 to 60 ring-forming atoms. Ar¹⁸ may have the same examples as Ar⁵ in formula (1). For example, Ar¹⁸ may be the same as Ar⁵ in formula (1).

In formula (7), Ar¹⁹ may be a substituted or unsubstituted aromatic hydrocarbon group having 6 to 60 carbon atoms, or a substituted or unsubstituted aromatic heterocyclic ring group having 3 to 60 ring-forming atoms. Ar¹⁹ may have the same examples as Ar⁶ in formula (1). For example, Ar¹⁹ may be the same as Ar⁶ in formula (1).

In formula (7), R⁶ may, independently, be a hydrogen atom, an alkyl group, a hydroxyalkyl group, an alkoxy group, an alkoxyalkyl group, an alkenyl group, an alkynyl group, an alkyl thio group, an alkoxy carbonyl group, a hydroxyl group (—OH), a carboxyl group (—COOH), a thiol group (—SH), or a cyano group (—CN). R⁶ may have the same examples as R¹ in formula (1). For example, R⁶ may be the same as R¹ in formula (1).

In formula (7), R⁷ may independently be a hydrogen atom, an alkyl group, a hydroxyalkyl group, an alkoxy group, an alkoxyalkyl group, an alkenyl group, an alkynyl group, an alkylthio group, an alkoxy carbonyl group, a hydroxyl group (—OH), a carboxyl group (—COOH), a thiol group (—SH), or a cyano group (—CN). At this time, R⁷ may have the same examples as R² in formula (1). For example, R⁷ may be the same as R² in formula (1).

For example, structural unit (D) may be selected from the following group:

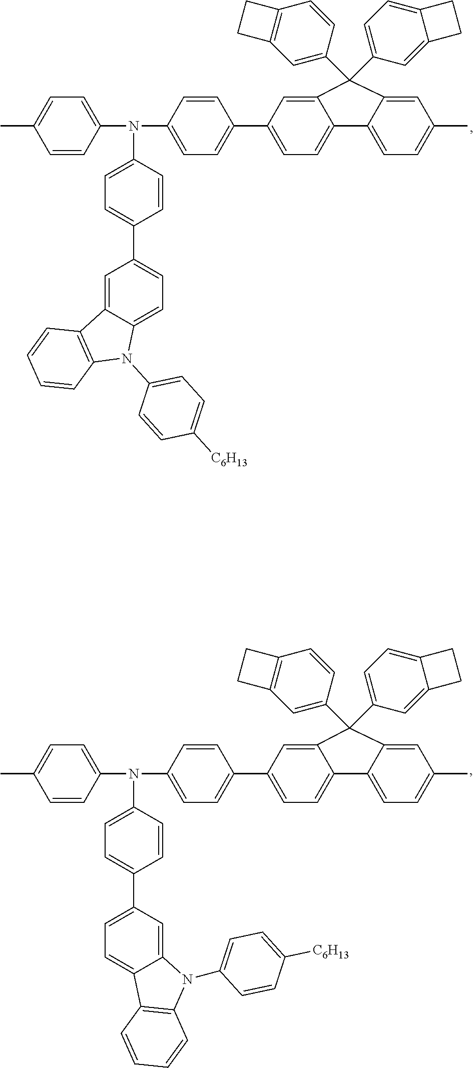

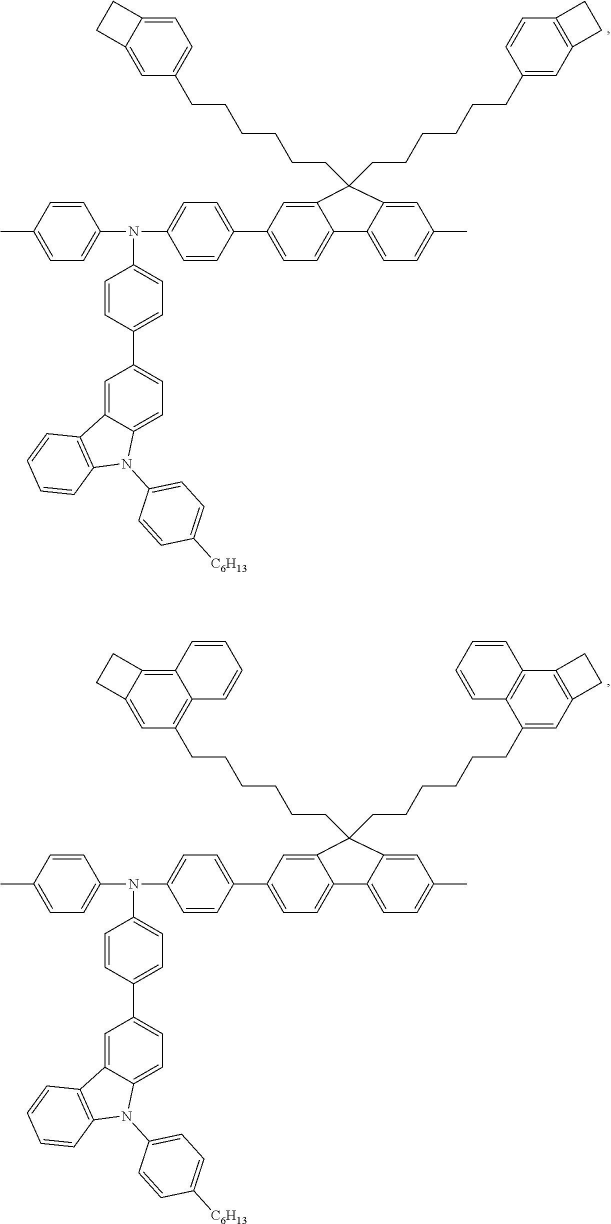

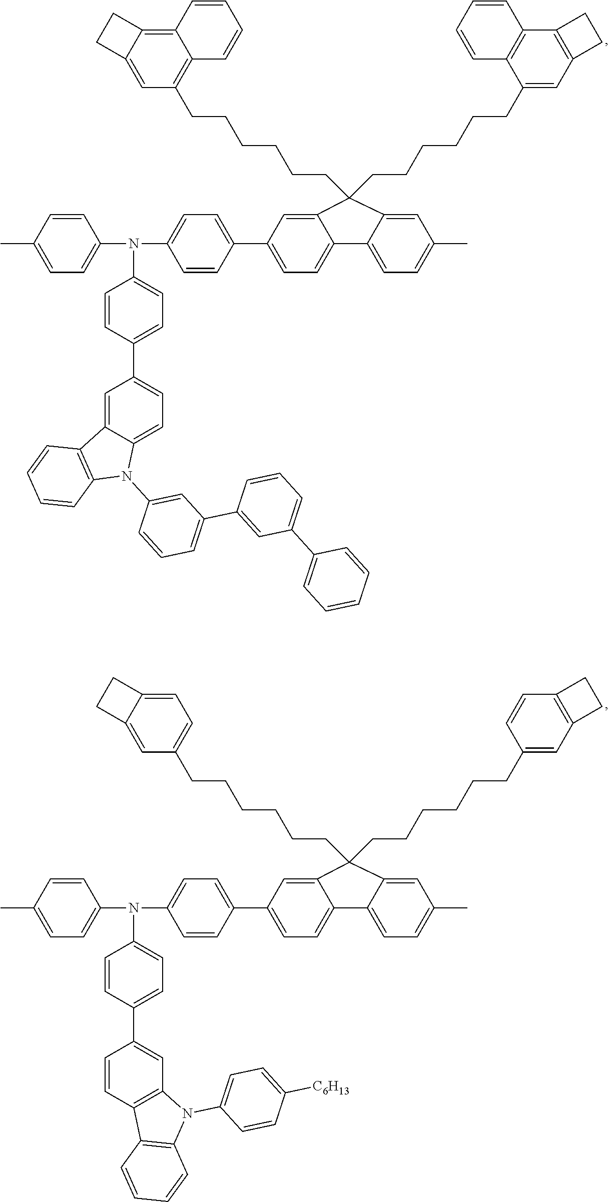

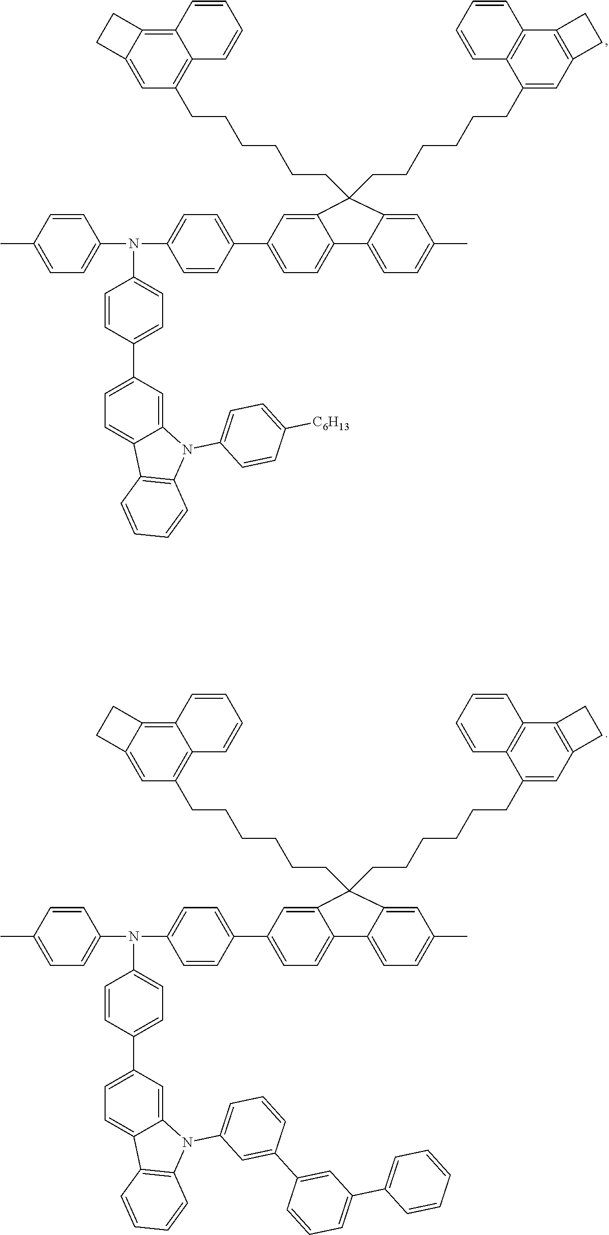

A mole ratio of the structural unit (D) of the polymer compound according to some embodiments is not particularly limited.

From a view point of improving durability (emission lifetime) or any improved effects of hole transport properties of the layer formed by using the obtained polymer compound according to some embodiments, such as, for example, hole transport layer or hole injection layer, the mole ratio of structural unit (D) may be configured to have the mole ratio of structural unit (A) and structural unit (D) (molar ratio of the structural unit (A): structural unit (D)) of, for example, from about 50:50 to about 99:1, for example, from about 80:20 to about 97:3, for example, from about 85:15 to about 95:5.

Meanwhile, if the polymer compound comprises two or more types of structural units (A), the amount of structural units (A) may be a total amount of structural units (A).

Likewise, if the polymer compound comprises two or more types of structural units (D), the amount of structural units (D) may be a total amount of structural units (D).

A terminal end of the main chain of the polymer compound according to some embodiments is not particularly limited and is appropriately defined depending on the type of raw material used, but is usually a hydrogen atom, a phenyl group, a biphenyl group, a phenyl fluorenyl group, a phenylindeno fluorenyl group, a group represented by —Ar⁴—Y {Ar⁴ has the same definition as Ar⁴ in formula (1) above, for example, may be the same as Ar⁴ in formula (1); Y is a hydrogen atom, a phenyl group, a biphenyl group, or a fluorenyl group}, or a group represented by formula (4) in which one end is Y′ (Y′ is a hydrogen atom, a phenyl group, a biphenyl group, or a fluorenyl group).

A polymer compound according to some embodiments may consist of only a structural unit (A), and at least one of structural unit (B) to structural unit (D).

Alternatively, the polymer compound according to some embodiments may further include another structural unit in addition to the structural units above.

When further including another structural unit, the another structural unit is not particularly limited as long as it does not impede the effects of the polymer compound according to some embodiments, such as, for example, durability, high triplet energy level, low driving voltage, and the like. For example, the another structural unit may be a structural unit selected from the following group:

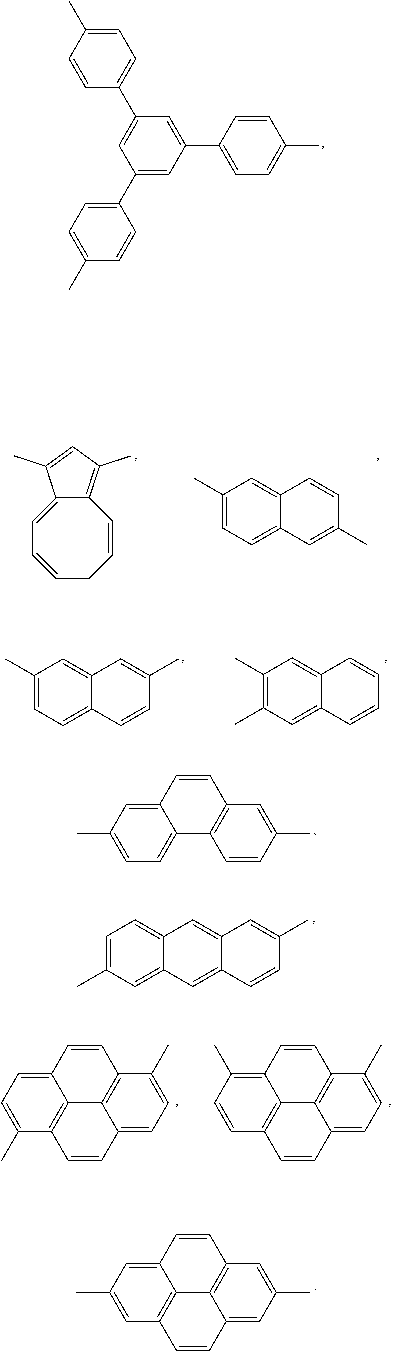

When the polymer compound according to some embodiments includes another structural unit, a content of the another structural unit is not particularly limited.

From a view point of improving durability (emission lifetime) or any improved effects of hole transport properties of the layer formed by using the obtained polymer compound according to some embodiments, such as, for example, hole transport layer or hole injection layer, the content of the another structural unit may be greater than 0 mole and less than 20 moles based on 100 moles of the total amount of structural unit (A), and structural unit (B) to structural unit (D). For example, a content of the another structural unit may be greater than 0 mole and less than or equal to 15 moles, or greater than 0 mole and less than or equal to 10 moles based on 100 moles of the total amount of structural unit (A), and structural unit (B) to structural unit (D), and is not limited thereto.

If the polymer compound comprises two or more types of the another structural units, the amount of the another structural units may be a total amount of the another structural units.

Meanwhile, if the polymer compound comprises two or more types of structural units (A), the amount of structural units (A) may be a total amount of structural units (A).

Likewise, if the polymer compound comprises two or more types of structural unit (B) to structural unit (D), the amount of structural unit (B) to structural unit (D) may be a total amount of structural unit (B) to structural unit (D).

The weight average molecular weight (Mw) of the polymer compound according to some embodiments is not particularly restricted as long as the effect of the invention is achieved. The weight average molecular weight (Mw) may be, for example, from about 5,000 gram/mole to about 1,000,000 gram/mole, from about 12,000 gram/mole to about 1,000,000 gram/mole, from about 20,000 gram/mole to about 800,000 gram/mole, or from about 50,000 gram/mole to about 500,000 gram/mole, and is not limited thereto.

With this weight average molecular weight, a viscosity of a coating solution containing the polymer compound according to some embodiments and for preparing a layer (e.g., hole injection layer or a hole transport layer) may appropriately be adjusted and it is possible to obtain uniform film thickness.

In addition, the number average molecular weight (Mn) of the polymer compound according to some embodiments is not particularly restricted as long as the effect of the invention is achieved. The number average molecular weight (Mn) of the polymer compound according to some embodiments may be, for example, from about 4,000 gram/mole to about 250,000 gram/mole, from about 10,000 gram/mole to about 250,000 gram/mole, from about 20,000 gram/mole to about 150,000 gram/mole, or from about 30,000 to about 100,000 gram/mole, and it is not limited thereto.

With this number average molecular weight, a viscosity of a coating solution containing the polymer compound according to some embodiments and for preparing a layer (e.g., hole injection layer or a hole transport layer) may appropriately be adjusted and it is possible to obtain uniform film thickness.

In addition, a polydispersity (weight average molecular weight/number average molecular weight) of the polymer compound according to some embodiments may be, for example, 1.2 or more and 7.0 or less, for example, 1.2 or more and 6.0 or less, or for example, 1.5 or more and 3.5 or less.

In the context of the specification, the determining method of number average molecular weight (Mn) or weight average molecular weight (Mw) is not particularly limited, and a method known in the art to which the invention pertains may appropriately be used or modified to be used to determine number average molecular weight (Mn) or weight average molecular weight (Mw) the polymer compound according to some embodiments.

In this specification, the number average molecular weight (Mn) and the weight average molecular weight (Mw) may be measured by a method described below.

Meanwhile, polydispersity (Mw/Mn) of the polymer may be calculated by dividing the weight average molecular weight (Mw) by the number average molecular weight (Mn) measured by the method.

Measurement of number average molecular weight (Mn) and weight average molecular weight (Mw)

Number average molecular weight (Mn) and weight average molecular weight (Mw) of a polymer compound may be measured by using a size exclusion chromatography (SEC) using polystyrene as a standard material under the following conditions:

### SEC Measurement Conditions

Analytical device (SEC): Shimadzu Seisakusho product, Prominence
Column: Polymer Laboratories Ltd., PLgel MIXED-B
Column temperature: 40° C.
Flow rate: 1.0 mL/minute (mL/min)
Sample solution: 20 μL (polymer concentration: Approximately 0.05% by mass)
Eluent: Tetrahydrofuran (THF)
Detector (UV-VIS detector): Shimadzu Seisakusho product, SPD-10AV
Standard Sample: Polystyrene

The polymer compound according to some embodiments may be synthesized by using a known organic synthesis method.

An example of synthesis method of the polymer compound according to some embodiment may easily be understood by those skilled in the art by referring to the method described in JP 2021-138915A and the Examples described hereinafter.

Specifically, the polymer compound according to some embodiments may be obtained by polymerization reaction using a monomer containing structural unit (A), and at least one structural unit of structural units (B) to (D) to be used, or by copolymerization reaction using at least one monomer corresponding to structural unit (A), and at least one monomer corresponding to at least one of structural units (B) to (D) to be used.

The polymer compound according to some embodiments includes structural unit (A). Therefore, the corresponding polymer compound may have high hole injection properties. Accordingly, when the polymer compound according to some embodiments may be used as a hole injection material or a hole transport material (for example, a hole transport material), high durability (luminescence lifetime) may be achieved.

Additionally, the polymer compound according to some embodiments may have a high triplet energy level, and, at the same time, have a low driving voltage. Therefore, when the polymer compound according to some embodiments may be used as a hole injection material or a hole transport material (e.g., a hole transport material), high hole mobility may be achieved with a low driving voltage. Therefore, an electroluminescence device containing the polymer compound according to an embodiment may have excellent durability (luminescence lifespan) and luminous efficiency.

In addition, the polymer compound according to some embodiments may have a hole transport structural unit (A), and a crosslinkable structural unit represented by at least one of formulas (2) to (4) may be apart from each other. Due to this, the crosslinking site (reaction point) does not inhibit hole transport properties, which does not deteriorate after crosslinking. Therefore, an electroluminescence device formed by using a polymer compound according to some embodiments (for example, in a hole transport layer or a hole injection layer) may also have excellent durability.

In addition, the polymer compound according to some embodiment may have a high solvent resistance (e.g., solvent, such as, for example, xylene, cyclohexylbenzene, etc.). Due to this, even if a layer is formed on another layer by a wet method using a solution containing the polymer compound according to some embodiments, membrane mixing between the layer containing the polymer compound and the another layer on which the layer containing the polymer compound is formed may be inhibited.

For example, even if an electroluminescence device is manufactured by using a solution coating method (e.g., inkjet printing method), in which the solution contains a polymer compound according to some embodiments, layer mixing between the layer containing the polymer compound and another layer adjacent to the layer containing the polymer compound may be inhibited. Therefore, an electroluminescence device in which an organic film (e.g., a hole transport layer or a hole injection layer) is formed by a solution coating method (e.g., inkjet printing method) using a polymer compound according to some embodiments can exhibit excellent durability.

### Composition

Another embodiment provides a composition containing the polymer compound according to some embodiment.

Additionally, as another embodiment, a composition containing an EL device material according to some embodiments may be provided.

The polymer compound according to some embodiments may be used in only one type, or a mixture of two or more types of the polymer compound may also be used.

The composition according to some embodiments may further include other compounds in addition to the polymer compound according to some embodiments. The other compounds are not particularly limited, but may be, for example, at least one type of material selected from hole transport materials, electron transport materials, and light-emitting materials. That is, some embodiments provide a composition comprising a polymer compound according to some embodiments and at least one material selected from hole transport materials, electron transport materials, and light-emitting materials. Here, the light-emitting material included in the composition is not particularly limited, but may include an organic metal complex (luminescent organic metal complex compound) or semiconductor nanoparticles (e.g., semiconductor inorganic nanoparticles etc.).

In other words, the composition according to some embodiments may contain organometallic complexes. Alternatively, a composition according to some embodiments may include semiconductor nanoparticles.

As described above, the polymer compound according to some embodiments may be used in an electroluminescence device. Accordingly, an electroluminescence device that may exhibit a long lifespan may be obtained by the composition according to some embodiments.

The polymer compound according to some embodiments has a good solvent-resistance (e.g., for solvents, such as, xylene, cyclohexylbenzene, etc.).

Therefore, the polymer compound (or a composition containing the polymer compound) according to some embodiments may be suitable for forming an organic film by using an inkjet method. In other words, the polymer compound (or composition containing the polymer compound) according to some embodiments may be used, for example, for inkjet applications.

### Organic Membrane

Another embodiment provides an organic film containing a polymer compound according to some embodiments. In other words, an embodiment provides an organic film containing a polymer compound according to some embodiments.

### Electroluminescence Device Materials

The polymer compound according to some embodiment may be used, for example, as an electroluminescence device material.

The polymer compound according to some embodiments may also be used as an electroluminescence device material with excellent durability (luminescence lifespan). Additionally, the polymer compound according to some embodiments may provide an electroluminescence device material with high hole mobility. The polymer compound according to some embodiments may also have a high triplet energy level (current efficiency) and a low driving voltage.

Additionally, the main chain of the polymer compound according to some embodiments may have appropriate flexibility. Due to this, the polymer compound according to some embodiments may exhibit high solubility in solvents and high heat resistance. In addition, an organic film containing a polymer compound according to some embodiments may have a good solvent-resistance (for solvents, such as, xylene, cyclohexylbenzene, etc.) of the organic film, such as, for example, a hole transport layer or a hole injection layer. Therefore, a film (for example, a thin film) may easily be formed by a solution application method (e.g., inkjet method, etc.).

Therefore, some embodiments provide an electroluminescence device material containing the polymer compound according to some embodiment. Alternatively, use of the polymer compound according to some embodiments as an electroluminescence device material may be provided.

In addition, the polymer compound according to some embodiments may have a low HOMO level of less than −5.20 electron volts (eV), for example, less than −5.33 eV. Due to this, the polymer compound according to some embodiments may also advantageously used in a quantum dot electroluminescence device (e.g., in a hole transport layer).

### Electroluminescence Device

As already described, the polymer according to an embodiment may be desirably used in an electroluminescence device. That is, provided is an electroluminescence device including a pair of electrodes and one or more layers of organic film disposed between the electrodes and including the polymer or electroluminescence device material of an embodiment. Accordingly, the electroluminescence device may exhibit good luminous efficiency, for example, good luminous efficiency at a low driving voltage.

According to some embodiments, an electroluminescence device includes a first electrode, a second electrode, and one or more layers of organic film disposed between the first electrode and the second electrode, wherein at least one of the one or more layers of the organic film includes the polymer of an embodiment.

The object or effect of the present disclosure may also be achieved by the electroluminescence device according to this embodiment. As an example of the above embodiment, the electroluminescence device further includes a light emitting layer between the electrodes and including a light emitting material capable of emitting light as a triplet exciton. Meanwhile, the electroluminescence device of the present embodiment is an example of an electroluminescence device according to an embodiment.

Further, an embodiment of the present disclosure provides a method for manufacturing an electroluminescence device including a pair of electrodes and one or more layers of organic films disposed between the pair of electrodes and including the polymer compound according to some embodiments, wherein at least one of the one or more layers of organic films is formed by a coating method. In other words, an embodiment of the present disclosure provides a method for manufacturing an electroluminescence device including a first electrode, a second electrode, and one or more layers of organic films disposed between the first electrode and the second electrode and including the polymer compound according to some embodiments, wherein at least one of the one or more layers of organic films is formed by coating a solution containing the polymer compound and a solvent to a layer adjacent to the at least one of the one or more layers of organic films to form a coated layer, and removing the solvent (by, for example, drying or heating) from the coated layer. According to this method, the embodiment of the present disclosure provides an electroluminescence device in which at least one layer of the organic films is formed by a coating method, such as, for example, inkjet method, etc.

The polymer compound and the electroluminescence device material (EL device material) according to an embodiment (hereinafter, collectively referred to as “polymer/EL device material”) also have good solubility in organic solvents. Because of this, the polymer/EL device material according to an embodiment may be advantageously used for manufacturing a device, for example, applied as a thin film by a coating method (wet process). Accordingly, an embodiment of the present disclosure provides a liquid composition including the polymer of an embodiment, and a solvent or dispersion medium. The liquid composition of the present embodiment is an example of the liquid composition according to an embodiment.

In addition, the electroluminescence device material according to the above embodiments may be advantageously used for manufacturing a device, for example, a thin film, by a coating method (wet process). In view of the above, an embodiment of the present invention provides a thin film including the polymer of an embodiment. Meanwhile, the thin film of this embodiment is one example of the thin film according to an embodiment.

In addition, the EL device material according to the embodiment has improved hole injectability and hole mobility. For this reason, it can be advantageously used in the formation of any organic film such as a hole injection material, a hole transport material, or a light emitting material (host). Since it can be used as a hole injection material or a hole transport material from the viewpoint of hole transport properties, it may be advantageously used as a hole transport material.

In other words, an embodiment of the present invention provides a composition including the polymer compound according to some embodiments and at least one material selected from a hole transport material, an electron transport material, and a light emitting host material. Herein, the light emitting material included in the composition is not particularly limited but may include organometallic complexes (luminescent organometallic complex compounds, e.g., phosphorescent emitter compounds) or semiconductor nanoparticles (semiconductor inorganic nanoparticles or quantum dots).

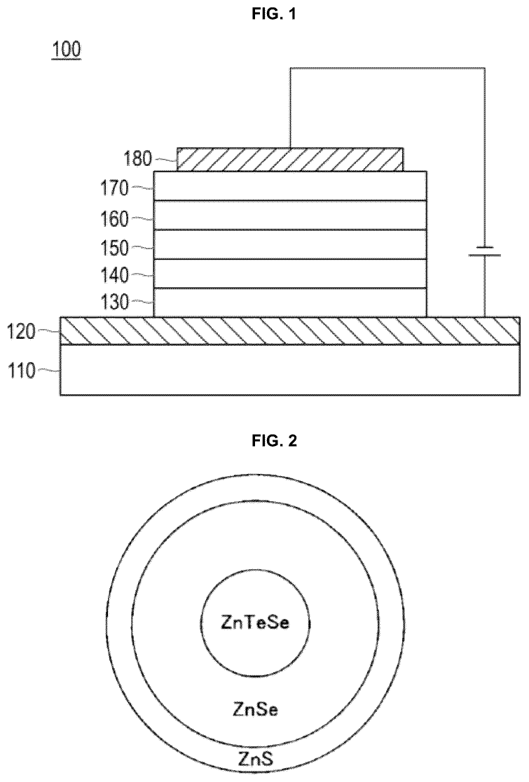

Hereinafter, an electroluminescence device according to an embodiment will be described in detail with reference to FIG. 1. FIG. 1 is a schematic view showing an electroluminescence device according to the present embodiment. As shown, an EL device 100 according to an embodiment includes a substrate 110, a first electrode 120 on the substrate 110, a hole injection layer 130 on the first electrode 120, a hole transport layer 140 on the hole injection layer 130, a light emitting layer 150 on the hole transport layer 140, an electron transport layer 160 on the light emitting layer 150, an electron injection layer 170 on the electron transport layer 160, and a second electrode 180 on the electron injection layer 170.

Herein, the polymer/EL device material of this embodiment is included in any one organic film (organic layer) between the first electrode 120 and the second electrode 180. For example, the polymer/EL device material may be included in the hole injection layer 130 as a hole injection material, in the hole transport layer 140 as a hole transport material, or in the light emitting layer 150 as a light emitting material (host). For example, the polymer/EL device material may be included in the hole injection layer 130 as a hole injection material or in the hole transport layer 140 as a hole transport material. For example, the polymer/EL device material may be included in the hole transport layer 140 as a hole transport material. In other words, in an embodiment, the organic film including the polymer/EL device material may be a hole transport layer, a hole injection layer, or a light emitting layer (host).

In an embodiment of the present disclosure, the organic film including the polymer/EL device material is a hole transport layer or a hole injection layer.

In an embodiment of the present disclosure, the organic film including the polymer/EL device material is a hole transport layer.

In addition, the organic film including the polymer/EL device material of the present embodiment may be formed by a coating method (solution coating method). For example, the organic film may be formed by using a solution coating method such as a spin coating method, a casting/casting method, a micro gravure coating method, a gravure coating method, a bar coating method, a roll coating method, a wire bar coating method, a dip coating method, a spray coating method, a screen printing method, a flexographic printing method, an offset printing method, or an ink jet printing method. However, the method for forming a layer other than the organic film including the polymer/EL device material is not particularly limited.

Meanwhile, the solvent used in the solution coating method is not particularly limited as long as it can dissolve the polymer/EL device material and may be appropriately selected depending on the type of used polymer/EL device material. For example, it may be toluene, xylene, ethyl benzene, diethylbenzene, mesitylene, propyl benzene, cyclohexyl benzene, dimethoxy benzene, anisole, ethoxy toluene, phenoxy toluene, isopropyl biphenyl, dimethyl anisole, phenyl acetate, phenyl propionate, methyl benzoate, ethyl benzoate, cyclohexane, and the like.

In addition, the amount of the solvent used is not particularly limited, but considering the ease of coating and the like, a concentration of the polymer/EL device material may be, for example, greater than or equal to about 0.1 weight percent (wt %) and less than or equal to about 10 wt %, for example, greater than or equal to about 0.5 wt % and less than or equal to about 5 wt %.

Layers other than the organic film including the polymer/EL device material of the present embodiment may be formed, for example, by a vacuum deposition method or a solution coating method.

The substrate 110 may be a substrate used in a general EL device. For example, the substrate 110 may be a semiconductor substrate such as a glass substrate, a silicon substrate, and the like, or a transparent plastic substrate. The first electrode 120 is formed on the substrate 110. The first electrode 120 is specifically an anode, and is formed by a material having a large work function among a metal, an alloy, or a conductive compound. For example, the first electrode 120 may be formed as a transmissive electrode by indium tin oxide (In₂O₃—SnO₂: ITO), indium zinc oxide (In₂O₃—ZnO), tin oxide (SnO₂), zinc oxide (ZnO) or the like due to improved transparency and conductivity.

The first electrode 120 may be formed as a reflective electrode by laminating magnesium (Mg), aluminum (Al), or the like on the transparent conductive layer. Further, after forming the first electrode 120 on the substrate 110, cleaning and UV-ozone treatment may be performed, if necessary.

On the first electrode 120, the hole injection layer 130 is formed. The hole injection layer 130 is a layer that facilitates injection of holes from the first electrode 120, and may be formed to have a thickness (dry film thickness, the same below) of specifically greater than or equal to about 10 nanometers (nm) and less than or equal to about 1000 nm, or greater than or equal to about 20 nm and less than or equal to about 50 nm.

The hole injection layer 130 may be formed of a known hole injection material. The known hole injection material of the hole injection layer 130 may include, for example, triphenylamine-containing poly(ether ketone) (TPAPEK), 4-isopropyl-4′-methyldiphenyl iodonium tetrakis(pentafluorophenyl)borate (PPBI), N,N′-diphenyl-N,N′-bis-[4-(phenyl-m-tolyl-amino)-phenyl]-biphenyl-4,4′-diamine (DNTPD), copper phthalocyanine, 4,4′,4″-tris(3-methylphenylphenylamino)triphenylamine (m-MTDATA), N,N′-di(1-naphthyl)-N,N′-diphenylbenzidine (NPB), 4,4′,4″-tris(diphenylamino)triphenylamine (TDATA), 4,4′,4″-tris(N,N-2-naphthylphenylamino)triphenylamine (2-TNATA), polyaniline/dodecylbenzenesulphonic acid, poly(3,4-ethylenedioxythiophene)/poly(4-styrenesulfonate) (PEDOT/PSS), polyaniline/10-camphorsulfonic acid, and the like.

The hole transport layer 140 is formed on the hole injection layer 130. The hole transport layer 140 is a layer having a function of transporting holes, and may be formed with a thickness of, for example, greater than or equal to about 10 nm and less than or equal to about 150 nm, and for example greater than or equal to about 20 nm and less than or equal to about 50 nm. In an embodiment, the hole transport layer 140 may be formed by a solution coating method using the polymer/EL device material according to the present embodiment. According to this method, the durability of the EL device 100 (luminescence lifespan, etc.) may be further improved. It is also possible to improve the current efficiency of the EL device 100 and reduce the driving voltage. In addition, since the hole transport layer may be formed by the solution coating method, a large area may be formed efficiently.

When any one other organic film of the EL device 100 includes the polymer/EL device material according to the present embodiment, the hole transport layer 140 may be formed of a known hole transport material. The known hole transport material may be, for example, 1,1-bis[(di-4-tolylamino)phenyl]cyclohexane (TAPC), carbazole derivatives such as N-phenylcarbazole and polyvinyl carbazole, and the like, N,N′-bis(3-methylphenyl)-N,N′-diphenyl-[1,1-biphenyl]-4,4′-diamine (TPD), 4,4′,4″-tris(N-carbazolyl) triphenylamine (TCTA), N,N′-di(1-naphthyl)-N,N′-diphenylbenzidine (NPB), and the like.

The light emitting layer 150 is formed on the hole transport layer 140. The light emitting layer 150 is a layer that emits light by fluorescence or phosphorescence, and may be formed using a vacuum deposition method, a spin coating method, an inkjet printing method, or the like. The light emitting layer 150 may have a thickness of, for example, greater than or equal to about 10 nm and less than or equal to about 60 nm, for example, greater than or equal to about 20 nm and less than or equal to about 50 nm. The light emitting material of the light emitting layer 150 is not particularly limited and a well-known light emitting material may be used. The light emitting material included in the light emitting layer 150 may be, for example, a light emitting material capable of emitting light from triplet excitons (i.e., phosphorescent light emission). In this case, the driving lifespan of the EL device 100 may also be improved.

The light emitting layer 150 is not particularly limited and may have a known configuration. For example, the light emitting layer may include semiconductor nanoparticles or organometallic complexes. In other words, in an embodiment, the organic film has a light emitting layer including semiconductor nanoparticles or organometallic complexes. Meanwhile, when the light emitting layer includes the semiconductor nanoparticles, the EL device is a quantum dot electroluminescence device (QLED) or a quantum dot light emitting device. In the case where the light emitting layer includes the organometallic complexes, the EL device is an organic electroluminescence device (OLED).

In the embodiment (QLED) in which the light emitting layer includes semiconductor nanoparticles, the light emitting layer may include a plurality of semiconductor nanoparticles (quantum dots) arranged in a single layer or a plurality of layers. Herein, the semiconductor nanoparticles (quantum dots) are particles of a predetermined size having a quantum confinement effect. The diameter (average diameter) of the semiconductor nanoparticles (quantum dots) is not particularly limited but may be greater than or equal to about 1 nm and less than or equal to about 10 nm.

The semiconductor nanoparticles (quantum dots) arranged in the light emitting layer may be synthesized by a wet chemical process, an organometallic chemical vapor deposition process, a molecular beam epitaxy process, or other similar processes. Among them, the wet chemical process is a method of growing particles by adding a precursor material to an organic solvent.

In the wet chemical process, when the crystal is grown, the organic solvent is naturally coordinated on the surface of the quantum dot crystal to act as a dispersant, thereby controlling the growth of the crystal. For this reason, the wet chemical processes may be more facile than vapor deposition methods such as metal organic chemical vapor deposition (MOCVD) or molecular beam epitaxy (MBE), and the growth of semiconductor nanoparticles may be controlled at considerably lower cost.

By controlling the size of semiconductor nanoparticles (quantum dots), an energy band gap may be adjusted, and light in various wavelength bands may be obtained from the light emitting layer (quantum dot light emitting layer). Therefore, by using a plurality of quantum dots of different sizes, a display that emits light of a plurality of wavelengths may be manufactured. The size of the quantum dots may be selected to emit red, green, or blue light to constitute a color display. In addition, the size of the quantum dots may be combined to emit white light with various color light (e.g., collectively, blue, green and red).

The semiconductor nanoparticles (quantum dots) may be semiconductor material selected from a Group II-VI semiconductor compound; a Group III-V semiconductor compound; a Group IV-VI semiconductor compound; a Group IV element or compound; and a combination thereof.

The Group Il-VI semiconductor compound is not particularly limited, but includes, for example, a binary compound selected from CdSe, CdTe, ZnS, ZnSe, ZnTe, ZnO, HgS, HgSe, HgTe, and a mixture thereof; a ternary compound selected from CdSeS, CdSeTe, CdSTe, ZnSeS, ZnTeSe, ZnSTe, HgSeS, HgSeTe, HgSTe, CdZnS, CdZnSe, CdZnTe, CdHgS, CdHgSe, CdHgTe, HgZnS, HgZnSe, HgZnTe, and a mixture thereof; or a quaternary compound selected from CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-V semiconductor compound is not particularly limited, but includes, for example, a binary compound selected from GaN, GaP, GaAs, GaSb, AlN, AlP, AlAs, AlSb, InN, InP, InAs, InSb, and a mixture thereof; a ternary compound selected from GaNP, GaNAs, GaNSb, GaPAs, GaPSb, AlNP, AlNAs, AlNSb, AlPAs, AlPSb, InNP, InNAs, InNSb, InPAs, InPSb, and a mixture thereof; or a quaternary compound selected from GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof.

The Group IV-VI semiconductor compound is not particularly limited, but includes, for example, a binary compound selected from SnS, SnSe, SnTe, PbS, PbSe, PbTe, and a mixture thereof; a ternary compound selected from SnSeS, SnSeTe, SnSTe, PbSeS, PbSeTe, PbSTe, SnPbS, SnPbSe, SnPbTe, and a mixture thereof; or a quaternary compound selected from SnPbSSe, SnPbSeTe, SnPbSTe, and a mixture thereof.

The Group IV element or compound is not particularly limited, but includes, for example, a single element selected from Si, Ge, and a mixture thereof; or a binary compound selected from SiC, SiGe, and a mixture thereof.

The semiconductor nanoparticles (quantum dots) may have a homogeneous single structure or a double structure of a core-shell.

The core-shell may include different materials. The materials constituting each core and shell may be made of different semiconductor compounds. However, an energy bandgap of the shell material is larger than an energy bandgap of the core material. For example, it may have a structure of ZnTeSe/ZnSe/ZnS (as shown in FIG. 2), InP/ZnSe/ZnS, CdSe/ZnS, InP/ZnS, and the like.

For example, a process of producing a quantum dot having a core (CdSe)-shell (ZnS) structure is as follows. First, trioctylphosphine oxide (TOPO) is used as a surfactant. A precursor material of the core (CdSe), such as (CH₃)₂Cd (dimethylcadmium) and TOPSe (trioctylphosphine selenide), is injected into an organic solvent to form crystals. At this time, after maintaining a certain time at high temperature so that the crystals grow to a certain size, the precursor materials of the shell (ZnS) are injected, to form a shell on the surface of the core already produced. As a result, a quantum dot of CdSe/ZnS capped with TOPO may be produced.

In addition, in the embodiment (OLED) in which the light emitting layer includes an organometallic complex, the light emitting layer 150 may include, for example, 6,9-diphenyl-9′-(5′-phenyl-[1,1′:3′,1″-terphenyl]-3-yl) 3,3′-bi[9H-carbazole], 3,9-diphenyl-5-(3-(4-phenyl-6-(5′-phenyl-[1,1′:3′,1″-terphenyl]-3-yl)-1,3,5-triazin-2-yl)phenyl)-9H-carbazole, 9,9′-diphenyl-3,3′-bi[9H-carbazole], tris (8-quinolinato)aluminium (Alq3), 4,4′-bis(carbazol-9-yl)biphenyl (CBP), poly(N-vinyl carbazole) (PVK), 9,10-di(naphthalene)anthracene (ADN), 4,4′,4″-tris(N-carbazolyl) triphenylamine (TCTA), 1,3,5-tris(N-phenyl-benzimidazol-2-yl)benzene (TPBI), 3-tert-butyl-9,10-di(naphth-2-yl)anthracene (TBADN), distyrylarylene (DSA), 4,4′-bis (9-carbazole)2,2′-dimethyl-bipheny (dmCBP), and the like, as a host material.

The light emitting layer 150 may include, for example, perylene and a derivative thereof, rubrene and a derivative thereof, coumarin and a derivative thereof, 4-dicyanomethylene-2-(p-dimethylaminostyryl)-6-methyl-4H-pyran (DCM) and a derivative thereof, an iridium (Ir) complex such as bis[2-(4,6-difluorophenyl)pyridinate]picolinate iridium(III) (Flrpic)), bis(1-phenylisoquinoline) (acetylacetonate)iridium(III) (Ir(piq)₂(acac)), tris(2-phenylpyridine)iridium(III) (Ir(ppy)₃), tris(2-(3-p-xylylphenyl)pyridine iridium (III), an osmium (Os) complex, a platinum complex, and the like, as a dopant material. Among these, for example, the light emitting material may be a light emitting organometallic complex compound.

A method for forming the light emitting layer is not particularly limited. It may be formed by coating (solution coating method) coating liquid including the semiconductor nanoparticles or organometallic complex. At this time, a solvent constituting the coating liquid may be a solvent which does not dissolve the materials (hole transport material, particularly polymer compound) in the hole transport layer.

The electron transport layer 160 is formed on the light emitting layer 150. The electron transport layer 160 is a layer having a function of transporting electrons. The electron transport layer is formed using a vacuum deposition method, a spin coating method, an inkjet method. The electron transport layer 160 may be formed to have a thickness of greater than or equal to about 15 nm and less than or equal to about 50 nm.

The electron transport layer 160 may be formed of a known electron transport material. The known electron transport material may include, for example, lithium 8-quinolate (Liq), tris (8-quinolate) aluminum (Alq3), and a compound having a nitrogen-containing aromatic ring. Examples of the compound having the nitrogen-containing aromatic ring may include, for example, a compound including a pyridine ring such as 1,3,5-tri [(3-pyridyl)-phen-3-yl]benzene), a compound including a triazine ring such as 2,4,6-tris(3′-(pyridin-3-yl)biphenyl-3-yl)-1,3,5-triazine), a compound including an imidazole ring such as 2-(4-(N-phenylbenzoimidazol-1-yl-phenyl)-9,10-dinaphthylanthracene or 1,3,5-tris(N-phenyl-benzimidazol-2-yl)benzene (TPBI). The electron transport material may be used alone or as a mixture of two or more.

The electron injection layer 170 is formed on the electron transport layer 160. The electron injection layer 170 is a layer having a function of facilitating injection of electrons from the second electrode 180. The electron injection layer 170 is formed using a vacuum deposition method or the like. The electron injection layer 170 may be formed to have a thickness of greater than or equal to about 0.1 nm and less than or equal to about 5 nm, and more specifically, greater than or equal to about 0.3 nm and less than or equal to about 2 nm.

As a material for forming the electron injection layer 170, any known material may be used. For example, the electron injection layer 170 may be formed of a lithium compound such as (8-quinolinato) lithium (lithium quinolate, Liq) and lithium fluoride (LiF), sodium chloride (NaCl), cesium fluoride (CsF), lithium oxide (Li₂O), or barium oxide (BaO).

The second electrode 180 is formed on the electron injection layer 170. The second electrode 180 is formed using a vacuum deposition method or the like. The second electrode 180 may be, for example, a cathode, and may be formed of a metal, an alloy, or a conductive compound having a small work function. For example, the second electrode 180 may be formed as a reflective electrode with a metal such as lithium (Li), magnesium (Mg), aluminum (Al), calcium (Ca), or an alloy such as aluminum-lithium (Al—Li), magnesium-indium (Mg—In), magnesium-silver (Mg—Ag), or the like. The second electrode 180 may be formed to have a thickness of greater than or equal to about 10 nm and less than or equal to about 200 nm, and more and specifically, greater than or equal to about 50 nm and less than or equal to about 150 nm. Alternatively, the second electrode 180 may be formed as a transmissive electrode by a thin film of less than or equal to about 20 nm of a metal material or a transparent conductive layer such as indium tin oxide (In₂O₃—SnO₂), and indium zinc oxide (In₂O₃—ZnO).

In the above, the EL device 100 according to an embodiment has been described as an example of an electroluminescence device according to an embodiment. In the EL device 100 according to an embodiment, durability (luminescence lifespan, etc.) may be further improved by disposing an organic film (particularly, a hole transport layer or a hole injection layer) including the polymer. In addition, the luminous efficiency (current efficiency) may be further improved and the driving voltage may be reduced.

The stacked structure of the EL device 100 according to an embodiment is not limited to the above embodiments.

The EL device 100 according to an embodiment may also be formed in other known stacked structures. For example, in the EL device 100, one or more of the hole injection layer 130, the hole transport layer 140, the electron transport layer 160, and the electron injection layer 170 may be omitted, or an additional layer may be further provided. In addition, each layer of the EL device 100 may be formed as a single layer or may be formed as a plurality of layers.

For example, the EL device 100 may further include a hole blocking layer between the electron transport layer 160 and the light emitting layer 150 to prevent excitons or holes from diffusing into the electron transport layer 160. The hole blocking layer may be formed of, for example, an oxadiazole derivative, a triazole derivative, or a phenanthroline derivative.

In addition, the polymer according to an embodiment may be applied to electroluminescence devices other than the QLED or OLED. Examples of other electroluminescence devices to which the polymer according to an embodiment is applicable are not particularly limited, but examples thereof include organic-inorganic perovskite light emitting devices and the like.

The present invention includes the following embodiments and examples.

1. A polymer compound comprising a structural unit represented by formula (1), and at least one of structural units represented by formula (2), formula (3), or formula (4):

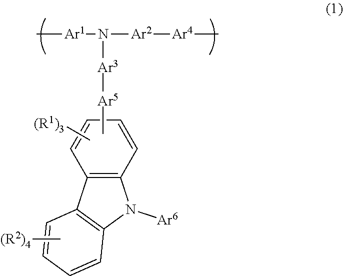

in formula (1) above,
Ar¹ and Ar² may, each independently, be a substituted or unsubstituted aromatic hydrocarbon group having 6 to 60 carbon atoms,
Ar³ may be a substituted or unsubstituted aromatic hydrocarbon group having 6 to 120 carbon atoms,
Ar⁴ may be a substituted or unsubstituted aromatic hydrocarbon group having 6 to 60 carbon atoms, or a substituted or unsubstituted aromatic heterocyclic group having 3 to 60 ring-forming atoms,
Ar⁵ may be a single bond or a substituted or unsubstituted aromatic heterocyclic group having 3 to 60 ring-forming atoms,
Ar⁶ may be a substituted or unsubstituted aromatic hydrocarbon group having 6 to 60 carbon atoms, or a substituted or unsubstituted aromatic heterocyclic group having 3 to 60 ring-forming atoms,
R¹ may be a hydrogen atom, an alkyl group, a hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN), and
R² may be a hydrogen atom, an alkyl group, an hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN);

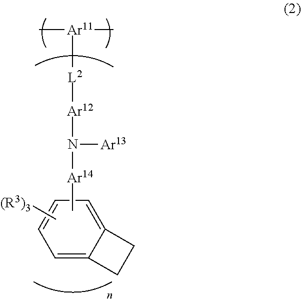

in formula (2) above,
Ar¹¹ may be a substituted or unsubstituted aromatic hydrocarbon group having 6 to 60 carbon atoms, or a substituted or unsubstituted aromatic heterocyclic group having 3 to 60 ring-forming atoms,
L² may be a single bond or a saturated hydrocarbon group having 2 to 60 carbon atoms,
Ar¹² may be a substituted or unsubstituted aromatic hydrocarbon group having 6 to 60 carbon atoms, or a substituted or unsubstituted aromatic heterocyclic group with 3 to 60 ring-forming atoms,
Ar¹³ may be a substituted or unsubstituted aromatic hydrocarbon group having 6 to 60 carbon atoms, or a substituted or unsubstituted aromatic heterocyclic group having 3 to 60 ring-forming atoms,
Ar¹⁴ may be a single bond, a substituted or unsubstituted aromatic hydrocarbon group having 6 to 60 carbon atoms, or a substituted or unsubstituted aromatic heterocyclic group having 3 to 60 ring-forming atoms,
R³ may be a hydrogen atom, an alkyl group, an hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN), wherein R³ may form a ring with another R³ or with a carbon atom in a benzene ring to which R³ is bonded, and
n is 1 or 2;

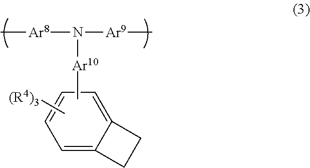

in formula (3) above,
Ar⁸ and Ar⁹ may, each independently, be a substituted or unsubstituted aromatic hydrocarbon group having 6 to 60 carbon atoms,
Ar¹⁰ may be a single bond, a substituted or unsubstituted aromatic hydrocarbon group having 6 to 60 carbon atoms, or a substituted or unsubstituted aromatic heterocyclic group having 3 to 60 ring-forming atoms, and
R⁴ may be a hydrogen atom, an alkyl group, a hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN), wherein R⁴ may form a ring with another R⁴ or with a carbon atom in a benzene ring to which R⁴ is bonded;

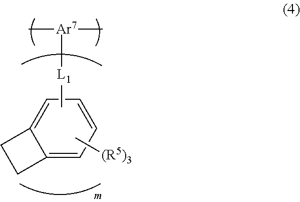

in formula (4) above,
Ar⁷ may be a substituted or unsubstituted aromatic hydrocarbon group having 6 to 60 ring atoms, or a substituted or unsubstituted aromatic heterocyclic group having 3 to 60 ring-forming atoms,
L¹ may be a single bond or a saturated hydrocarbon group having 2 to 60 carbon atoms,
R⁵ may be a hydrogen atom, an alkyl group, a hydroxyalkyl group, an alkoxygroup, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN), wherein R⁵ may form a ring with another R⁵ or with a carbon atom in a benzene ring to which R⁵ is bonded, and
m is 1 or 2.

The polymer compound mentioned in item 1 above may include a structural unit represented by formula (1), and a structural unit represented by formula (2), wherein in formula (2), Ar¹¹ may be a substituted or unsubstituted aromatic hydrocarbon group having 6 to 20 carbon atoms, L² may be a single bond, a straight-chain or branched saturated hydrocarbon group having 4 to 12 carbon atoms, Ar¹² may be a substituted or unsubstituted aromatic hydrocarbon group having 6 to 20 carbon atoms, Ar¹³ may be a substituted or unsubstituted aromatic hydrocarbon group having 6 to 20 carbon atoms, Ar¹⁴ may be a single bond or a substituted or unsubstituted aromatic hydrocarbon group having 6 to 20 carbon atoms, R³ may independently be a hydrogen atom, an alkyl group, or an alkenyl group, where R³ may form a ring with another R³ or with a carbon atom in a benzene ring to which R³ is bonded (i.e., substituted by R³), and n may be 1 or 2.

The polymer compound mentioned in item 1 or 2 above may include a structural unit represented by formula (1), and a structural unit represented by formula (5):

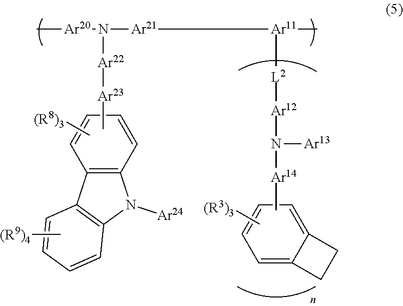

in formula (5) above,
Ar¹¹, L², Ar¹², Ar¹³, Ar¹⁴, R³, and n are the same as defined in formula (2),
Ar²⁰ and Ar²¹ may each independently be a substituted or unsubstituted aromatic hydrocarbon group having 6 to 60 carbon atoms,
Ar²² may be a substituted or unsubstituted aromatic hydrocarbon group having 6 to 120 carbon atoms,
Ar²³ may be a single bond, or a substituted or unsubstituted aromatic heterocyclic ring group having 3 to 60 ring-forming atoms,
Ar²⁴ may be a substituted or unsubstituted aromatic hydrocarbon group having 6 to 60 carbon atoms, or a substituted or unsubstituted aromatic heterocyclic ring having 3 to 60 ring-forming atoms,
R⁸ may independently be a hydrogen atom, an alkyl group, a hydroxyalkyl group, an alkoxy group, an alkoxyalkyl group, an alkenyl group, an alkynyl group, an alkylthio group, an alkoxy carbonyl group, a hydroxyl group (—OH), a carboxyl group (—COOH), a thiol group (—SH), or a cyano group (—CN),
R⁹ may independently be a hydrogen atom, an alkyl group, a hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN).

The polymer compound according to any one of items 1 to 3 above may include a structural unit represented by formula (1), and a structural unit represented by formula (3), wherein in formula (3), at least one of Ar⁸ or Ar⁹ may include an aromatic hydrocarbon group having 6 to 60 carbon atoms, wherein the aromatic hydrocarbon group may be substituted with an alkyl group having 9 to 60 carbon atoms.

The polymer compound according to any one of items 1 to 4 above may include a structural unit represented by formula (1), a structural unit represented by formula (3), and a structural unit represented by formula (6):

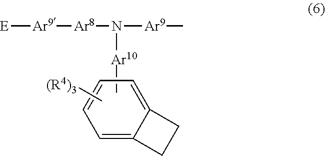

in formula (6),
Ar⁸ to Ar¹⁰, and R⁴ may be the same as defined in formula (3),
Ar^{9′} may be a substituted or unsubstituted aromatic hydrocarbon group having 6 to 60 carbon atoms,
E may be a substituted or unsubstituted aromatic hydrocarbon group having 6 to 60 carbon atoms.

The polymer compound according to any one of items 1 to 5 above may include a structural unit represented by formula (1), and a structural unit represented by formula (7):

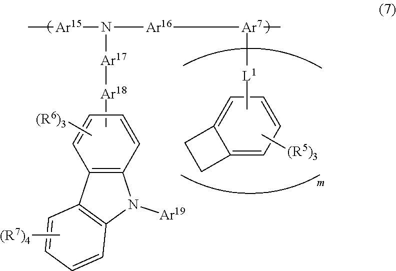

in formula (7),
L¹, R⁵, and m may be the same as defined in formula (4),
Ar⁷ may be selected from Group (II) below:

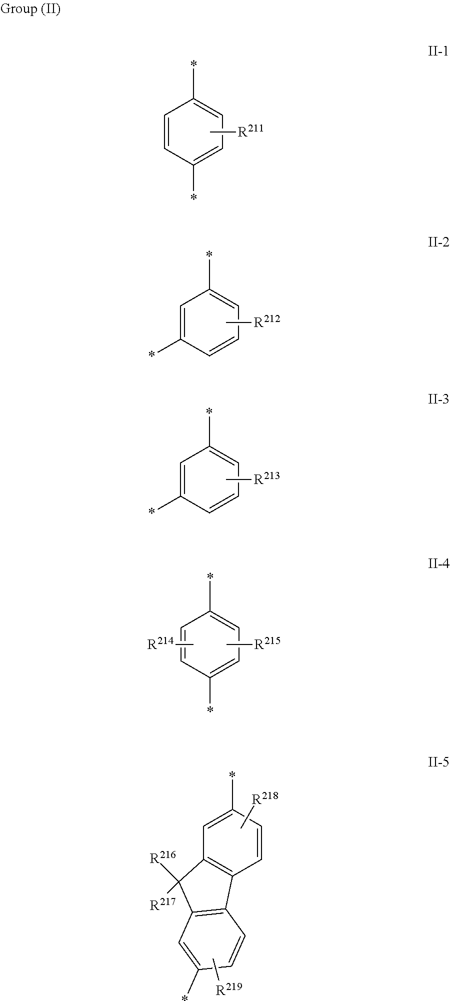

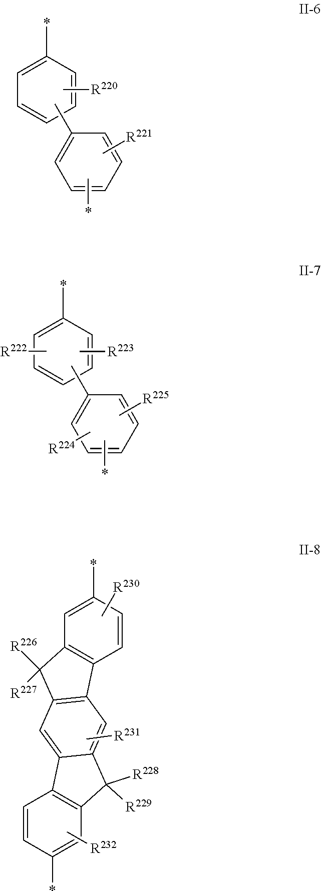

in Group (II),
R²¹ to R²³² may, each independently, be a hydrogen atom, a straight-chain or branched hydrocarbon group having 1 to 18 carbon atoms, or a group represented by formula (4′) below, and * indicates a bonding position with adjacent atoms:

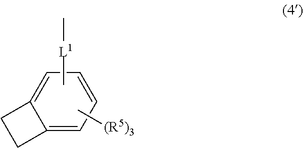

wherein in formula (4′), L¹ and R⁵ are the same as in formula (4);
Ar¹⁵ and Ar¹⁶ may, each independently, be a substituted or unsubstituted aromatic hydrocarbon group having 6 to 60 carbon atoms,
Ar¹⁷ may be a substituted or unsubstituted aromatic hydrocarbon group having 6 to 120 carbon atoms,
Ar¹⁸ may be a single bond, or a substituted or unsubstituted aromatic heterocyclic ring having 3 to 60 ring-forming atoms,
Ar¹⁹ may be a substituted or unsubstituted aromatic hydrocarbon group having 6 to 60 carbon atoms, or a substituted or unsubstituted aromatic heterocyclic ring group having 3 to 60 ring-forming atoms,
R⁶ may be a hydrogen atom, an alkyl group, a hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN), and
R⁷ may independently be a hydrogen atom, an alkyl group, a hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN).

The polymer compound according to any one of items 1 to 6 above, wherein Ar³ in formula (1) may be selected from Group (I):

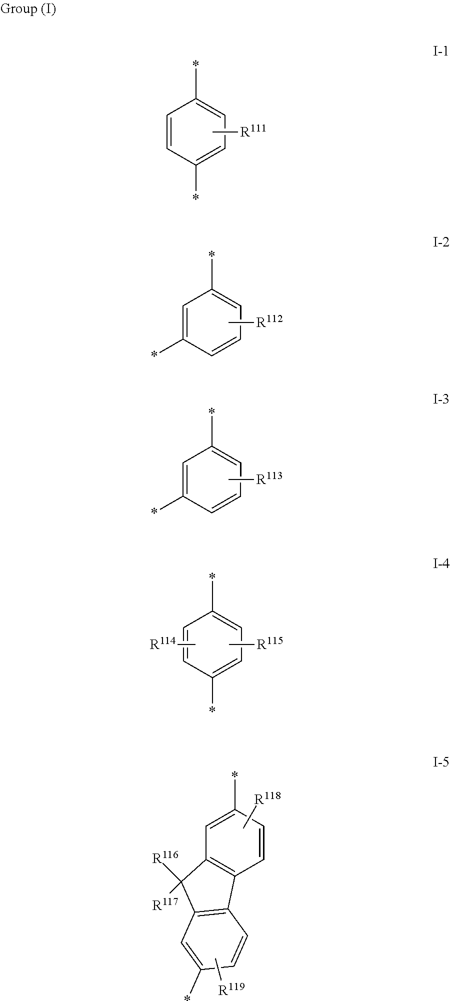

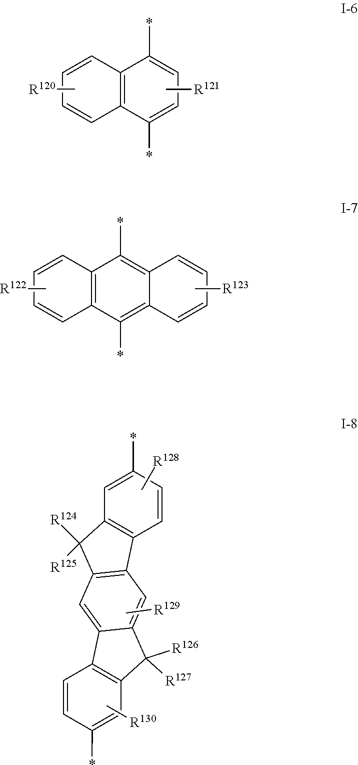

in Group (I) above,
R¹¹¹ to R¹³⁰ may, each independently, be a hydrogen atom, or a straight-chain or branched hydrocarbon group having 1 to 18 carbon atoms, and
* indicates a bonding portion with an adjacent atom.

The polymer compound according to any one of items 1 to 6, wherein Ar¹, Ar², and Ar⁴ in formula (1) may, each independently, be selected from the following Group (II′):

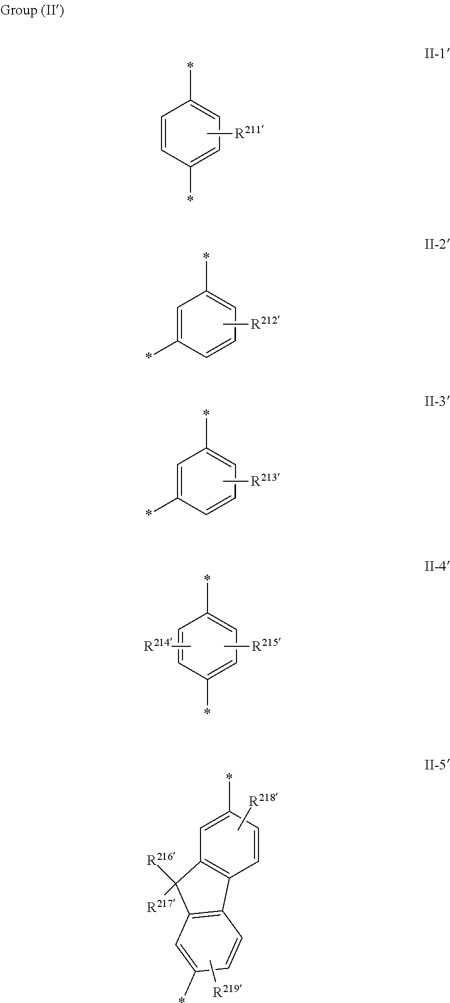

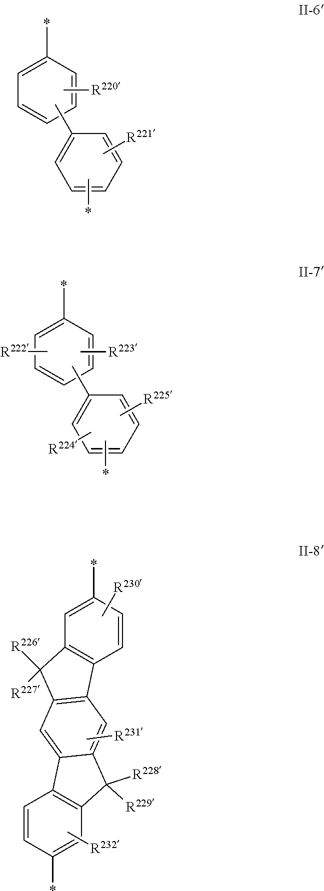

in Group (II′) above,
R^{211′} to R^{232′} may, each independently, be a hydrogen atom, or a straight-chain or branched hydrocarbon group having 1 to 18 carbon atoms, and * indicates a bonding position with an adjacent atom.

The polymer compound according to any one of items 1 to 6 above, wherein Ar⁶ in formula (1) may be selected from the following Group (III):

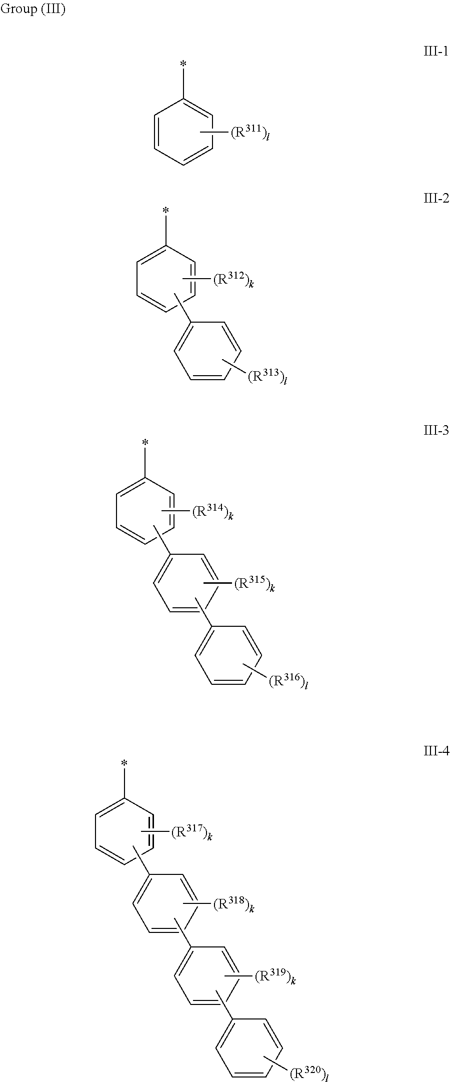

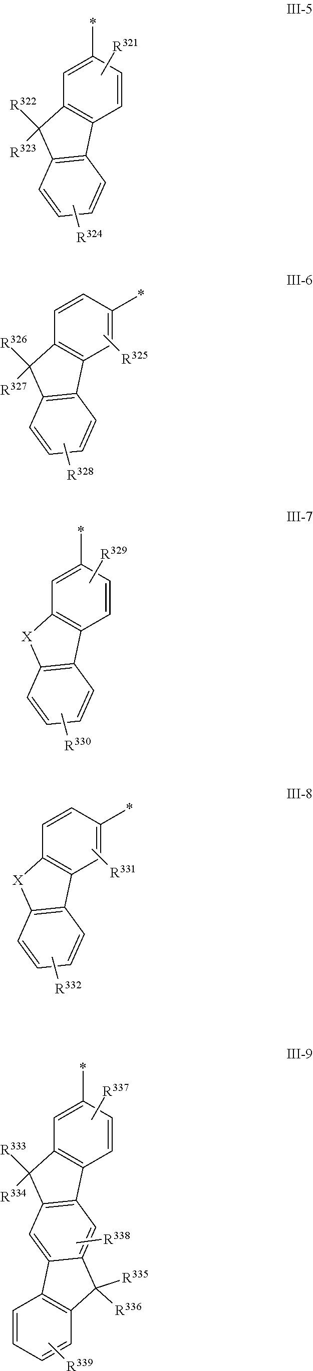

in Group (III),
R³¹¹ to R³³⁹ may, each independently, be a hydrogen atom, or a straight-chain or branched hydrocarbon group having 1 to 18 carbon atoms,
X indicates oxygen atom or sulfur atom, and
* indicates a bonding position with an adjacent atom.

The polymer compound according to any one of items 1 to 6 above, wherein Ar⁴ in formula (1) is represented by formula (a) or formula (b):

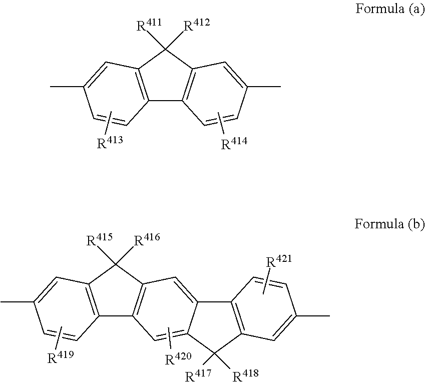

wherein in formula (a) and formula (b),
R⁴¹¹, R⁴¹², and R⁴¹⁵ to R⁴¹⁸ may, each independently, be a hydrogen atom, or a hydrocarbon group having 1 to 30 carbon atoms, provided that one or more of R⁴¹¹ and R⁴¹², and one or more of R⁴¹⁵ to R⁴¹⁸, may, each independently, be a straight-chain or branched alkyl group having 8 to 30 carbon atoms, and
R⁴¹³, R⁴¹⁴, and R⁴¹⁹ to R⁴²¹ are, each independently, a hydrogen atom, or a hydrocarbon group having 1 to 30 carbon atoms.

A composition comprising the polymer compound according to any one of items 1 to 10 above, and at least one material selected from a hole transport material, an electron transport material, a luminescent material, or a combination thereof.

The composition of item 11 may further include an organic metal complex.

The composition of item 11 may further include semiconductor nanoparticles.

An organic film containing the polymer compound according to any one of items 1 to 10 above.

An electroluminescence device comprises a first electrode, a second electrode, and an organic film disposed between the first electrode and the second electrode, wherein the organic film comprises one or more layers, and wherein at least one of the one or more layers of the organic film may include the polymer compound according to any one of items 1 to 10.

The electroluminescence device according to item 15, wherein the at least one of the one or more layers of the organic film including the polymer compound may be a hole transport layer or a hole injection layer.

The electroluminescence device according to item 15 or 16, wherein the organic film comprises two or more layers, and wherein at least one of the two or more layers of the organic film further comprises a light-emitting layer comprising semiconductor nanoparticles or organic metal complex.

A method of manufacturing an electroluminescence device including a first electrode, a second electrode, and an organic film disposed between the first electrode and the second electrode and comprising one or more layers, wherein the method comprising:
forming at least one of the one or more layers of the organic film by coating a solution comprising the polymer compound according to any one of items 1 to 10 above and a solvent to a layer adjacent to the at least one of the one or more layers of the organic film to form a coated layer, and removing the solvent from the coated layer.

### Example

The effects of the present disclosure will be described with reference to the following examples and comparative examples. However, the technical scope of the present disclosure is not limited only to the following examples. Unless otherwise specified in the following examples, the operation stated is performed at room temperature (25° C.). In addition, unless otherwise indicated, “%” and “part” mean weight percent “wt %” and “part of a total mass,” respectively.

### Synthesis of Polymer

### Synthesis of Intermediate Compound 1

Intermediate compound 1 was synthesized according to Scheme 1 below.

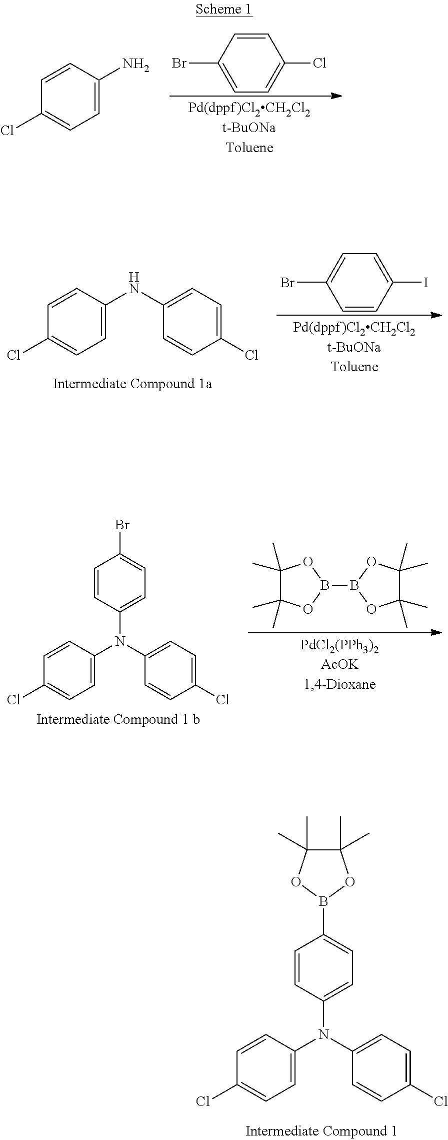

4-Chloroaniline (510 millimoles (mmol), 65.0 grams (g)), 1-Bromo-4-chlorobenzene (535 mmol, 102.4 g), tert-butoxy sodium (t-BuONa) (764 mmol, 73.4 g), toluene (1020 milliliters (mL)), and [1,1′-bis(diphenylphosphino)ferrocene]palladium(II) dichloride dichloromethane adjunct (PdCl₂(dppf)-CH₂Cl₂) (15.3 mmol, 12.5 g) were added to a 3 liter (L), 4-neck flask, with heating and stirring at 110° C. under a nitrogen atmosphere. The solution was heated and stirred at 110° C. for 6 hours, while confirming the progress of the reaction.

After 6 hours, the solution was cooled to room temperature and filtered through Celite. The obtained filtrate was concentrated and purified by silica gel chromatography (hexane:toluene=7:3). Then, the obtained solution was concentrated and purified by recrystallization using toluene and hexane, and vacuum dried at 50° C., for 16 hours to provide Intermediate compound 1a (100 g, 83% yield).

Intermediate compound 1a (168 mmol, 40.0 g), 1-bromo-4-iodobenzene (p-bromoiodobenzene) (252 mmol, 71.3 g), t-BuONa (336 mmol, 32.3 g), toluene) (336 mL), and PdCl₂(dppf)-CH₂Cl₂ (0.50 mmol, 4.12 g) were added to a 1 L four-neck flask, with heating and stirring at 110° C. under a nitrogen atmosphere. Then, the reaction solution was heated and stirred at 110° C. for 6 hours, while monitoring the progress of the reaction.

After 6 hours, the solution was cooled to room temperature and filtered through Celite. The obtained filtrate was concentrated and purified by silica gel chromatography (hexane:toluene=7:3). After concentrating the obtained solution, it was purified by recrystallization twice using tetrahydrofuran (THF) and methanol (MeOH), and the obtained solid was vacuum dried at 50° C., for 16 hours to provide Intermediate compound 1b (34 g, 50% yield).

Intermediate compound 1b (178 mmol, 70.0 g), bis(pinacolate)diboron (267 mmol, 67.8 g), potassium acetate (AcOK) (356 mmol, 34.2 g), and 1,4-dioxane (650 mL) were added to a 2 L three-neck flask, stirred to be dispersed. Then, bis(triphenylphosphine) palladium (II) dichloride (PdCl₂ (PPh₃)₂) (5.34 mmol, 4.36 g) was added. Then, the solution was refluxed under argon atmosphere for 20 hours.

After 20 hours, the solution was cooled to room temperature and filtered using Celite to remove insoluble material. After concentrating the obtained filtrate, it is filtered through a silica gel pad to remove the original component. The obtained filtrate was concentrated and purified by recrystallization using toluene and hexane. The obtained solid was vacuum dried at 50° C., for 12 hours to provide Intermediate Compound 1 (53.5 g, 68% yield).

### Synthesis of Intermediate Compound 2

Intermediate compound 2 was synthesized according to Scheme 2 below.

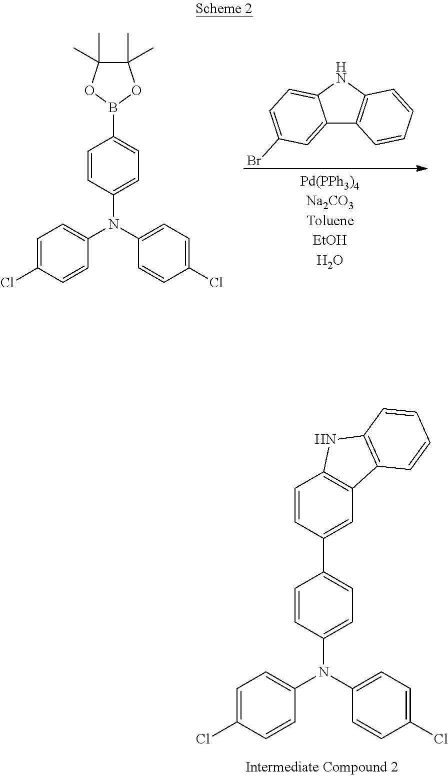 [SMILES: CC1(C)OB(c2ccc(N(c3ccc(Cl)cc3)c3ccc(Cl)cc3)cc2)OC1(C)C ; Brc1ccc2[nH]c3ccccc3c2c1 ; Clc1ccc(N(c2ccc(Cl)cc2)c2ccc(-c3ccc4[nH]c5ccccc5c4c3)cc2)cc1]

Intermediate compound 1 (73.1 mmol, 9.0 g), 3-bromo-9H-carbazole (73.1 mmol, 16.1 g), and toluene (180 mL) were added to a 500 mL three-necked flask, and dissolved. Then, a Na₂CO₃ aqueous solution (109.7 mmol, 5.82 g, 90 mL of pure water) and ethanol (90 mL) were added thereto and dispersed, and nitrogen was bubbled for 30 minutes. Afterwards, tetrakis(triphenylphosphine) palladium (0) (Pd(PPh₃)₄) (3.66 mol, 2.11 g) was added and the reaction mixture was refluxed under a nitrogen atmosphere for 5 hours.

After 5 hours, the solution was cooled to room temperature, diluted with toluene, and then washed with pure water 3 times. The obtained solution was dried with MgSO₄ and then filtered through a silica gel pad. Solvent in the obtained filtrate was removed under reduced pressure. After solvent removal, is the residue was purified by recrystallization using toluene and methanol twice. The obtained solid was vacuum dried at 50° C., for 16 hours to provide Intermediate compound 2 (13.8 g, 79% yield).

### Synthesis of Intermediate Compound 3

Intermediate compound 3 was synthesized according to Scheme 3.

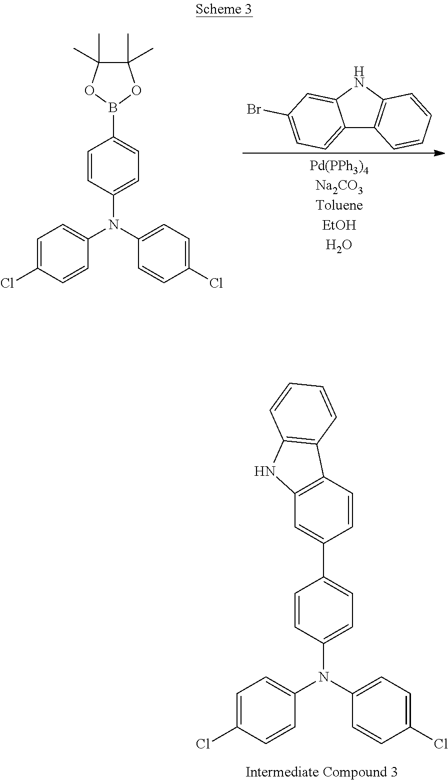 [SMILES: CC1(C)OB(c2ccc(N(c3ccc(Cl)cc3)c3ccc(Cl)cc3)cc2)OC1(C)C ; Brc1ccc2c(c1)[nH]c1ccccc12 ; Clc1ccc(N(c2ccc(Cl)cc2)c2ccc(-c3ccc4c(c3)[nH]c3ccccc34)cc2)cc1]

Intermediate compound 3 was synthesized with the same method as for the synthesis of Intermediate compound 2, the 3-bromo-9H-carbazole used for Intermediate compound 2 was replaced with 2-bromo-9H-carbazole (14.5 g, 89% yield).

### Synthesis of Intermediates Compound M-1

Intermediate compound M-1 of the following structure was synthesized by the same method as Synthesis Example 3 (for preparing Compound A-4) in JP 2021-138915 A:

### Intermediate Compound M-1

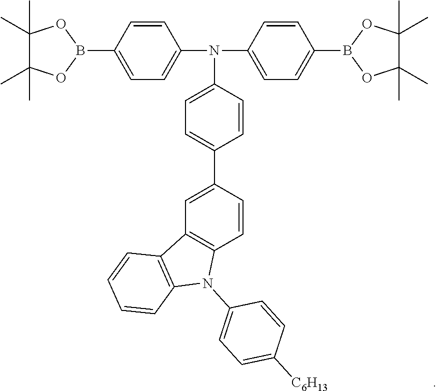

### Synthesis of Intermediate Compound M-2

Intermediate compound M-2 of the following structure was synthesized by using the same method as in Synthesis Example 4 (for preparing Compound A-5) in JP 2021-138915 A:

### Intermediate Compound M-2

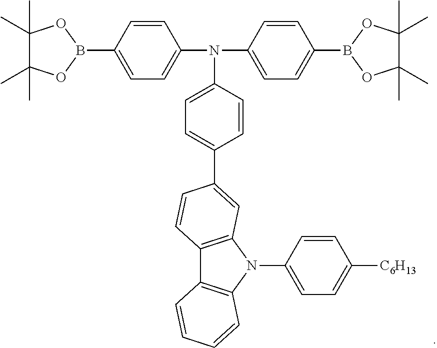

### Synthesis of Intermediate Compound M-3

Intermediate compound M-3 was synthesized according to Scheme M-3 below:

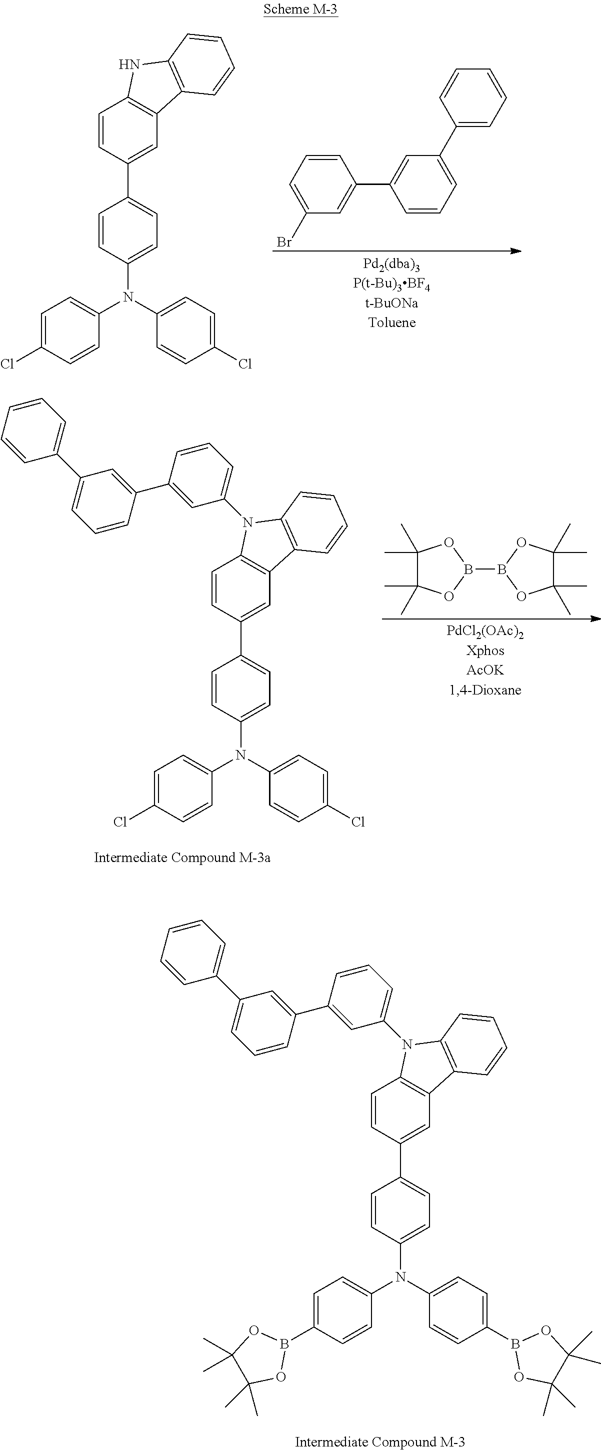

Intermediate compound 2 (28.8 mmol, 13.8 g), 3-bromo-1,1′:3′, 1″-terphenyl (31.7 mmol, 9.79 g), and t-BuONa (43.2 mmol, 4.15 g), and toluene (160 mL) were added to a 300 mL four-necked flask, and dispersed. Trisdibenzylidene acetone dipalladium (Pd₂(dba)₃) (0.58 mmol, 0.53 g) and tri-tert-butylphosphine tetrafluoroborate (P(t-Bu)₃—BF₄) (1.15 mmol, 0.33 g) were added thereto, and the mixture was heated and stirred at 110° C. for 4 hours under a nitrogen atmosphere.

After 4 hours, the obtained mixture was cooled to room temperature, and insoluble material was removed using Celite. Solvent was removed from the filtrate by distillation under reduced pressure, and the residue was purified by column chromatography (silica gel, hexane/toluene) to provide Intermediate compound M-3a (11.0 g, 54% yield).

Intermediate M-3a (15.5 mmol, 11.0 g), bis(pinacolate)diboron (62.2 mmol, 15.8 g), potassium acetate (93.3 mmol, 9.0 g), and 1,4-Dioxane (155 mL) were added to a 2 L three-necked flask, and stirred to disperse. Then, palladium acetate (Pd(OAc)₂) (1.55 mmol, 0.35 g) and 2-dicyclohexylphosphino-2′,4′,6′-triisopropylbiphenyl (Xphos) (1.55 mmol, 0.74 g) were added thereto and incubated under argon atmosphere for 5 hours, while refluxing.

The obtained mixture was cooled to room temperature and filtered using Celite to remove insoluble material. Solvent was removed from the filtrate by distillation under reduced pressure, and then filtered through a silica gel pad to remove the original components. The obtained solution was concentrated and then purified by recrystallization with toluene and acetonitrile. The obtained solid was vacuum dried at 50° C., for 12 hours to provide Intermediate compound M-3 (5.3 g, 38% yield).

### Synthesis of Intermediate Compound M-4

Intermediate compound M-4 is synthesized according to Scheme M-4 below:

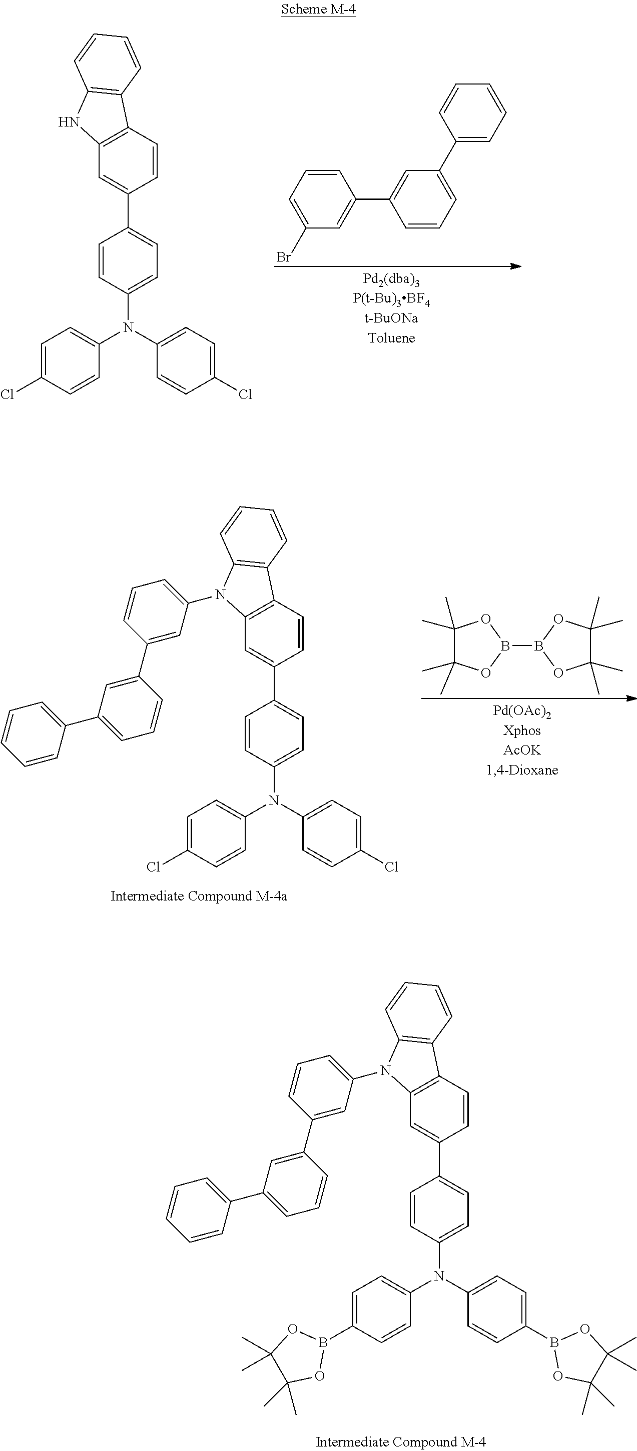

Intermediate compound M-4 was synthesized by the same method as in Intermediate compound M-3, except for replacing Intermediate compound 2 with Intermediate compound 3.

The isolated quantity of Intermediate compound M-4a was 7.0 g with a 73% yield. The isolated quantity of Intermediate compound M-4 was 6.0 g with a 68% yield.

### Synthesis of Intermediate Compound M-5

Intermediate compound M-5 having the following formula was synthesized by the same method as for Compound C described in WO 2008/038747 A.

### Intermediate Compound M-5

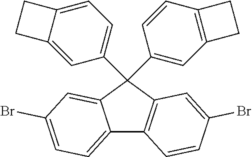 [SMILES: Brc1ccc2c(c1)C(c1ccc3c(c1)CC3)(c1ccc3c(c1)CC3)c1cc(Br)ccc1-2]

### Synthesis of Intermediate Compound M-6

Intermediate compound M-6 was synthesized according to Scheme M-6 below:

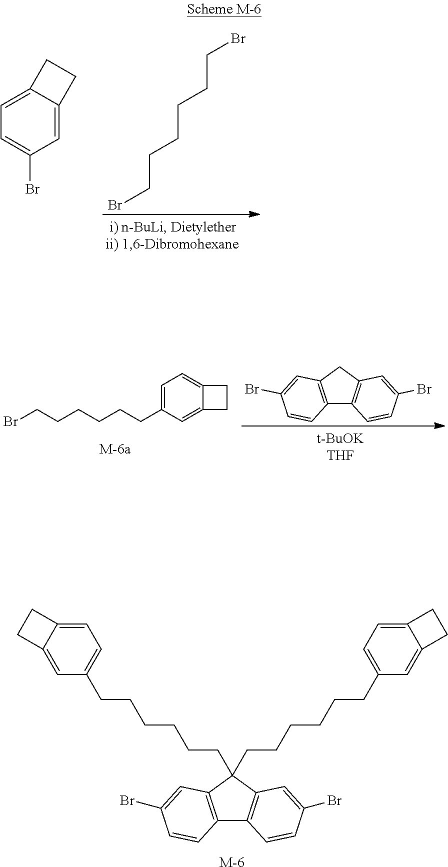

3-Bromobicyclo[4.2.0]octa-1(6), 2,4-triene (54.6 mmol, 10.0 g) and diethyl ether (182 mL) were added to a 500 mL four-necked flask, and cooled to −78° C. under a nitrogen atmosphere. Then, n-butyllithium (n-BuLi) (54.6 mmol, 9.72 g) was added slowly. After stirring at −78° C. for 1 hour, 1,6-dibromohexane (163.9 mmol, 40.0 g) was added, and stirred at −78° C. for 1 hour, and then further stirred at room temperature for 12 hours.

Then, the reaction solution was diluted with ethyl acetate and washed with pure water. The organic layer was dried with magnesium sulfate, filtered, and isolated. After concentrating the obtained solution, 1,6-dibromohexane was removed by distillation under reduce pressure. The liquid residue was purified by silica gel chromatography (with hexane).

The obtained solution was vacuum dried at 50° C., for 16 hours to provide Intermediate compound M-6a (6.0 g, 40% yield).

Potassium tert-butoxide (13.89 mmol, 1.6 g) and tetrahydrofuran (10 mL) were added to a 100 mL four-necked flask, and cooled to 0° C. under a nitrogen atmosphere. Afterwards, a tetrahydrofuran solution (10 mL) of 2,7-dibromofluorene (4.63 mmol, 1.5 g) was slowly added, and stirred at 0° C., for 30 minutes. Then, a tetrahydrofuran solution (10 mL) of Intermediate compound M-6a (10.2 mmol, 2.7 g) (“M-6a” in Scheme M-6) was slowly added, and stirred at 0° C. for 1 hour.

The reaction solution was diluted with ethyl acetate and washed with pure water. The organic layer was dried with magnesium sulfate, filtered, and isolated. The obtained solution was concentrated and purified by silica gel chromatography (hexane: toluene=9:1).

The obtained liquid was vacuum dried at 50° C., for 16 hours to provide Intermediate compound M-6 (“M-6” in Scheme M-6) (1.1 g, 34% yield).

### Synthesis of Intermediate Compound M-7

Intermediate compound M-7 is synthesized according to Scheme M-7 below:

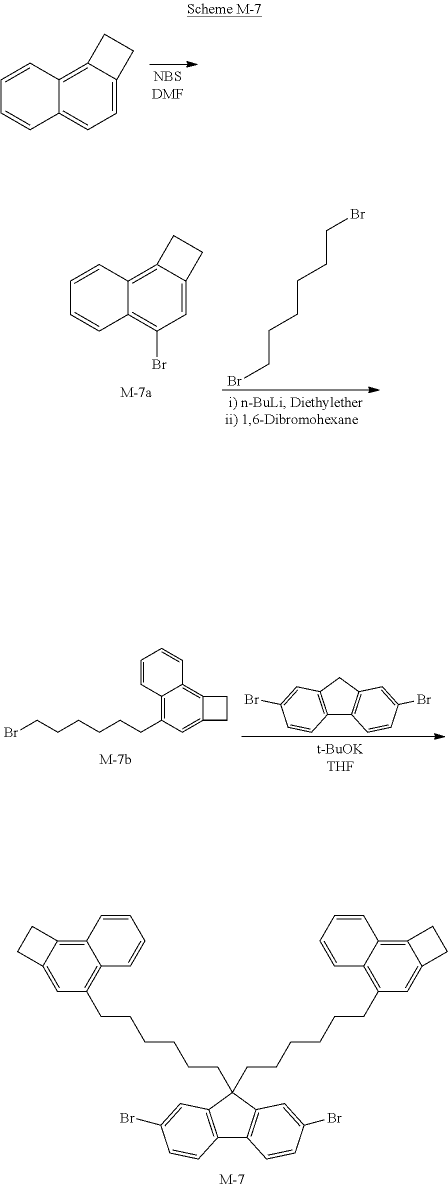

1,2-dihydrocyclobuta[a]naphthalene (259.4 mmol, 40 g) and dimethylformamide (DMF) (432 mL) were added to a 2 L four-necked flask, and cooled to 0° C. under a nitrogen atmosphere. Afterwards, a solution of N-bromosuccinimide (NBS) (259.4 mmol, 46.2 g) in DMF (432 mL) was slowly added. The reaction solution was stirred at room temperature for 1 hour while confirming the progress of the reaction.

Upon completion of the reaction, pure water was added to the obtained solution, and the solution was washed and separated with dichloromethane and pure water. After concentrating the obtained solution, it was diluted with acetone (30 mL), and methanol (300 mL) was added to precipitate the solids. The obtained solids were dispersed in methanol and washed.

The obtained solids were vacuum dried at 50° C., for 16 hours to provide Intermediate compound M-7a (“M-7a” in Scheme M-7) (40 g, 66% yield).

M-7a (42.9 mmol, 10.0 g) and diethyl ether (143 ml) were added to a 500 mL four-necked flask, and cooled to −78° C. under a nitrogen atmosphere. Afterwards, n-butyllithium (n-BuLi) (42.9 mmol, 7.64 g) was slowly added. After stirring at −78° C. for 1 hour, 1,6-dibromohexane (128.7 mmol, 31.4 g) was added, and after stirring at −78° C. for another hour, the mixture was stirred at room temperature for 12 hours.

The reaction solution was diluted with ethyl acetate and washed with pure water. The organic layer was dried with magnesium sulfate, filtered, and isolated.

The obtained solution was concentrated and then purified by silica gel chromatography (hexane). After distilling and removing the solvent, it was recrystallized with tetrahydrofuran and ethanol.

The obtained solid was vacuum dried at 50° C., for 16 hours to provide Intermediate compound M-7b (“M-7b” in Scheme M-7) (6.6 g, 48% yield).

Potassium t-butoxide (t-BuOK) (13.89 mmol, 1.6 g) and tetrahydrofuran (10 mL) were added to a 100 mL four-necked flask, and cooled to 0° C. under a nitrogen atmosphere. Afterwards, a tetrahydrofuran solution (10 mL) of 2,7-dibromofluorene (4.63 mmol, 1.5 g) was slowly added, and stirred at 0° C. for 30 minutes. Then, a tetrahydrofuran solution (10 mL) of Intermediate compound M-7b (10.2 mmol, 3.2 g) was slowly added, and stirred at 0° C., for 1 hour.

The reaction solution was diluted with ethyl acetate and washed with pure water. The organic layer was dried with magnesium sulfate, filtered, and isolated. The obtained solution was concentrated and purified by silica gel chromatography (hexane: toluene=9:1). After distilling off the solvent, the obtained solids were washed with methanol.

The obtained solids were vacuum dried at 50° C., for 16 hours to provide Intermediate compound M-7 (“M-7” in Scheme M-7) (2.6 g, 70% yield).

### Synthesis of Intermediate Compound M-8

Intermediate compound M-8 is synthesized according to Scheme M-8 below:

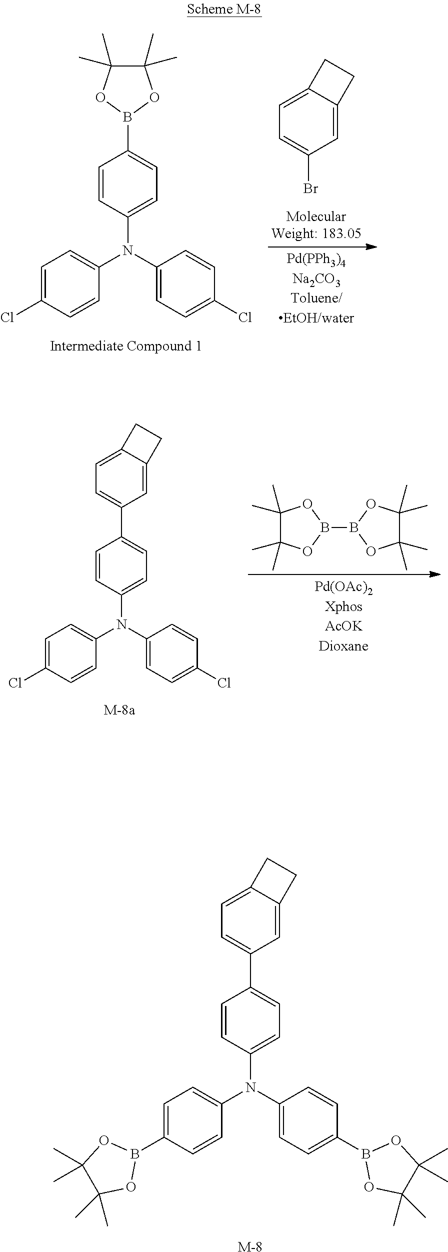

Intermediate compound 1 (21.9 mmol, 9.6 g), 3-bromobicyclo[4.2.0]octa-1(6),2,4-triene (21.9 mmol, 4.0 g), sodium carbonate (Na₂CO₃) (32.8 mmol, 3.47 g), toluene (109 mL), ethanol (EtOH) (55 mL)), pure water (55 mL), and tetrakis(triphenylphosphine)palladium (Pd(PPh₃)₄) (1.09 mmol, 1.26 g) were added to a 500 mL four-necked flask, and the reaction was started by heating and stirring at 90° C. under a nitrogen atmosphere. Afterwards, the reaction solution was heated and stirred at 90° C. for 6 hours, while monitoring the progress of the reaction.

After 6 hours, the obtained solution was cooled to room temperature and washed with ethyl acetate and pure water. The obtained solution was concentrated and purified by silica gel chromatography (hexane: toluene=8:2).

Solids were obtained by removing the solvent, and the solids were vacuum dried at 50° C., for 16 hours to provide Intermediate compound M-8a (“M-8a” in Scheme M-8) (8.1 g, 89% yield).

Intermediate compound M-8a (19.2 mmol, 8.0 g), bis(pinacolate)diboron (76.9 mmol, 19.5 g), potassium acetate (115.3 mmol, 11.1 g), and 1,4-dioxane (192 mL) were added to a 500 mL three-necked flask, and stirred to disperse. Then, palladium acetate (1.92 mmol, 0.42 g) and 2-dicyclohexylphosphino-2′,4′,6′-triisopropylbiphenyl (192 mmol, 0.92 g) were added thereto, and refluxed under an argon atmosphere for 5 hours.

The obtained solution was cooled to room temperature, and filtered using Celite to remove insoluble material. Solvent was removed from the filtrate by distillation under reduced pressure, and is the residue was filtered through a silica gel pad to remove the starting materials. The obtained solution was concentrated and then purified by recrystallization with toluene and acetonitrile.

The obtained solids were vacuum dried at 50° C., for 12 hours to provide Intermediate compound M-8 (“M-8” in Scheme M-8) (5.6 g, 49% yield).

### Synthesis of Intermediate Compound M-9

Intermediate compound M-9 is synthesized according to Scheme M-9 below:

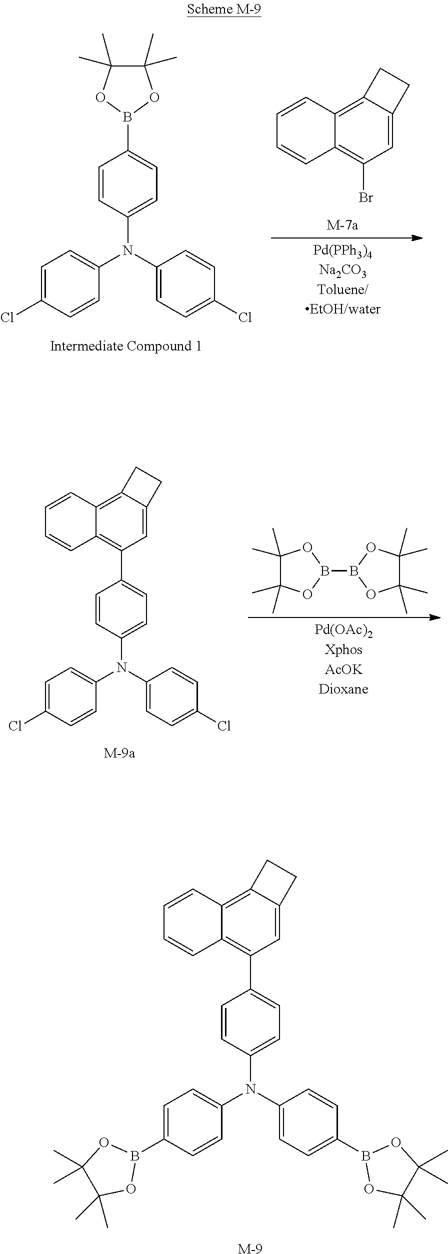

Intermediate compound M-9 was synthesized by the same method as Intermediate compound M-8, except for replacing 3-bromobicyclo[4.2.0]octa-1(6),2,4-triene with Intermediate compound M-7a.

The isolated quantity of Intermediate compound M-9a was 6.0 g (84% yield), and of M-9 was 5.1 g (66% yield).

### Synthesis of Intermediate Compound M-10

Intermediate compound M-10 is synthesized according to Scheme M-10 below:

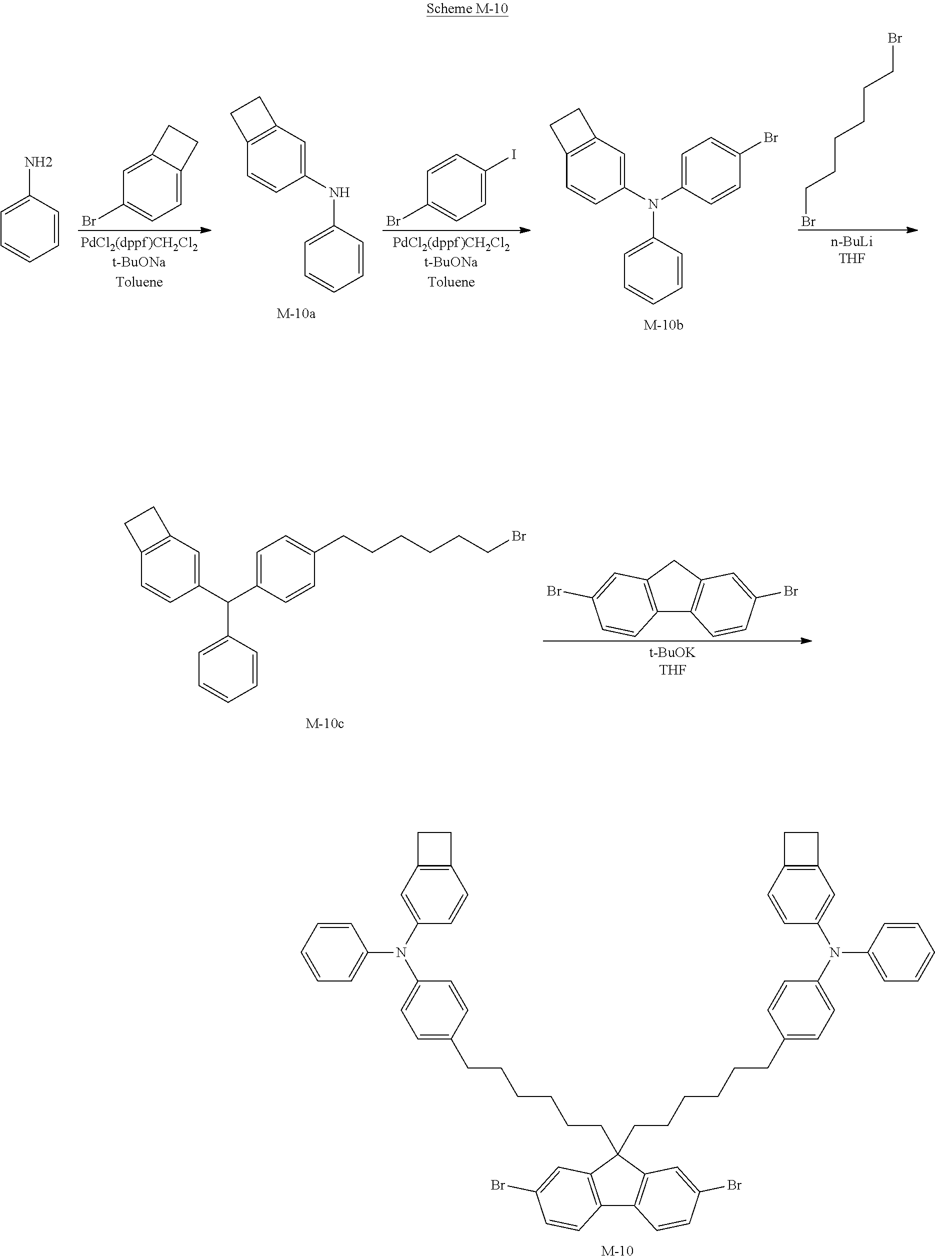

Aniline (80.5 mmol, 7.5 g), 3-bromobicyclo[4.2.0]Octa-1(6),2,4-triene (80.5 mmol, 14.7 g), t-butoxy sodium (t-BuONa) (120.8 mmol, 11.6 g), toluene (161 mL), and [1,1′-bis(diphenylphosphino)ferrocene]palladium(II) dichloride dichloromethane adjunct (PdCl₂(dppf)-CH₂Cl₂) (2.42 mmol, 1.97 g) were added to a 500 mL four-necked flask, heated to 110° C. under a nitrogen atmosphere, and stirred to start the reaction. Afterwards, the reaction mixture was heated and stirred at 110° C. for 6 hours, while monitoring the progress of the reaction.

The obtained solution was cooled to room temperature and filtered through Celite. The obtained filtrate was concentrated and purified by silica gel chromatography (hexane: toluene=5:5).

Solids were obtained by removing the solvent, and is the solids were vacuum dried at 50° C., for 16 hours to provide Intermediate compound M-10a (“M-10a” in Scheme M-10) (14.9 g, 96% yield).

Intermediate compound M-10a (76.3 mmol, 14.9 g), 1-bromo-4-iodobenzene (114.5 mmol, 32.4 g), t-butoxy sodium (t-BuONa) (152.6 mmol, 14.7 g), toluene (153 mL), and [1,1′-bis(diphenylphosphino)ferrocene]palladium(II) dichloride dichloromethane adduct (PdCl₂(dppf)-CH₂Cl₂) (2.29 mmol, 1.87 g) are added to a 500 mL four-necked flask, and the reaction is started by heating to 110° C. and stirring under a nitrogen atmosphere. The, the reaction mixture was heated and stirred at 110° C. for 2 hours, while confirming the progress of the reaction.

Upon completion of the reaction, the obtained solution was cooled to room temperature and filtered through Celite. The obtained filtrate was concentrated and purified by silica gel chromatography (hexane: toluene=5:5). The solvent was removed and the obtained solids were purified by recrystallization using toluene and hexane.

The obtained solids were vacuum dried at 50° C., for 16 hours to provide Intermediate compound M-10b (“M-10b” in Scheme M-10) (18.9 g, 71% yield).

Intermediate compound M-10b (42.8 mmol, 15.0 g) and tetrahydrofuran (214 mL) are added in a 500 mL four-necked flask, and cooled to −78° C. under a nitrogen atmosphere. Afterwards, n-butyllithium (n-BuLi) (45.0 mmol, 8.0 g) was slowly added. After stirring at −78° C. for 1 hour, 1,6-dibromohexane (128.5 mmol, 31.3 g) was added, stirred at −78° C. for another hour, and then stirred at room temperature for 12 hours.

The reaction solution was diluted with ethyl acetate and washed with pure water. The organic layer was dried with magnesium sulfate, filtered, and isolated. The obtained solution was concentrated and purified by silica gel chromatography (hexane: toluene=1:9).

The obtained liquid was vacuum dried at 50° C., for 16 hours to provide Intermediate compound M-10c (“M-10c” in Scheme M-10) (13.0 g, 70% yield).

Tetrahydrofuran (30 mL) and t-butoxy potassium (t-BuOK) (38.1 mmol, 4.27 g) are added to a 300 mL four-necked flask, and cooled to 0° C. under a nitrogen atmosphere. Afterwards, a tetrahydrofuran solution (70 mL) of 2,7-dibromofluorene (12.7 mmol, 4.1 g) was slowly added. Afterwards, a tetrahydrofuran solution (30 mL) of Intermediate compound M-10c (26.7 mmol, 11.6 g) was slowly added, and stirred at 0° C. for 1 hour.

The reaction solution was diluted with ethyl acetate and washed with pure water. The organic layer was dried with magnesium sulfate, filtered, and isolated. The obtained solution was concentrated and purified by silica gel chromatography (hexane:toluene=2:8). The obtained solid was purified by recrystallization using hexane.

The obtained solid was vacuum dried at 50° C., for 16 hours to provide Intermediate compound M-10 (“M-10” in Scheme M-10) (14.2 g, 97% yield).

### Example 1

Under a nitrogen atmosphere, intermediate compound M-1 (1.535 g), 2,7-dibromo-9,9-didodecyl fluorene (1.110 g), intermediate compound M-5 (0.099 g), palladium acetate (4.20 mg), tris(2-methoxyphenyl)phosphine (39.5 mg), toluene (53 mL), and 20% by mass aqueous solution of tetraethylammonium hydroxide (9.62 g) were added to a four-necked flask, and stirred at 85° C. for 6 hours.

Then, phenyl boronic acid (225.8 mg), bis(triphenylphosphine)palladium(II) dichloride (78.6 mg), and a 20 mass % aqueous solution of tetraethylammonium hydroxide (9.62 g) were added, and stirred at 85° C., for 6 hours. Afterwards, sodium N,N-diethyldithiocarbamidate trihydrate (6.31 g) dissolved in ion-exchanged water (50 mL) was added, and the mixture was stirred at 85° C., for 6 hours.

Then, the organic layer was separated from the aqueous layer, and the organic layer was washed with water, 3 mass % of acetic acid, and water. Upon combining the organic layer with methanol to precipitate the polymer, the obtained polymer was separated and dried to provide a solid residue. The solid residue was dissolved in toluene, passed through a column of silica gel/alumina, and the solvent was removed by distillation under reduced pressure.

The obtained liquid was added dropwise to methanol, and the precipitated solid was isolated and dried to provide a polymer compound. For the obtained polymer compound P-1 (1.12 g), the weight average molecular weight (Mw) and polydispersity index (Mw/Mn) were measured by SEC (size exclusion chromatography). The measured weight average molecular weight (Mw) and polydispersity index (Mw/Mn) of polymer compound P-1 were 201,000 g/mol and 2.3, respectively.

The obtained polymer compound P-1 is considered to have the following structure based on the monomers (Intermediates M-1, 2,7-dibromo-9,9-didodecyl fluorene, and intermediate compound M-5) and their ratios used to prepare the polymer compound:

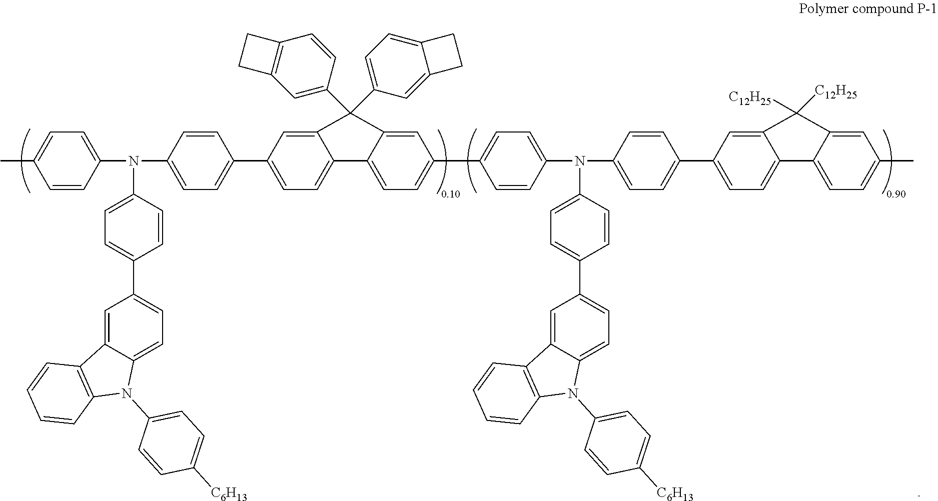

The terminal ends of polymer compound P-1 are assumed to have any one of the following structures:

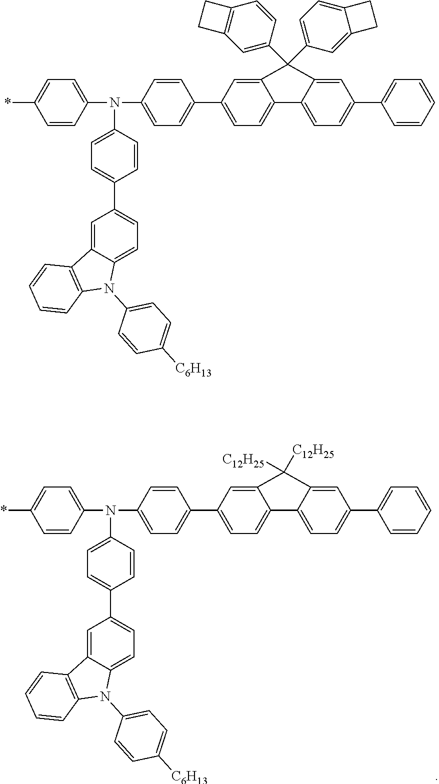

### Example 2

Under a nitrogen atmosphere, intermediate compound M-2 (1.535 g), 2,7-dibromo-9,9-didecyl fluorene (1.015 g), intermediate compound M-5 (0.099 g), palladium acetate (4.20 mg), tris(2-methoxyphenyl)phosphine (39.5 mg), toluene (53 mL), and a 20 mass % of tetraethylammonium hydroxide aqueous solution (9.62 g) were added to a four-necked flask, and stirred at 85° C. for 6 hours. Phenylboronic acid (225.8 mg), bis(triphenylphosphine) palladium(II) dichloride (78.6 mg), and a 20% by mass aqueous solution of tetraethylammonium hydroxide (9.62 g) were added thereto, and stirred at 85° C., for 6 hours. Afterwards, sodium N, N-diethyldithiocarbamidate trihydrate (6.31 g) dissolved in ion-exchanged water (50 mL) was added, and the mixture was stirred at 85° C. for 6 hours.

Then, the organic layer was isolated from the aqueous layer, and then the organic layer was washed with water, 3 mass % of acetic acid, and water. The organic layer was added dropwise to methanol to precipitate the polymer compound, which was separated and dried to provide a solid residue. The solid residue was dissolved in toluene, passed through a column of silica gel/alumina, and the solvent was removed by distillation under reduced pressure.

The obtained solution is added dropwise to methanol, and the precipitated solid was isolated, and dried to produce polymer compound P-2. For the obtained polymer compound P-2 (0.6 g), the weight average molecular weight (Mw) and polydispersity index (Mw/Mn) was measured by SEC. The measured weight average molecular weight (Mw) and polydispersity index (Mw/Mn) of polymer compound P-2 were 86,000 g/mol and 2.3, respectively.

The obtained polymer compound P-2 is considered to have the following structure based on the monomers (Intermediate compound M-2, 2,7-dibromo-9,9-didecyl fluorene, and intermediate compound M-5) and their ratios used to prepare the polymer compound:

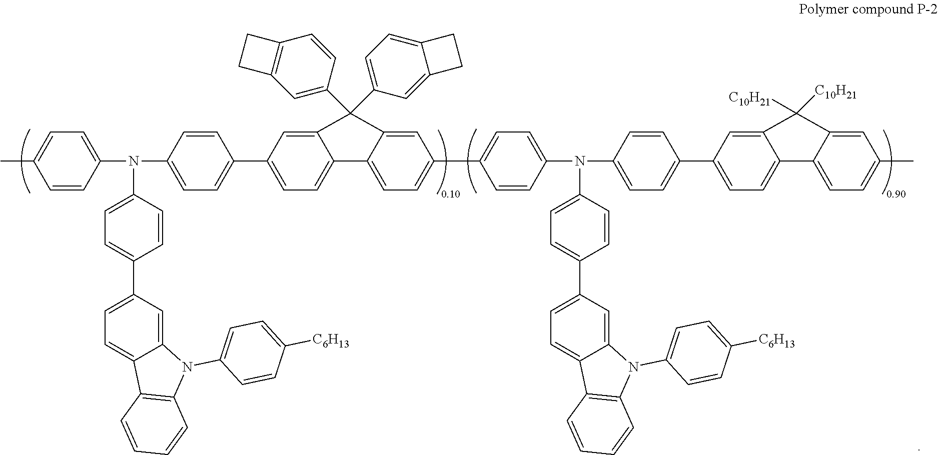

The terminal ends of polymer compound P-2 are assumed to have any one of the following structures:

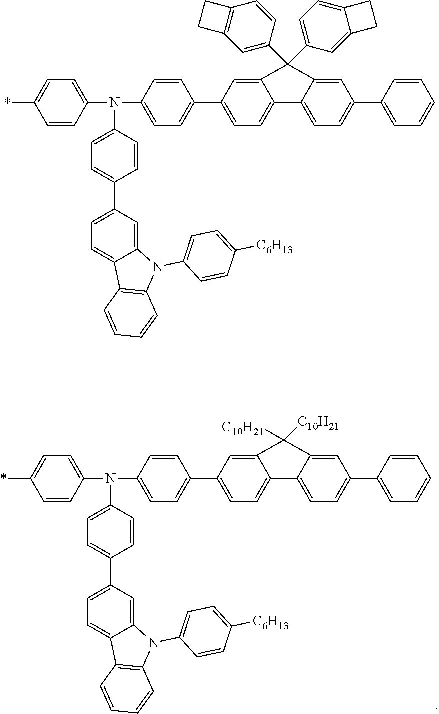

### Example 3

Under a nitrogen atmosphere, intermediate compound M-1 (1.382 g), 2,7-dibromo-9,9-didodecyl fluorene (0.999 g), intermediate compound M-6 (0.117 g), palladium acetate (3.80 mg), tris (2-methoxyphenyl) phosphine (35.5 mg), toluene (48 mL), and a 20% by mass aqueous solution of tetraethylammonium hydroxide (8.66 g) were added to a four-necked flask, and stirred at 85° C. for 6 hours. Phenyl boronic acid (203.2 mg), bis (triphenylphosphine) palladium (II) dichloride (70.7 mg), and 20 mass % aqueous solution of tetraethylammonium hydroxide (8.66 g) were added, and stirred at 85° C., for 6 hours. Then, sodium N,N-diethyldithiocarbamidate trihydrate (5.68 g) dissolved in ion-exchanged water (50 mL) was added, and the mixture was stirred at 85° C. for 6 hours.

For the obtained solution, the organic layer was separated from the aqueous layer, and then the organic layer was washed with water, a 3% by mass of acetic acid aqueous solution, and water. The organic layer was added dropwise to methanol to precipitate the polymer compound, which was isolated and dried to provide a solid residue. The solid residue was dissolved in toluene, passed through a column of silica gel/alumina, and the solvent was removed by distillation under reduced pressure.

The obtained solution was added dropwise to methanol, and the precipitated solid was isolated, and dried to provide polymer compound P-3. For the obtained polymer compound P-3 (1.3 g), the weight average molecular weight (Mw) and polydispersity index (Mw/Mn) were measured by SEC. The measured weight average molecular weight (Mw) and polydispersity index (Mw/Mn) of polymer compound P-3 were 88,100 g/mol and 2.1, respectively.

The obtained polymer compound P-3 is considered to have the following structure based on the monomers used (intermediate compound M-1, 2,7-dibromo-9,9-didodecylfluorene, intermediate compound M-6) and their ratios used to prepare the polymer compound:

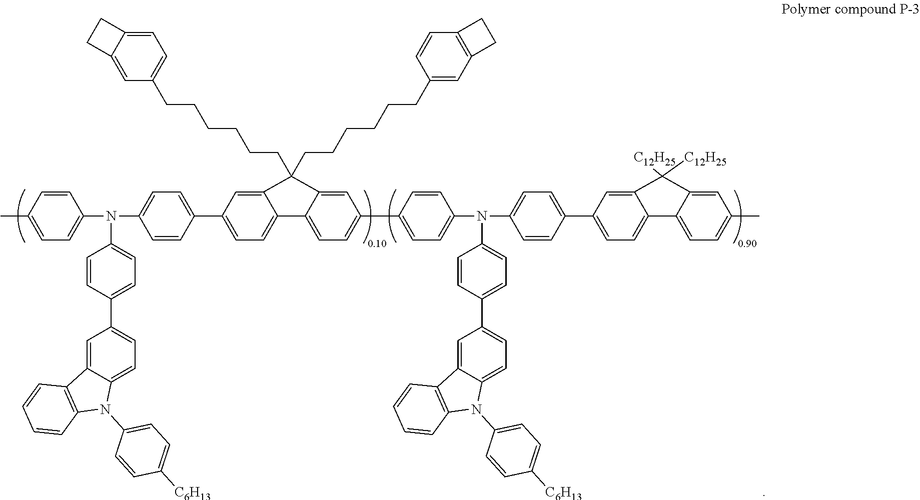

The terminal ends of polymer compound P-3 was assumed to have any one of the structures below:

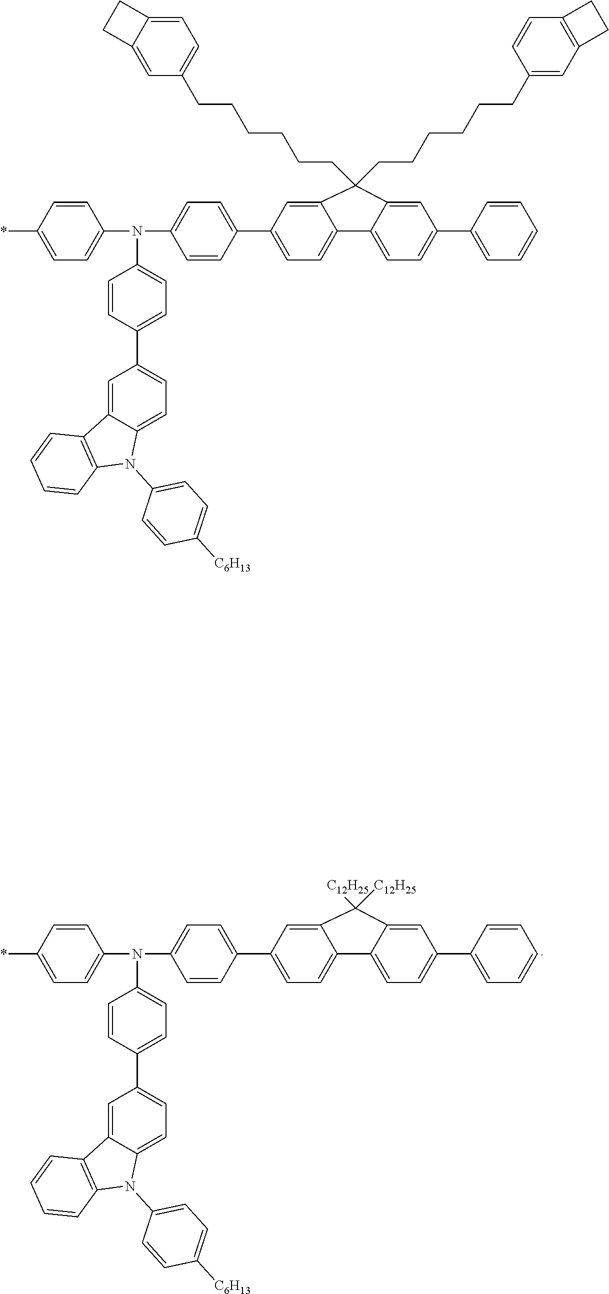

### Example 4

Under a nitrogen atmosphere, intermediate compound M-1 (1.382 g), 2,7-dibromo-9,9-didodecyl fluorene (0.999 g), intermediate M-7 (0.134 g), palladium acetate (3.80 mg), tris(2-methoxyphenyl)phosphine (35.5 mg), toluene (48 mL), and a 20% by mass aqueous solution of tetraethylammonium hydroxide (8.66 g) were added to a four-necked flask, and stirred at 85° C. for 6 hours. Phenyl boronic acid (203.2 mg), bis(triphenylphosphine) palladium (II) dichloride (70.7 mg), and a 20 mass % aqueous solution of tetraethylammonium hydroxide (8.66 g) were added thereto, and stirred at 85° C., for 6 hours. Afterwards, sodium N, N-diethyldithiocarbamidate trihydrate (5.68 g) dissolved in ion-exchanged water (50 mL) was added, and stirred at 85° C. for 6 hours.

For the obtained solution, the organic layer was isolated from the aqueous layer, and the organic layer was washed with water, 3 mass % of acetic acid, and water. The organic layer was added dropwise to methanol to precipitate the polymer compound, which was isolated, and dried to provide a solid residue. The solid residue was dissolved in toluene, passed through a column of silica gel/alumina, and the solvent was removed by distillation under reduced pressure.

The obtained liquid was added dropwise to methanol, and the precipitated solid was separated, and dried to provide polymer compound P-4. For the obtained polymer compound P-4 (1.4 g), the weight average molecular weight (Mw) and polydispersity index (Mw/Mn) were measured by SEC. The measured weight average molecular weight (Mw) and polydispersity index (Mw/Mn) of polymer compound P-4 were 86,400 g/mol and 2.2, respectively.

The obtained polymer compound P-4 is considered to have the following structure based on the monomers (intermediate compound M-1, 2,7-dibromo-9,9-didodecyl fluorene, and intermediate compound M-7) and their ratios used to prepare the polymer compound:

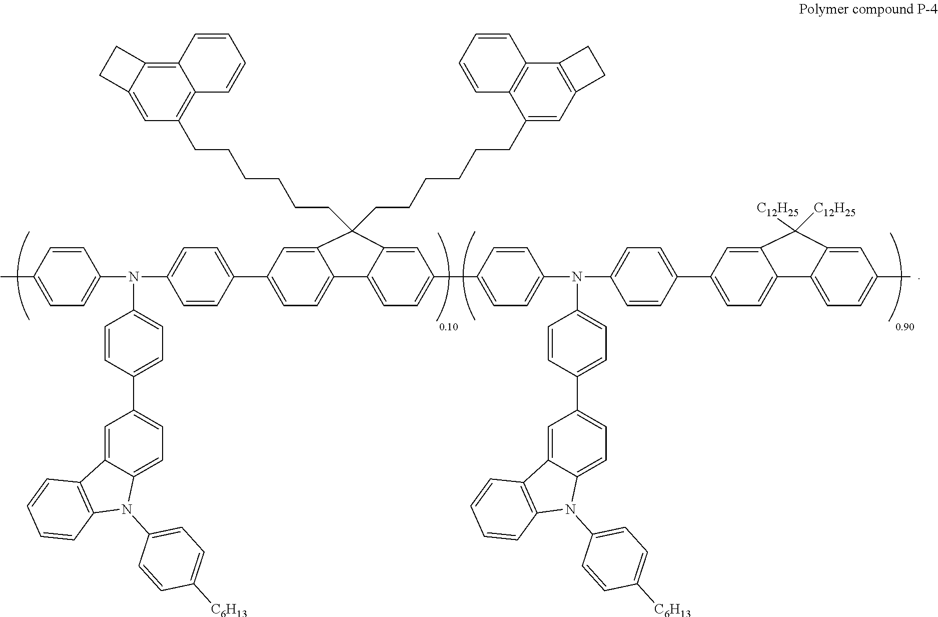

The terminal ends of polymer compound P-4 are assumed to have any one of the structures below:

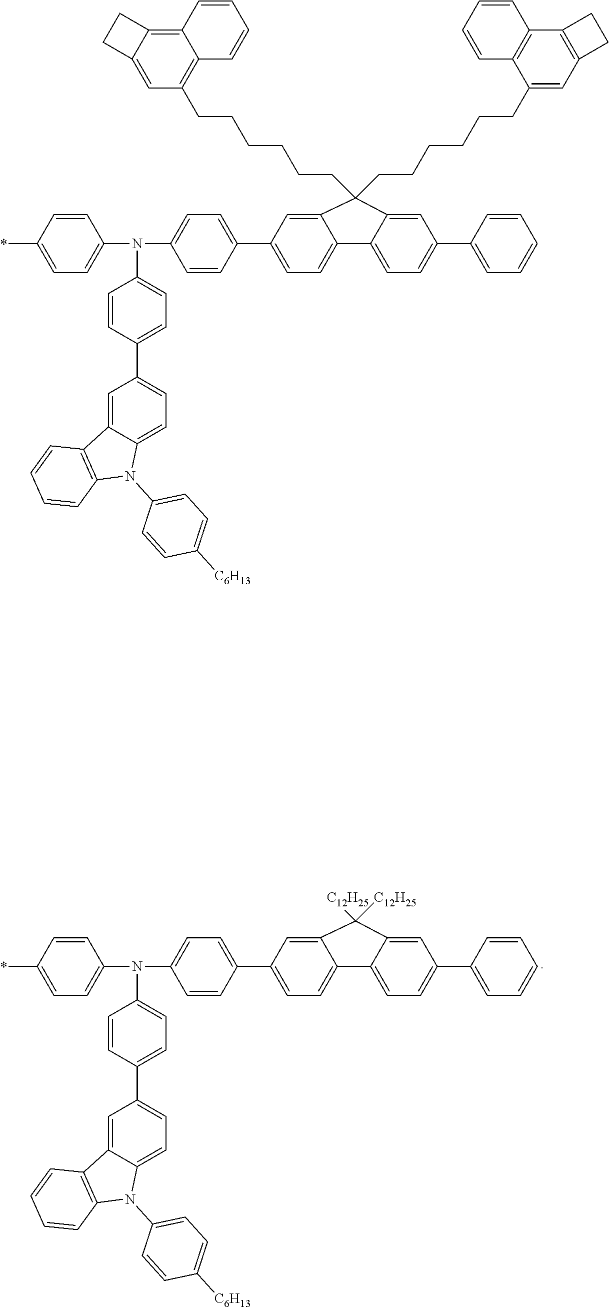

### Example 5

Under a nitrogen atmosphere, intermediate compound M-3 (1.662 g), 2,7-dibromo-9,9-dioctylfluorene (0.921 g), intermediate compound M-7 (0.149 g), palladium acetate (4.20 mg), tris(2-methoxyphenyl) phosphine (39.5 mg), toluene (52 mL), and a 20% by mass aqueous solution of tetraethylammonium hydroxide (9.62 g) were added to a four-necked flask, and stirred at 85° C. for 6 hours. Phenyl boronic acid (225.8 mg), bis(triphenylphosphine) palladium (II) dichloride (78.6 mg), and a 20 mass % aqueous solution of tetraethyl ammonium hydroxide (9.62 g) were added thereto, and stirred at 85° C. for 6 hours. Afterwards, sodium N, N-diethyldithiocarbamidate trihydrate (6.31 g) dissolved in ion-exchanged water (50 mL) was added, and the mixture was stirred at 85° C. for 6 hours.

For the obtained solution, the organic layer was isolated from the aqueous layer, and the organic layer was washed with water, 3 mass % of acetic acid, and water. The organic layer was added dropwise to methanol to precipitate the polymer compound, which was separated, and dried to provide a solid residue. The solid residue was dissolved in toluene, passed through a column of silica gel/alumina, and the solvent was removed by distillation under reduced pressure.

The obtained solution was added dropwise to methanol, and the precipitated solids were separated and dried to provide polymer compound P-5. For the obtained polymer compound P-5 (0.87 g), the weight average molecular weight (Mw) and polydispersity index (Mw/Mn) were measured by SEC. The measured weight average molecular weight (Mw) and polydispersity index (Mw/Mn) of polymer compound P-5 were 174,400 g/mol and 1.7, respectively.

The obtained polymer compound P-5 was considered to have the following structure based on the monomers (intermediate compound M-3, 2,7-dibromo-9,9-dioctyl fluorene, and intermediate compound M-7) and their ratios used to prepare the polymer compound:

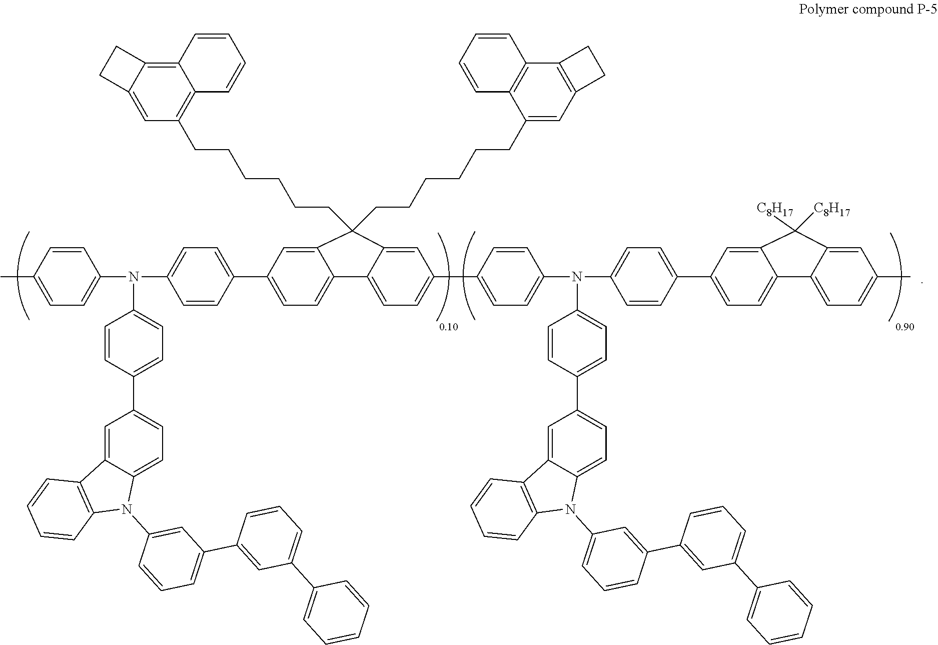

The terminal ends of polymer compound P-5 are assumed to have any one of the structures below:

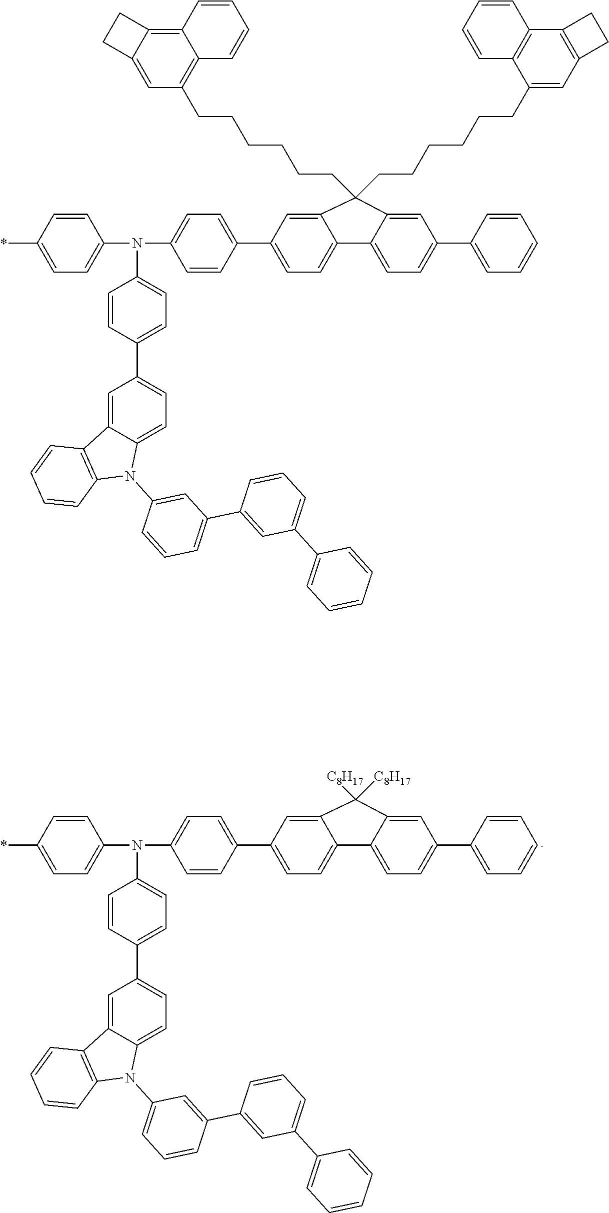

### Example 6

Under a nitrogen atmosphere, intermediate compound M-1 (1.382 g), 2,7-dibromo-9,9-didodecylfluorene (1.233 g), intermediate compound M-8 (0.112 g), palladium acetate (4.20 mg), tris (2-methoxyphenyl) phosphine (35.5 mg), toluene (52 mL), and a 20% by mass aqueous solution of tetraethylammonium hydroxide (8.66 g) were added to a four-necked flask, and stirred at 85° C. for 6 hours. Phenylboronic acid (182.9 mg), bis(triphenylphosphine) palladium(II) dichloride (78.6 mg), and a 20 mass % aqueous solution of tetraethylammonium hydroxide (8.66 g) were added, and stirred at 85° C. for 6 hours. Afterwards, sodium N, N-diethyldithiocarbamidate trihydrate (5.68 g) dissolved in ion-exchanged water (50 mL) was added, and stirred at 85° C. for 6 hours.

For the obtained solution, the organic layer was isolated from the aqueous layer, and the organic layer was mixed with water, 3 mass % of acetic acid, and water. After dropping the organic layer into methanol to precipitate a polymer compound, which was separated and dried to provide a solid residue. The solid residue was dissolved in toluene, passed through a column of silica gel/alumina, and the solvent was removed by distillation under reduced pressure.

The obtained liquid was added dropwise to methanol, and the precipitated solid was separated and dried to provide polymer compound P-6. For the obtained polymer compound P-6 (1.0 g), the weight average molecular weight (Mw) and polydispersity index (Mw/Mn) were measured by SEC. The measured weight average molecular weight (Mw) and polydispersity index (Mw/Mn) of polymer compound P-6 were 136,000 g/mol and 1.9, respectively.

The obtained polymer compound P-6 is considered to have the following structure based on the monomers (intermediate compound M-1, 2,7-dibromo-9,9-didodecyl fluorene, and intermediate compound M-8) and their ratios used to prepare the polymer compound:

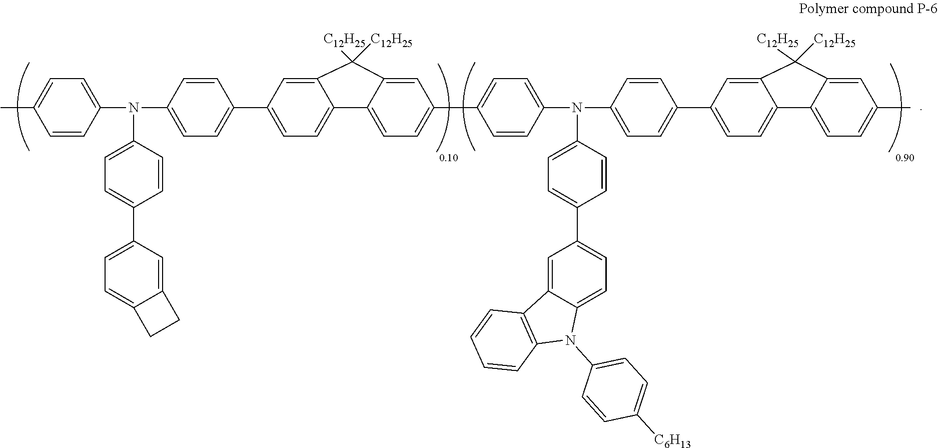

The terminal ends of polymer compound P-6 are assumed to have any one of the structures below:

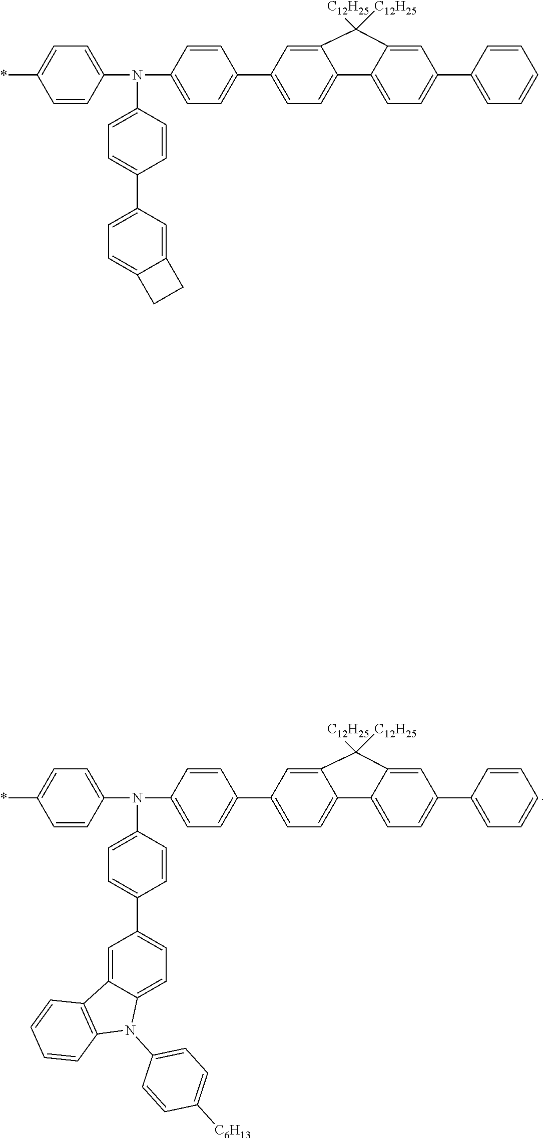

### Example 7

Under a nitrogen atmosphere, intermediate compound M-2 (1.382 g), 2,7-dibromo-9,9-didecylfluorene (1.128 g), intermediate compound M-8 (0.112 g), palladium acetate (4.20 mg), tris(2-methoxyphenyl) phosphine (35.5 mg), toluene (50 mL), and a 20 mass % aqueous solution of tetraethylammonium hydroxide (8.66 g) were added to a four-necked flask, and stirred at 85° C. for 6 hours. Phenylboronic acid (182.9 mg), bis(triphenylphosphine) palladium(II) dichloride (78.6 mg), and a 20 mass % aqueous solution of tetraethylammonium hydroxide (8.66 g) were added, and stirred at 85° C. for 6 hours. Afterwards, N, N-diethyldithiocarbamidate sodium trihydrate (5.68 g) dissolved in ion-exchanged water (50 mL) was added, and stirred at 85° C. for 6 hours.

For the obtained solution, after separating the organic layer from the aqueous layer, the organic layer was washed with water, 3 mass % of acetic acid, and water. The organic layer was added dropwise to methanol to precipitate the polymer compound, which is separated, and dried to provide a solid residue. The solid residue was dissolved in toluene, passed through a column of silica gel/alumina, and the solvent was removed by distillation under reduced pressure.

The obtained solution was added dropwise to methanol, and the precipitated solid was separated and dried to provide polymer compound P-7. For the obtained polymer compound P-7 (0.68 g), the weight average molecular weight (Mw) and polydispersity index (Mw/Mn) were measured by SEC. The measured weight average molecular weight (Mw) and polydispersity index (Mw/Mn) of polymer compound P-7 were 124,000 g/mol and 1.7, respectively.

The obtained polymer compound P-7 is considered to have the following structure based on the monomers (intermediate compound M-2, 2,7-dibromo-9,9-didodecyl fluorene, and intermediate compound M-8) and their ratios used to prepare the polymer compound:

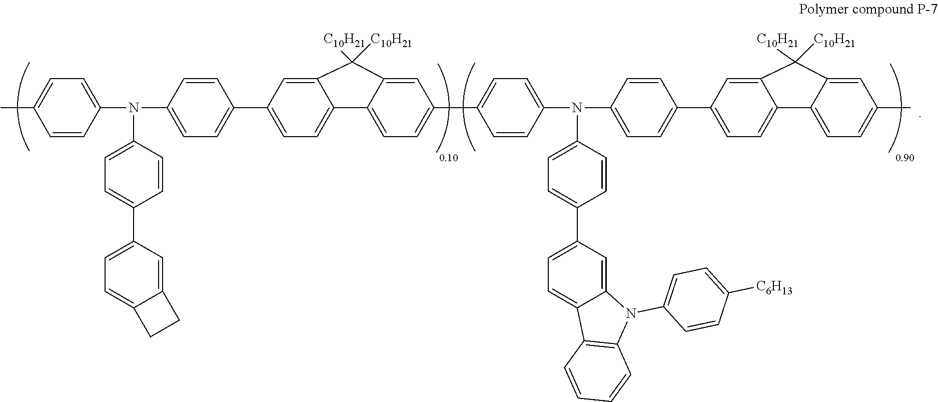

The terminal ends of polymer compound P-7 are assumed to have any one of the structures below:

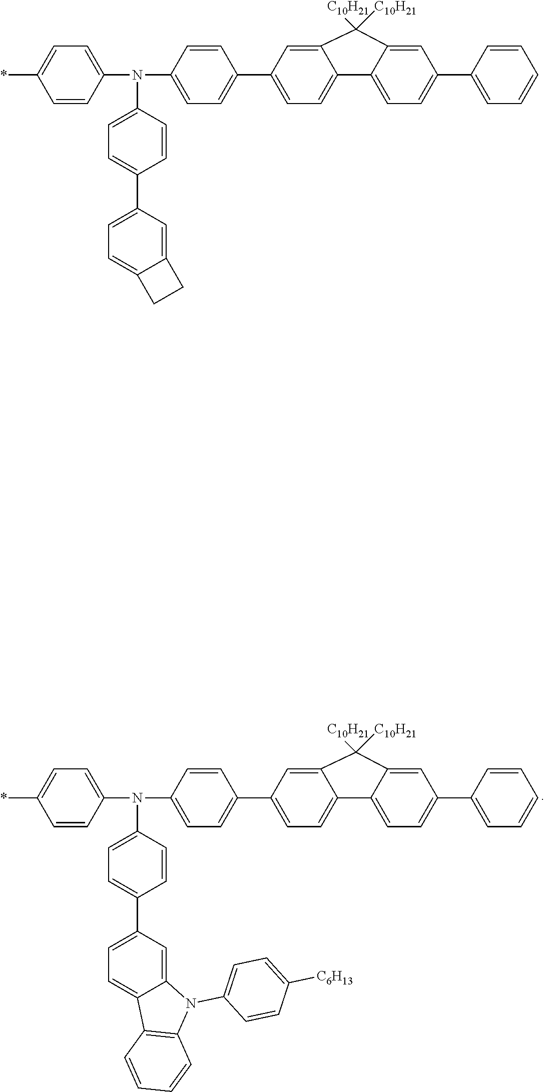

### Example 8

Under a nitrogen atmosphere, intermediate compound M-1 (1.382 g), 2,7-dibromo-9,9-didodecylfluorene (1.233 g), intermediate compound M-9 (0.121 g), palladium acetate (4.20 mg), tris(2-methoxyphenyl) phosphine (35.5 mg), toluene (50 mL), and a 20 mass % aqueous solution of tetraethylammonium hydroxide (8.66 g) were added to a four-necked flask and stirred at 85° C. for 6 hours. Phenylboronic acid (182.9 mg), bis(triphenylphosphine)palladium(II) dichloride (78.6 mg), and a 20 mass % aqueous solution of tetraethylammonium hydroxide (8.66 g) were added, and stirred at 85° C. for 6 hours. Afterwards, N, N-diethyldithiocarbamidate sodium trihydrate (5.68 g) dissolved in ion-exchanged water (50 mL) was added, and stirred at 85° C. for 6 hours.

For the obtained solution, after separating the organic layer from the aqueous layer, the organic layer was washed with water, 3 mass % of acetic acid, and water. The organic layer was added dropwise to methanol to precipitate the polymer compound, separated, and dried to provide a solid residue. The solid residue was dissolved in toluene, passed through a column of silica gel/alumina, and the solvent was removed by distillation under reduced pressure.

The obtained solution was added dropwise to methanol, and the precipitated solids were separated and dried to provide polymer compound P-8. For the obtained polymer compound P-8 (1.4 g), the weight average molecular weight (Mw) and polydispersity index (Mw/Mn) were measured by SEC. The measured weight average molecular weight (Mw) and polydispersity index (Mw/Mn) of polymer compound P-8 were 151,000 g/mol and 2.8, respectively.

The obtained polymer compound P-8 is considered to have the following structure based on the monomers (intermediate compound M-1, 2,7-dibromo-9,9-didodecylfluorene, intermediate compound M-9) and their ratios used to prepare the polymer compound:

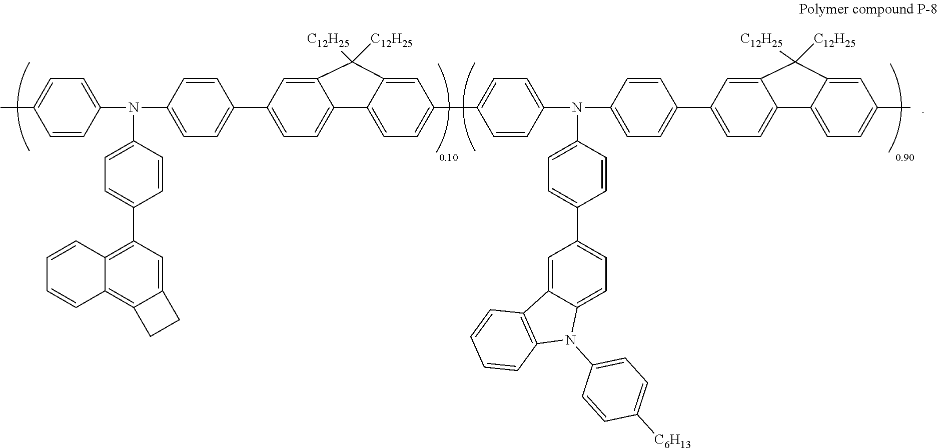

The terminal ends of polymer compound P-8 are assumed to have any one of the structures below:

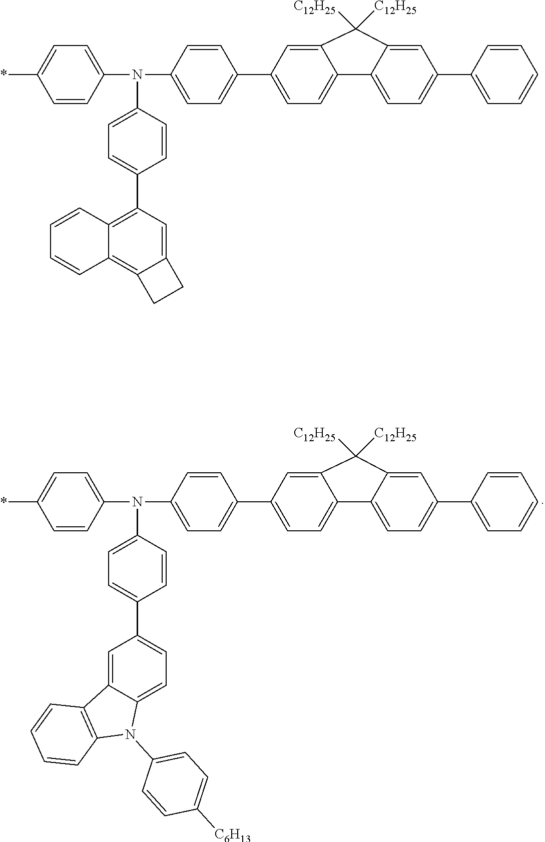

### Example 9

Under a nitrogen atmosphere, intermediate compound M-1 (1.443 g), 2,7-dibromo-9,9-didodecylfluorene (1.233 g), intermediate compound M-9 (0.073 g), palladium acetate (4.20 mg), tris (2-methoxyphenyl) phosphine (35.5 mg), toluene (50 mL), and a 20 mass % aqueous solution of tetraethylammonium hydroxide (8.66 g) were added to a four-necked flask, and stirred at 85° C. for 6 hours. Phenylboronic acid (182.9 mg), bis(triphenylphosphine) palladium(II) dichloride (78.6 mg), and a 20 mass % aqueous solution of tetraethylammonium hydroxide (8.66 g) were added, and stirred at 85° C. for 6 hours. Afterwards, N, N-diethyldithiocarbamidate sodium trihydrate (5.68 g) dissolved in ion-exchanged water (50 mL) was added, and stirred at 85° C. for 6 hours.

For the obtained solution, after separating the organic layer from the aqueous layer, the organic layer was washed with water, 3 mass % of acetic acid, and water. The organic layer was added dropwise to methanol to precipitate the polymer compound, which was separated and dried to provide a solid residue. The solid residue was dissolved in toluene, passed through a column of silica gel/alumina, and the solvent was removed by distillation under reduced pressure.

The obtained solution was added dropwise to methanol, and the precipitated solids were separated and dried to provide polymer compound P-9. For the obtained polymer compound P-9 (0.7 g), the weight average molecular weight (Mw) and polydispersity index (Mw/Mn) were measured by SEC. The measured weight average molecular weight (Mw) and polydispersity index (Mw/Mn) of polymer compound P-9 were 133,600 g/mol and 2.9, respectively.

The obtained polymer compound P-9 is considered to have the following structure based on the monomers (intermediate compound M-1, 2,7-dibromo-9,9-didodecylfluorene, intermediate compound M-9) and their ratios used to prepare the polymer compound:

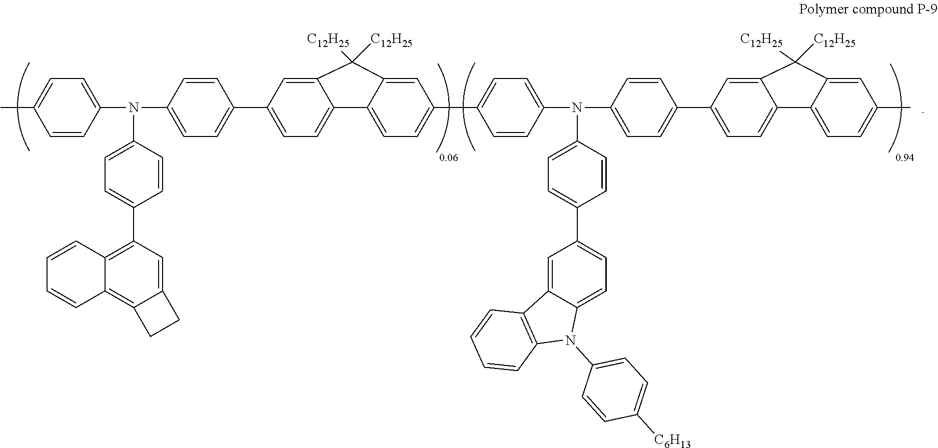

The terminal ends of polymer compound P-9 are assumed to have any one of the structures below:

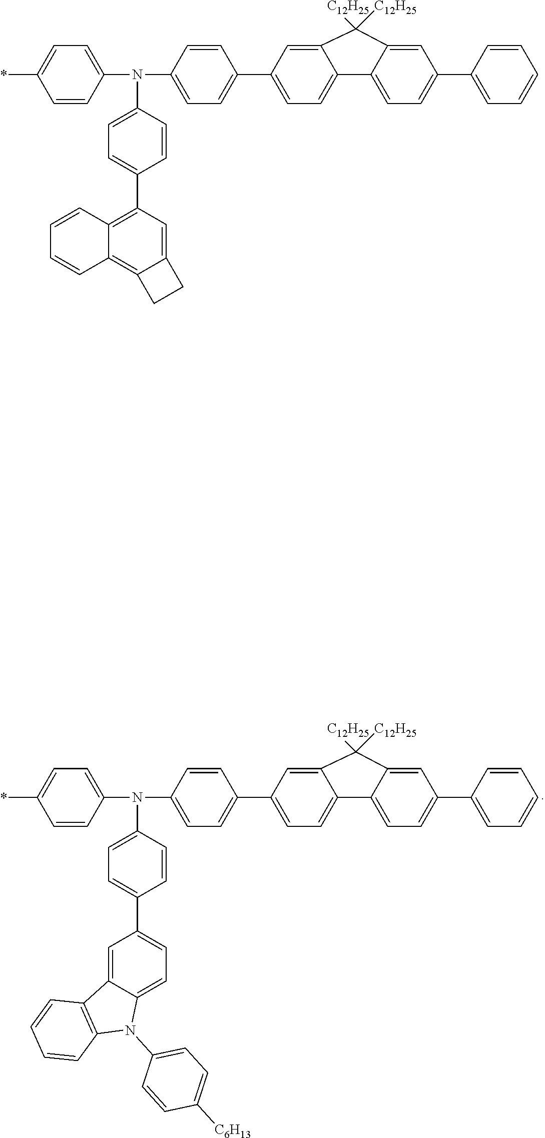

### Example 10

Under a nitrogen atmosphere, intermediate compound M-2 (1.382 g), 2, 7-dibromo-9,9-didecylfluorene (1.128 g), intermediate compound M-9 (0.121 g), palladium acetate (4.20 mg), tris (2-methoxy phenyl) phosphine (35.5 mg), toluene (50 mL), and a 20% by mass aqueous solution of tetraethylammonium hydroxide (8.66 g) were added to a four-necked flask, and stirred at 85° C. for 6 hours. Phenyl boronic acid (182.9 mg), bis(triphenylphosphine) palladium (II) dichloride (78.6 mg), and a 20 mass % aqueous solution of tetraethylammonium hydroxide (8.66 g) were added thereto, and stirred at 85° C. for 6 hours. Afterwards, N, N-diethyldithiocarbamidate sodium trihydrate (5.68 g) dissolved in ion-exchanged water (50 mL) was added, and stirred at 85° C. for 6 hours.

For the obtained solution, after separating the organic layer from the aqueous layer, the organic layer was washed with water, 3 mass % of acetic acid, and water. The organic layer was added dropwise to methanol to precipitate the polymer compound, separated, and dried to provide a solid residue. The solid residue was dissolved in toluene, passed through a column of silica gel/alumina, and the solvent was removed by distillation under reduced pressure.

The obtained solution was added dropwise to methanol, and the precipitated solids were isolated and dried to provide polymer compound P-10. For the obtained polymer compound P-10 (0.9 g), the weight average molecular weight (Mw) and polydispersity index (Mw/Mn) were measured by SEC. The measured weight average molecular weight (Mw) and polydispersity index (Mw/Mn) of polymer compound P-10 were 77,000 g/mol and 2.5, respectively.

The obtained polymer compound P-10 is considered to have the following structure based on the monomers (intermediate compound M-2, 2,7-dibromo-9,9-didecylfluorene, intermediate compound M-9) and their ratios used to prepare the polymer compound:

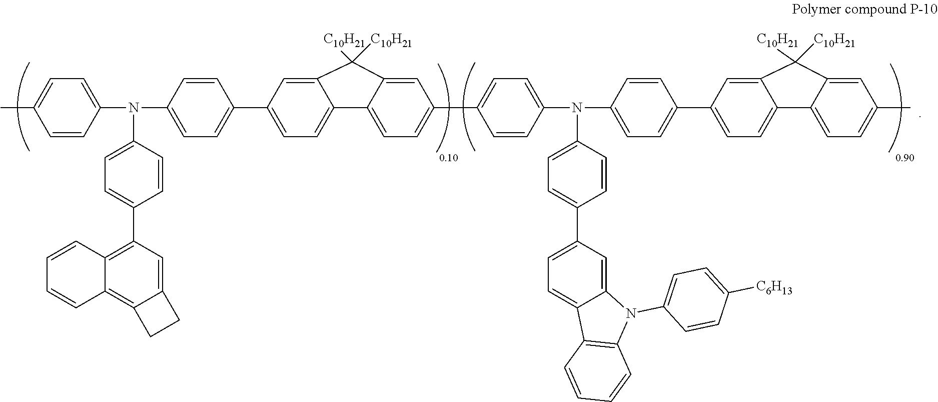

The terminal ends of polymer compound P-10 are assumed to have any one of the structures below:

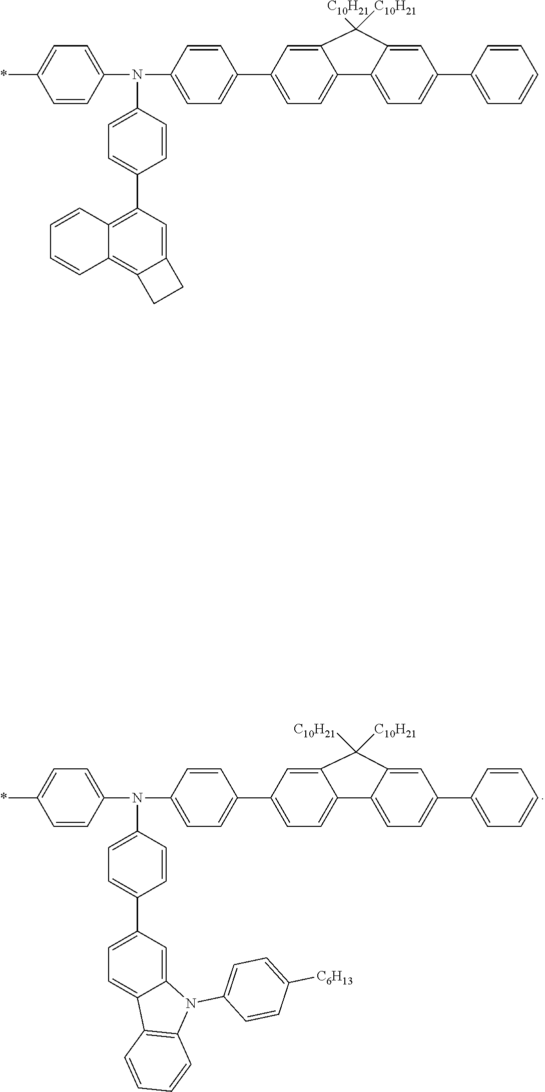

### Example 11

Under a nitrogen atmosphere, intermediate compound M-1 (1.382 g), 2,8-dibromo-6,6,12,12-tetradodecyl-6,12-dihydroindeno[1,2-b]fluorene (2.0268 g), intermediate compound M-9 (0.121 g), palladium acetate (4.20 mg), tris(2-methoxy phenyl)phosphine (35.5 mg), toluene (50 mL), and a 20% by mass aqueous solution of tetraethylammonium hydroxide (8.66 g) were added to a four-necked flask, and stirred at 85° C., for 6 hours. Phenylboronic acid (182.9 mg), bis(triphenylphosphine)palladium(II) dichloride (78.6 mg), and a 20% by mass aqueous solution of tetraethylammonium hydroxide (8.66 g) were added, and stirred at 85° C. for 6 hours. Afterwards, sodium N, N-diethyldithiocarbamidate trihydrate (5.68 g) dissolved in ion-exchanged water (50 mL) was added, and the mixture was stirred at 85° C. for 6 hours.

For the obtained solution, after separating the organic layer from the aqueous layer, the organic layer was washed with water, 3 mass % of acetic acid, and water. The organic layer was added dropwise to methanol to precipitate the polymer compound, which was separated, and dried to provide a solid residue. The solid residue was dissolved in toluene, passed through a column of silica gel/alumina, and the solvent was removed by distillation under reduced pressure.

The obtained liquid was added dropwise to methanol, and the precipitated solids were separated and dried to provide polymer compound P-11. For the obtained polymer compound P-11 (0.94 g), the weight average molecular weight (Mw) and polydispersity index (Mw/Mn) were measured by SEC. The measured weight average molecular weight (Mw) and polydispersity index (Mw/Mn) of polymer compound P-11 were 114,300 g/mol and 2.5, respectively.

The obtained polymer compound P-11 is considered to have the following structure based on the monomers (intermediate compound M-1, 2,8-dibromo-6,6,12,12-tetra dodecyl-6,12-dihydroindeno[1,2-b]fluorene, and intermediate compound M-9) and their ratios used to prepare the polymer compound:

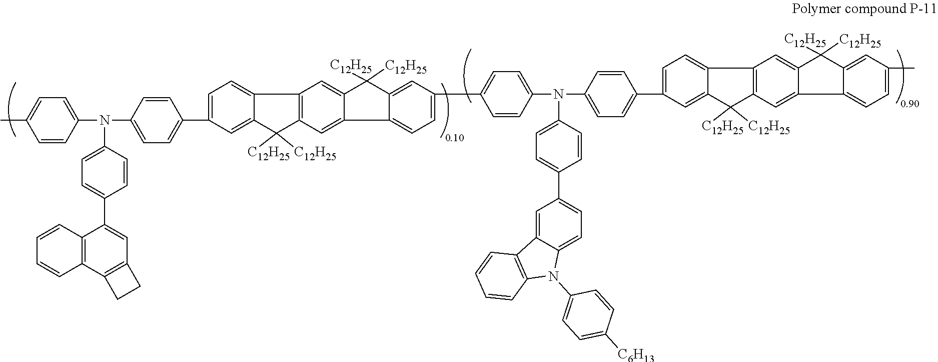

The terminal ends of polymer compound P-11 are assumed to have any one of the structures:

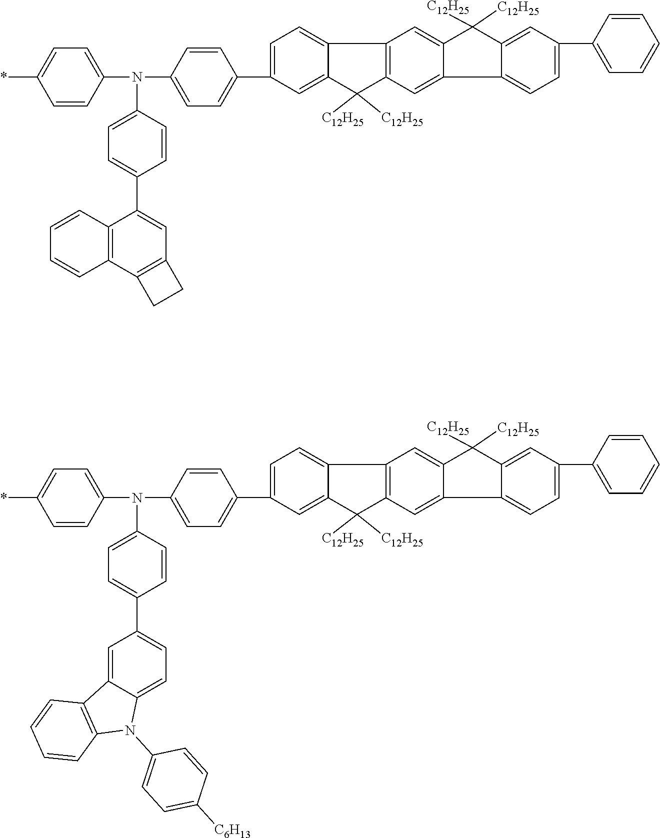

### Example 12

Under a nitrogen atmosphere, intermediate compound M-2 (1.382 g), 2,7-dibromo-9,9-dioctadecyl fluorene (1.547 g), intermediate compound M-9 (0.121 g), 4-bromo-1, 1′-biphenyl (0.052 g), 4,4″-dibromo-5′-(4-bromophenyl)-1,1′:3′,1″-terphenyl (0.101 g), palladium acetate (4.20 mg), tris(2-methoxy phenyl) phosphine (35.5 mg), toluene (50 mL), and a 20% by mass aqueous solution of tetraethylammonium hydroxide (8.66 g) are added to a four-necked flask, and stirred at 85° C. for 6 hours. Phenyl boronic acid (182.9 mg), bis(triphenylphosphine)palladium(II) dichloride (78.6 mg), and a 20 mass % aqueous solution of tetraethylammonium hydroxide (8.66 g) were added, and stirred at 85° C. for 6 hours. Afterwards, N, N-diethyldithiocarbamidate sodium trihydrate (5.68 g) dissolved in ion-exchanged water (50 mL) was added, and the mixture was stirred at 85° C. for 6 hours.

For the obtained solution, after separating the organic layer from the aqueous layer, the organic layer was washed with water, 3 mass % of acetic acid, and water. The organic layer was added dropwise to methanol to precipitate the polymer compound, which was separated, and dried to provide a solid residue. The solid residue was dissolved in toluene, passed through a column of silica gel/alumina, and the solvent was removed by distillation under reduced pressure.

The obtained liquid was added dropwise to methanol, and the precipitated solids were separated and dried to provide polymer compound P-12. For the obtained polymer compound P-12 (0.6 g), the weight average molecular weight (Mw) and polydispersity index (Mw/Mn) were measured by SEC. The measured weight average molecular weight (Mw) and polydispersity index (Mw/Mn) of polymer compound P-12 were 123,000 g/mol and 5.38, respectively.

The obtained polymer compound P-12 is considered to have the following structure based on the monomers (intermediate compound M-2, 2,7-dibromo-9,9-dioctadecyl fluorene, intermediate compound M-9, and 4-bromo-1,1′-biphenyl,4,4″-dibromo-5′-(4-bromophenyl)-1,1′:3′-1″-terphenyl) and their ratios used to prepare the polymer compound:

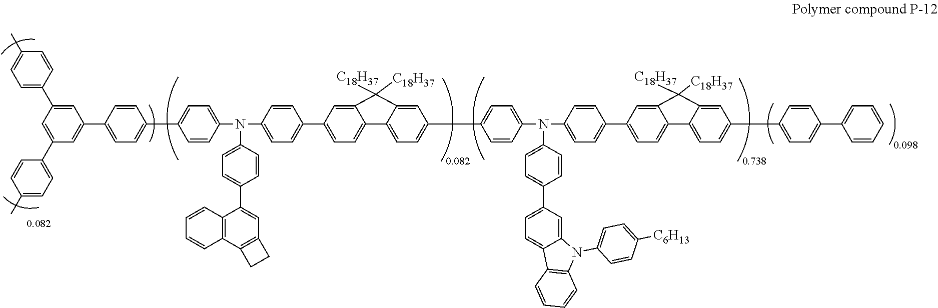

The terminal ends of polymer compound P-12 are assumed to have any one of the structures below:

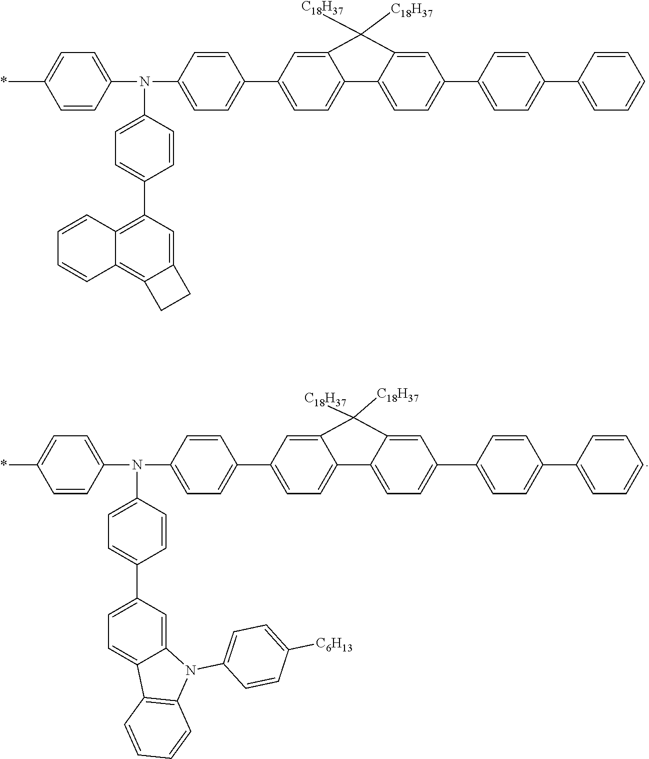

### Example 13

Under a nitrogen atmosphere, intermediate compound M-2 (1.623 g), 2,7-dibromo-9,9-didecylfluorene (1.074 g), intermediate compound M-10 (0.203 g), palladium acetate (4.40 mg), tris(2-methoxyphenyl) phosphine (41.7 mg), toluene (54 mL), and a 20% by mass aqueous solution of tetraethylammonium hydroxide (10.17 g) were added to a four-necked flask, and stirred at 85° C. for 6 hours. Phenylboronic acid (238.8 mg), bis(triphenylphosphine) palladium (II) dichloride (83.1 mg), and a 20% by mass aqueous solution of tetraethylammonium hydroxide (10.17 g) were added, and stirred at 85° C. for 6 hours. Afterwards, sodium N, N-diethyldithiocarbamidate trihydrate (6.67 g) dissolved in ion-exchanged water (50 mL) was added, and stirred at 85° C. for 6 hours.

For the obtained solution, after separating the organic layer from the aqueous layer, the organic layer was washed with water, 3 mass % of acetic acid, and water. The organic layer was added dropwise to methanol to precipitate the polymer compound, which was separated, and dried to provide a solid residue. The solid residue was dissolved in toluene, passed through a column of silica gel/alumina, and the solvent was removed by distillation under reduced pressure.

The obtained solution was added dropwise to methanol, and the precipitated solids were isolated and dried to provide polymer compound P-13. For the obtained polymer compound P-13 (1.0 g), the weight average molecular weight (Mw) and polydispersity index (Mw/Mn) were measured by SEC. The measured weight average molecular weight (Mw) and polydispersity index (Mw/Mn) of polymer compound P-13 were 92,000 g/mol and 1.8, respectively.

The obtained polymer compound P-13 is considered to have the following structure based on the monomers (intermediate compound M-2, 2,7-dibromo-9,9-didecylfluorene, and intermediate compound M-10) and their ratios used to prepare the polymer compound:

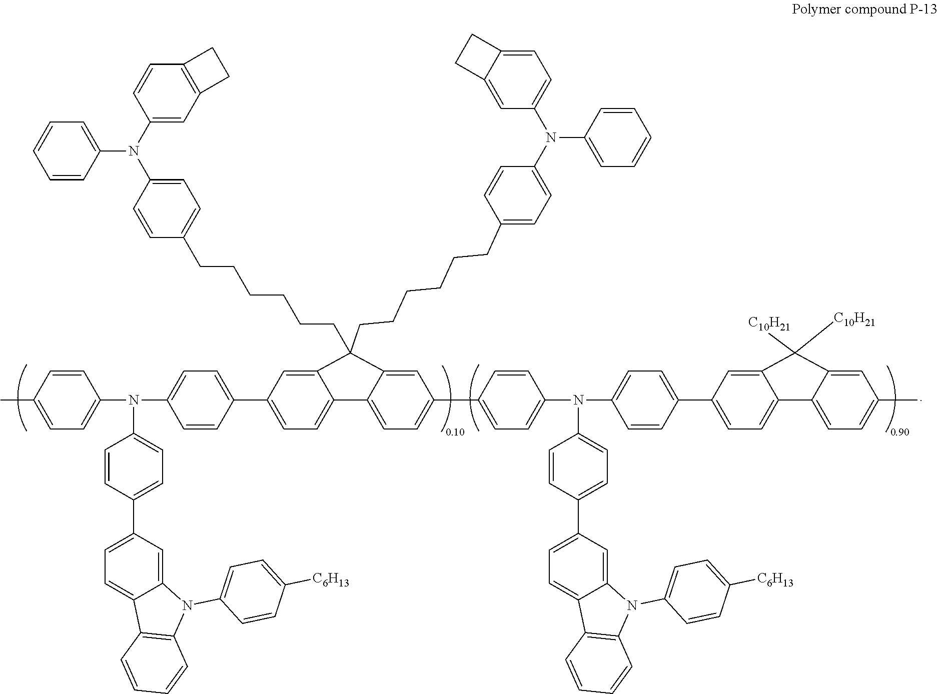

The terminal ends of polymer compound P-13 are assumed to have any one of the structures below:

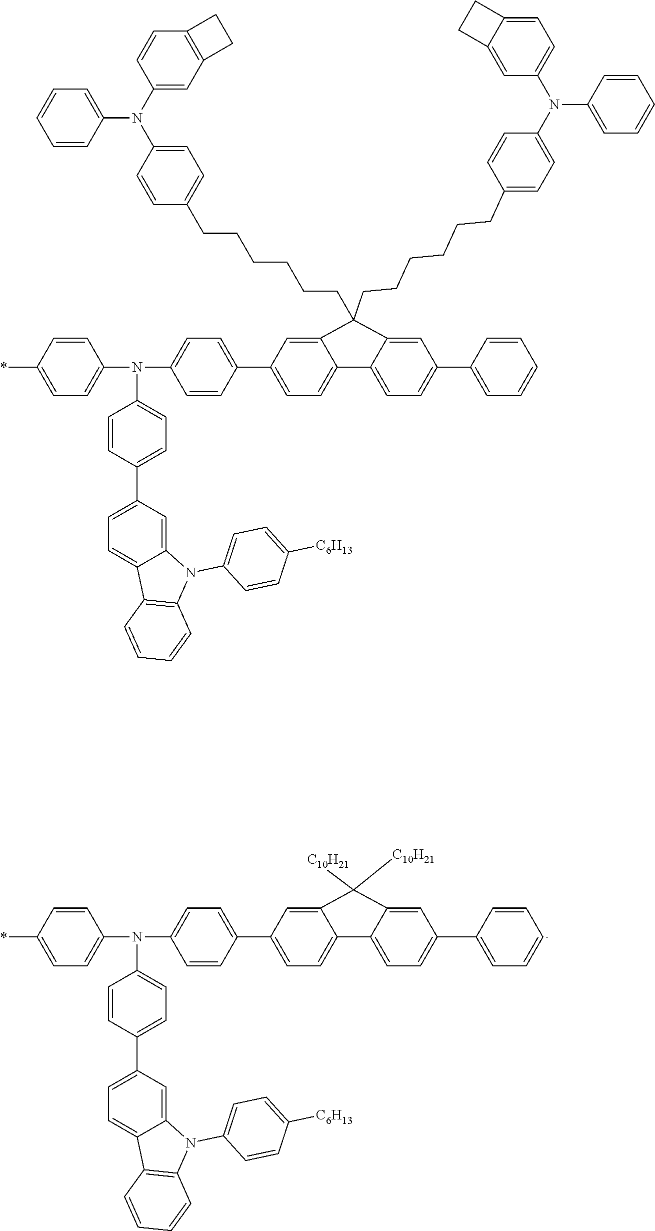

### Example 14

Under a nitrogen atmosphere, intermediate compound M-4 (1.647 g), 2,7-dibromo-9,9-didecylfluorene (1.006 g), intermediate compound M-10 (0.191 g), palladium acetate (4.20 mg), tris (2-methoxyphenyl) phosphine (39.1 mg), toluene (54 mL), and a 20% by mass aqueous solution of tetraethylammonium hydroxide (9.53 g) were added to a four-necked flask, and stirred at 85° C. for 6 hours. Phenyl boronic acid (223.8 mg), bis(triphenylphosphine) palladium (II) dichloride (77.9 mg), and a 20 mass % aqueous solution of tetraethylammonium hydroxide (9.53 g) were added, and stirred at 85° C. for 6 hours. Afterwards, N, N-diethyldithiocarbamidate sodium trihydrate (6.25 g) dissolved in ion-exchanged water (50 mL) was added, and stirred at 85° C. for 6 hours.

For the obtained solution, after separating organic layer from the aqueous layer, the organic layer is washed with water, 3 mass % of acetic acid, and water. The organic layer is added dropwise to methanol to precipitate a polymer compound, which is separated, and and dried to obtain a solid. The solid is dissolved in toluene, passed through a column chromatography filled with silica gel/alumina, and the solvent is removed by distillation under reduced pressure.

The obtained solution was added dropwise to methanol, and the precipitated solids were isolated and dried to provide polymer compound P-14. For the obtained polymer compound P-14 (1.0 g), the weight average molecular weight (Mw) and polydispersity index (Mw/Mn) were measured by SEC. The measured weight average molecular weight (Mw) and polydispersity index (Mw/Mn) of polymer compound P-14 were 109,000 g/mol and 1.7, respectively.

The obtained polymer compound P-14 is considered to have the following structure based on the monomers (intermediate compound M-4, 2,7-dibromo-9,9-didecylfluorene, intermediate compound M-10) and their ratios used to prepare the polymer compound:

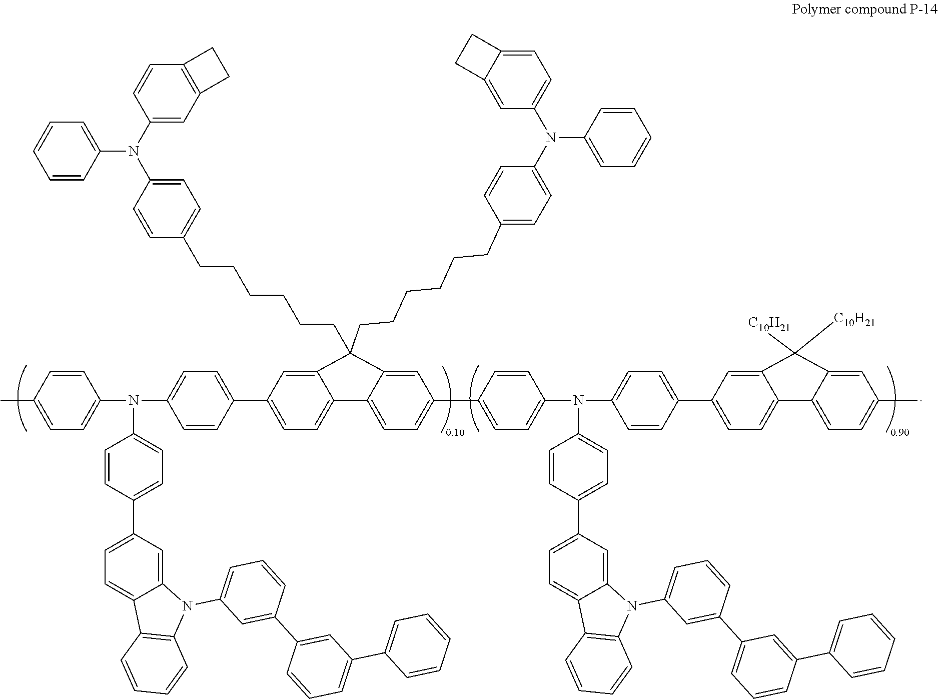

The terminal ends of polymer compound P-14 are assumed to have any one of the structures below:

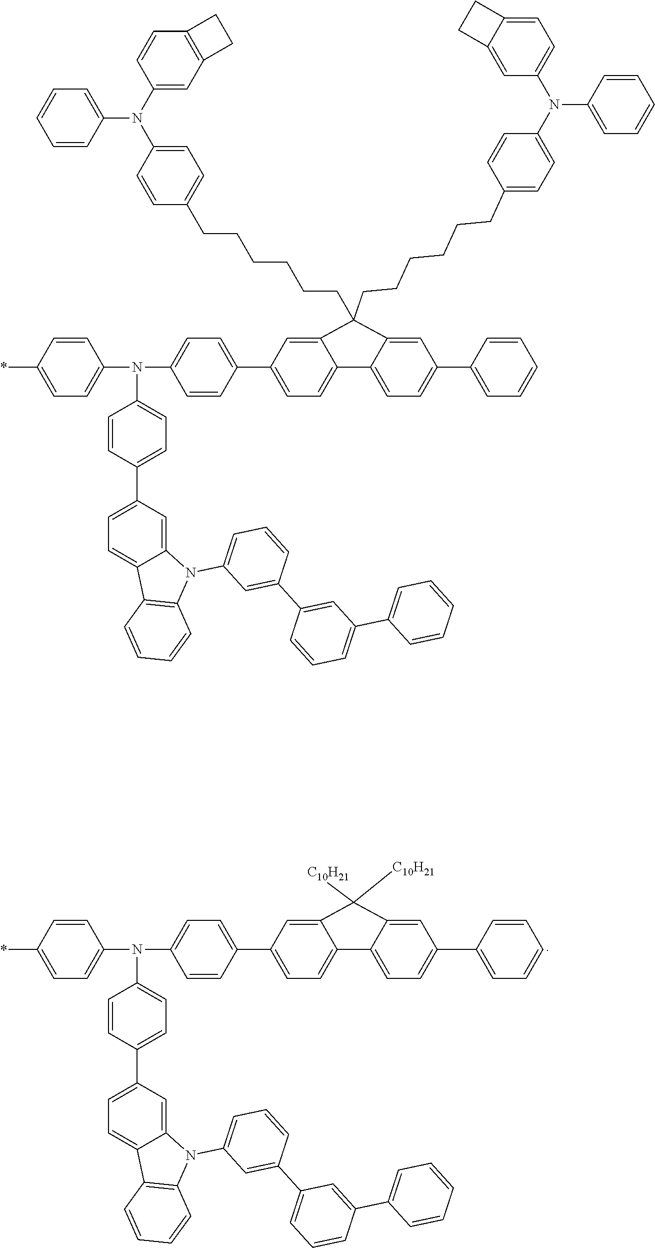

### Comparative Example 1

Comparative polymer compound P-15 was synthesized by the method described in Example 6 of Japanese Patent Laid-Open Publication No.: 2021138915A for preparing Polymer Compound P-6.

Obtained comparative polymer compound P-15 had a weight average molecular weight (Mw) and polydispersity index (Mw/Mn) of 108,000 g/mol and 2.70, respectively.

Comparative polymer compound P-15 is considered to have the following structural unit from the composition of the monomers:

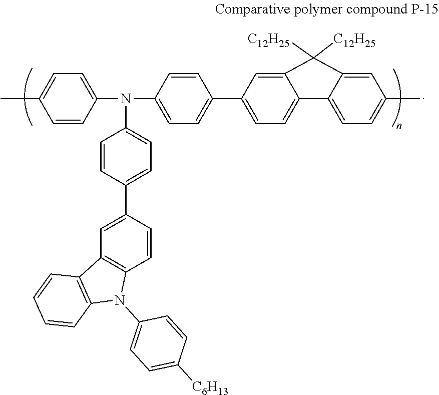

### Comparative Example 2

Comparative polymer compound P-16 was synthesized by the method described in Example 18 of Japanese Patent Laid-Open Publication No.: 2021-138915A for preparing Polymer Compound P-18.

Obtained comparative polymer compound P-16 had a weight average molecular weight (Mw) and polydispersity index (Mw/Mn) of 59,000 g/mol and 1.76, respectively.

Comparative polymer compound P-16 is considered to have the following structural unit from the composition of the monomers:

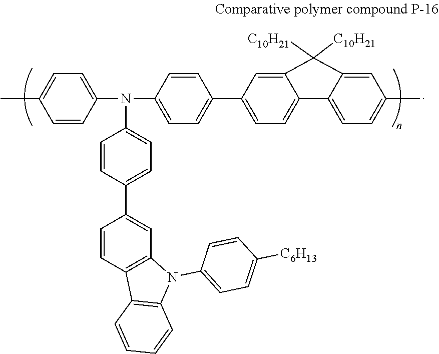

### Comparative Example 3

Comparative polymer compound P-17 was synthesized in the same manner as described for polymer compound 8 in Example 1 of Japanese Patent Laid-Open Publication No.: 2014-1349 A.

Obtained comparative polymer compound P-17 had a number average molecular weight (Mn) in terms of polystyrene standards of 3.42×10⁴ g/mol and the weight average molecular weight (Mw) in terms of polystyrene standards of 66.8×10⁴ g/mol.

Comparative polymer compound P-17 is considered to have the following structure and mole ratios among structural units thereof based on the monomers and their ratios used to prepare the polymer compound. The polymer compound is also assumed to have a structural unit (PA) and a structural unit (PB) that are alternately arranged.

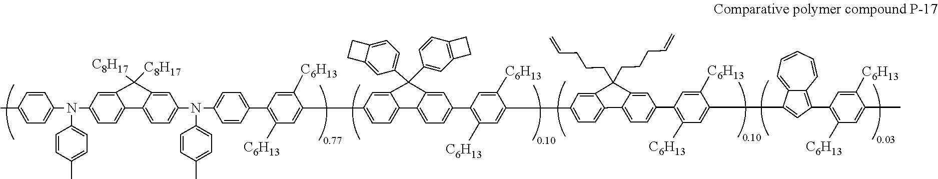

### Comparative Example 4

Poly [(9,9-dioctyl fluoren-2,7-diyl)-co-(4,4′-(N— (4-sec-butyl phenyl) diphenyl amine) having the following structural unit] (hereinafter, referred to be abbreviated as ‘TFB’) (manufactured by Luminescence Technology Corp.) was prepared in the same manner as Comparative polymer compound P-18 of Comparative Example 4.

The weight average molecular weight (Mw) and polydispersity index (Mw/Mn) of TFB were measured by SEC. The measured weight average molecular weight (Mw) and polydispersity index (Mw/Mn) of TFB were 359,000 g/mol and 3.4, respectively.

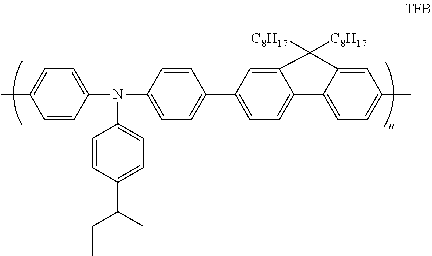

### Evaluation 1

### Evaluation of Properties of Polymer Compounds

Regarding polymer compounds of Examples 1 to 14, HOMO level (eV), LUMO level (eV), and glass transition temperature (T₉) (° C.) were measured by the following methods. The results are shown in Table 1.

### Measurement of HOMO Level

Each polymer compound was dissolved in xylene at a concentration of 1% by mass to prepare a coating solution.

Sample films (thickness of the formed film is about 70 nm) were prepared by coating the prepared coating solutions on glass substrates coated with UV-cleaned ITO by spin coating at a rotation speed of 2000 revolutions per minute (rpm), followed by drying on a hot plate by heating at 150° C. for 30 minutes.

The HOMO levels of the sample films were measured in air using a photoelectron spectroscopy device (AC-3, manufactured by Riken Keiki Co., Ltd.).

The intersection point of tangent to the rise was calculated from the measurement results, and set as the HOMO level (eV).

The HOMO level was usually a negative value.

### Measurement of LUMO Level

Each polymer compound was dissolved in toluene at a concentration of 3.2% by mass to prepare a coating solution.

Sample films (thickness of the formed film is about 70 nm) were prepared by coating the prepared coating solutions on glass substrates coated with UV-cleaned ITO by spin coating at a rotation speed of 1600 rpm, followed by drying on a hot plate by heating at 250° C. for 60 minutes.

The obtained sample film were cooled to 77K (−196° C.), and the photoluminescence (PL) spectrum is measured.

The LUMO level (eV) was calculated from the peak value in the side of the shortest wavelength region of the PL spectrum.

### Glass Transition Temperature (T₉)

Each polymer compound was heated to 300° C. at a temperature rise rate of 10° C./minute (min) and held for 10 minutes, then cooled to 25° C. at a temperature fall rate of 10° C./min and held for 10 minutes, and then heated to 300° C. at a temperature increase rate of 10° C./min, and measurement was performed with a differential scanning calorimeter (DSC) (Seiko instrument company, DSC6000). After the measurement, the polymer compound was cooled to room temperature (25° C.) at temperature fall rate of 10° C./min.

TABLE 1

| | Polymer | Mw | HOMO | LUMO | T_{g} |
|---|---|---|---|---|---|
| Example | Compound | (Mw/Mn) | (eV) | (eV) | ( ° C. ) |
| 1 | P-1 | 201,000 (2.3) | −5.40 | −2.58 | 127 |
| 2 | P-2 | 86,000 (2.3) | −5.53 | −2.70 | 136 |
| 3 | P-3 | 88,100 (2.1) | −5.40 | −2.56 | 102 |
| 4 | P-4 | 86,400 (2.2) | −5.42 | −2.58 | 102 |
| 5 | P-5 | 174,400 (1.7) | −5.51 | −2.69 | 134 |
| 6 | P-6 | 136,000 (1.9) | −5.43 | −2.59 | 107 |
| 7 | P-7 | 124,000 (1.7) | −5.54 | −2.69 | 132 |
| 8 | P-8 | 151,000 (2.8) | −5.46 | −2.62 | 101 |
| 9 | P-9 | 133,600 (2.9) | −5.46 | −2.63 | 107 |
| 10 | P-10 | 77,000 (2.5) | −5.52 | −2.67 | 131 |
| 11 | P-11 | 114,300 (2.5) | −5.52 | −2.71 | 71.3 |
| 12 | P-12 | 123,000 (5.38) | −5.58 | −2.72 | 84 |
| 13 | P-13 | 92,000 (1.8) | −5.53 | −2.69 | 117 |
| 14 | P-14 | 109,000 (1.7) | −5.59 | −2.74 | 118 |

### Evaluation 2

### Evaluation of Solvent Resistance 1 of Polymer Compounds

Regarding the polymer compounds of Examples 1 to 14 and Comparative Examples 1, 2, and 4, solvent resistance was assessed by the following method. The results are shown in Table 2.

A 1.0% by mass of toluene solution containing each polymer compound was applied by spin coating to a dry film having a thickness of 30 nm, and then heat treated at 200° C. for 60 minutes to form a thin film.

The UV absorption spectrum of each thin film was measured. Then, a solvent (xylene or cyclohexyl benzene) was applied to each thin film in a form of a thin film, and left for 20 minutes. Afterwards, the solvent (xylene or cyclohexyl benzene) was removed and the samples were dried at 150° C.

The UV spectrum of each thin film applied with each solvent and then dried was measured, and compared to the previously measured spectrum. Spectral intensity after processing was divided by the spectral intensity before processing, and if the value exceeded 95%, then the solvent resistance was evaluated as “o”, if the value was lower than 95%, then the solvent resistance evaluated as “X”.

TABLE 2

| | | Solvent | Solvent Resistance |
|---|---|---|---|
| | Polymer | Resistance Vs. | Vs. cyclohexyl |
| | Compound | xylene | benzene |
| Example 1 | P-1 | ◯ | ◯ |
| Example 2 | P-2 | ◯ | ◯ |
| Example 3 | P-3 | ◯ | ◯ |
| Example 4 | P-4 | ◯ | ◯ |
| Example 5 | P-5 | ◯ | ◯ |
| Example 6 | P-6 | ◯ | ◯ |
| Example 7 | P-7 | ◯ | ◯ |
| Example 8 | P-8 | ◯ | ◯ |
| Example 9 | P-9 | ◯ | ◯ |
| Example 10 | P-10 | ◯ | ◯ |
| Example 11 | P-11 | ◯ | ◯ |
| Example 12 | P-12 | ◯ | ◯ |
| Examples 13 | P-13 | ◯ | ◯ |
| Example 14 | P-14 | ◯ | ◯ |
| Comparative | P-15 | X | X |
| Example 1 | | | |
| Comparative | P-16 | X | X |
| Example 2 | | | |
| Comparative | TFB | X | X |
| Example 4 | | | |

From the results of Table 2, the polymer compounds according to some embodiments have high solvent resistance for xylene and cyclohexyl benzene. Therefore, even if a light emitting layer (e.g., a light-emitting layer containing quantum dots) was formed by a wet process, for example a solution coating method, such as, an inkjet method, on a hole transport layer or a hole injection layer containing the polymer compound according to some embodiments, membrane mixing between the layer that contains the polymer compound and the light emitting layer may be suppressed.

### Evaluation of Solvent Resistance 2 of Polymer Compounds

Regarding the polymer compounds of Examples 1, 4, 5, 8, 10, 11, 12, and Comparative Examples 1 and 3, solvent resistance was assessed by the following method. The results are shown in Table 3.

Each polymer compound was dissolved in xylene (a solvent) at a concentration of 1 mass % to form a coating solution. The coating solution was applied on a quartz substrate by spin coating, and then dried at 140° C. for 30 minutes to form a dry film with a thickness of 25 nm. The absorption spectrum of the film (before immersion in a solvent) was measured by an ultraviolet-visible spectroscopy photometer (Shimadzu Works Co., Ltd., UV-1800). The peak wavelength in the side of the longest wavelength region of the absorption spectrum was measured as a reference wavelength.

Subsequently, the same film on the quartz substrate was immersed in a solvent described in Table 3 (cyclohexylbenzene, at 25° C.) for 20 minutes, and was then removed from the solvent to be dried at 140° C. for 30 minutes. Then, the absorption spectrum of the dried film (after solvent immersion) was measured in the same manner as above with the ultraviolet-visible spectroscopy photometer.

Regarding the absorption spectra, the ratio (%) of the spectral intensity of the reference wavelength of the absorption spectrum after immersion in solvent with respect to the spectral intensity of the reference wavelength of the absorption spectrum before immersion in solvent {(i.e., “spectral intensity of the reference wavelength of the absorption spectrum after immersion in solvent”/“spectral intensity of the reference wavelength of the absorption spectrum before immersion in solvent)×100} is defined as solvent resistance value (%).

Further, the solvent resistance was evaluated according to the following criteria:
A: Solvent Resistance value over 90%,
B: Solvent Resistance value greater than or equal to 75%, and less than 90%,
C: Solvent Resistance value less than 75%.

Solvent resistance is preferably evaluation result A or B, and A is more preferable. In the case of these evaluations, even if a layer is formed by a wet method on a layer containing a polymer compound, membrane mixing between the two layers would be further inhibited.

TABLE 3

| | polymer | Solvent Resistance Vs. |
|---|---|---|
| | compound | cyclohexyl benzene |
| Example 1 | P-1 | A |
| Example 4 | P-4 | A |
| Example 5 | P-5 | A |
| Example 8 | P-8 | A |
| Example 10 | P-10 | A |
| Example 11 | P-11 | A |
| Example 12 | P-12 | A |
| Comparative Example 1 | P-15 | C |
| Comparative Example 3 | P-17 | A |

### Example 15

An ITO-coated glass substrate was used as a first electrode (anode), in which indium tin oxide (ITO) was patterned to a film of 150 nm on the glass substrate. The ITO-coated glass substrate was sequentially cleaned with a neutral detergent, deionized water, water, and isopropyl alcohol, and then subjected to a UV-ozone treatment. Then, poly (3,4-ethylenedioxythiophene)/poly (4-styrene sulfonate) (PEDOT/PSS) (manufactured by Sigma-Aldrich) was applied on the ITO-coated glass substrate by spin coating, and dried, to provide a dry film with a thickness of 30 nm. As a result, a hole injection layer with a thickness (dry film thickness) of 30 nm was formed on the ITO-attached glass substrate.

A coating solution containing polymer compound P-1 according to Example 1 at a concentration of 1.0% by mass in toluene (hole transport material) was applied on the hole injection layer by spin coating, and was then heat treated at 230° C. for 60 minutes, to provide a dry film with a thickness of 30 nm, as a hole transport layer. As a result, a hole transport layer with a thickness (dry film thickness) of 30 nm was formed on the hole injection layer.

Core/shell type blue light-emitting quantum dots with a ZnTeSe/ZnSe/ZnS (core/shell/shell; average diameter of about 10 nm) structure were dispersed in cyclohexane at a concentration of 1.0 mass % to provide a quantum dot dispersion.

The hole transport layer (e.g., polymer compound P-1) was not soluble in cyclohexane.

The quantum dot dispersion was spin-coated on the hole transport layer, and then dried, to provide a dry film with a thickness of 30 nm. As a result, a quantum dot light-emitting layer with a thickness (dry film thickness) of 30 nm was formed on the hole transport layer.

Meanwhile, the light emitted from the quantum dot dispersion by irradiating ultraviolet light to the dispersion had a centered wavelength of 462 nm and a full width at half maximum of 30 nm.

The quantum dot emitting layer was completely dried. Then, lithium quinolate (Liq), and 1,3,5-tris(N-phenylbenzimidazol-2-yl) benzene (TPBI) (Sigma) as an electron transport material were co-deposited on the quantum dot emitting layer with a vacuum deposition device (Sigma-Aldrich). As a result, an electron transport layer with a thickness of 36 nm was formed on the quantum dot emitting layer.

Using a vacuum deposition device, 8-hydroxyquinolinolatolithium (lithium 8-quinolate) (Liq) was deposited on the electron transport layer. As a result, an electron injection layer with a thickness of 0.5 nm was formed on the electron transport layer.

Aluminum (Al) was deposited on the electron injection layer with the vacuum deposition device. As a result, a second electrode (cathode) with a thickness of 100 nm was formed on the electron injection layer.

Accordingly, quantum dot electroluminescence device 1 was obtained.

### Examples 16 to 28

Quantum dot electroluminescence devices 2 to 14 were produced in the same manner as in Example 15, except that polymer compounds P-2 to P-14 according to Examples 2 to 14 were used instead of Polymer compound P-1 in Example 15.

### Comparative Examples 5 to 8

Comparative quantum dot electroluminescence devices 1 to 4 were produced in the same manner as in Example 15, except that comparative polymer compounds P-15 to P-18 according to Comparative Examples 1 to 4 were used instead of Polymer compound P-1 in Example 15.

### Evaluation 3

### Evaluation of Device Performances of Polymer Compounds

Luminous efficiency and luminous lifetime were evaluated by the following method for the quantum dot electroluminescence devices 1, 4, 5, 8, 10, 11, and 12 manufactured in Examples 15, 18, 19, 22, 24, 25, and 26, and comparative quantum dot electroluminescence device 7 manufactured in Comparative Example 7. The results are shown in Table 4.

### Luminous Efficiency

When a potential is applied to each quantum dot electroluminescence device, current begins to flow, and the quantum dot electroluminescence device emits light at a certain voltage. For each device, while gradually increasing voltage by using a direct current constant voltage power supply (made by KEYENCE, source meter), the current was measured, and luminance of emitted light was measured by a luminance measuring device (SR-3, manufactured by Topcom). Here, the measurement ends when the luminance begins to decline.

The current value (i.e., current density) per area was calculated from the area of each device, and the current efficiency (candela per ampere, cd/A) was obtained by dividing the luminance (candela per square meter, cd/m²) by the current density (ampere per square meter, A/m²).

The highest current efficiency in the measured voltage range in Table 4 below is set as “cd/Aₘₐₓ”.

Current efficiency indicates the efficiency of converting current into luminous energy (conversion efficiency), and the higher the current efficiency, the higher the device performance.

Also, the luminous efficiency was evaluated from the radiation luminance spectrum measured by a luminance measuring device, assuming Lambertian radiation, by calculating the external quantum efficiency (EQE) (%) at cd/Aₘₐₓ.

The luminous efficiency of each quantum dot electroluminescence device is expressed as a relative value with respect to 100 of comparative quantum dot electroluminescence device 3 according to Comparative Example 7, in Table 4.

In addition, when a potential is applied to each quantum dot electroluminescence device by a direct current constant voltage power supply (made by KEYENCE, source meter), current begins to flow at a certain voltage, and the quantum dot electroluminescence device emits light. While measuring luminance of each device by a luminance measuring device (SR-3, manufactured by Topcom), current was gradually increased until when the luminance reaches 1000 nit (cd/m²), from which the current is maintained constant and placed. Here, the voltage at 1000 nit is taken as “V@1000 nit”.

### Luminescence Lifetime

A predetermined potential was applied to each quantum dot electroluminescence device by a direct current constant voltage power supply (made by KEYENCE, source meter), and the quantum dot electroluminescence device emits light. While measuring luminance of each device by a luminance measuring device (SR-3, manufactured by Topcom), current was gradually increased until the luminance reached 650 nit (cd/m²), where the current was set and maintained constant. The luminance value measured by the luminance measurement device gradually decreased, and reached 50% of the initial luminance. The time to the point of reaching 50% of the initial luminance was set as “LT50 (hr)”.

The device lifespan of the quantum dot electroluminescence device was expressed as a relative value with respect to 100 of LT50 (hr) of comparative quantum dot electroluminescence device 3 according to Comparative Example 7, in Table 4.

TABLE 4

| | | Device Performance | |
|---|---|---|---|
| | | | Device |
| | Polymer | Luminous | Lifespan |
| | Compound | efficiency | (Durability) |
| Example 15 | P-1 | 188 | 211 |
| Example 18 | P-4 | 150 | 383 |
| Example 19 | P-5 | 150 | 233 |
| Example 22 | P-8 | 190 | 258 |
| Example 24 | P-10 | 202 | 231 |
| Example 25 | P-11 | 142 | 311 |
| Example 26 | P-12 | 179 | 231 |
| Comparative | P-17 | 100 | 100 |
| Example 7 | | | |

### Reference Examples

Quantum dot electroluminescence devices A to C were produced in the same manner as in Example 15, except that polymer compounds A to C were used instead of Polymer compound P-1 in Example 15.

Then, luminous efficiency and device lifespan were measured for each of the obtained quantum dot electroluminescence devices A to C in the same manner as Evaluation 3, and the results are shown in Tables 5 to 7.

Meanwhile, the device lifespan of each quantum dot electroluminescence device is expressed as a relative value with respect to 100 of LT50 (hr) of each quantum dot electroluminescence device manufactured by using a polymer compound having ‘n’ of 10, in Tables 5 to 7. Further, the luminous efficiency of each quantum dot electroluminescence device is expressed as a relative value with respect to 100 of comparative quantum dot electroluminescence device 3 according to Comparative Example 7, in Tables 5 to 7.

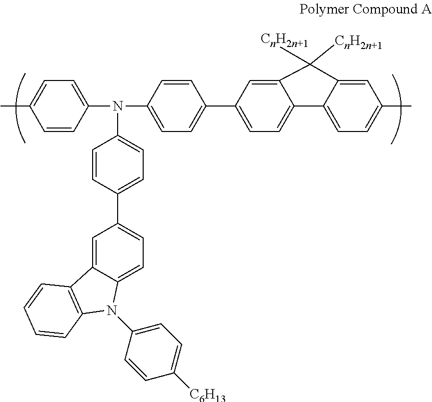

TABLE 5

| n in polymer | Device Performance | |
|---|---|---|
| compound | Luminous | Device Lifespan |
| A | efficiency | (Durability) |
| 6 | 73 | 92 |
| 10 | 60 | 100 |
| 12 | 67 | 127 |

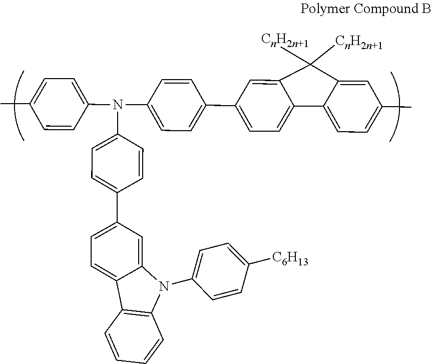

TABLE 6

| n in Polymer | Device Performance | |
|---|---|---|
| compound | Luminous | Device Lifespan |
| B | efficiency | (Durability) |
| 8 | 105 | — |
| 10 | 100 | 100 |
| 12 | 96 | 110 |

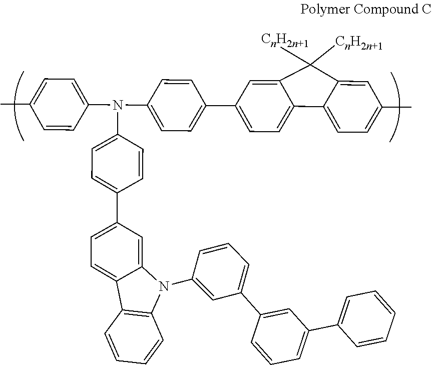

TABLE 7

| n in Polymer | Device Performance | |
|---|---|---|
| Compound | Luminous | Device Lifespan |
| C | efficiency | (Durability) |
| 8 | 83 | 79 |
| 10 | 80 | 100 |
| 12 | 95 | 136 |

From the results in tables 5 to 7, it is shown that durability is significantly improved when the number of carbon atoms of the alkyl group substituted to the fluorene moiety in each polymer compound is 10 or more.

Although polymer compounds A to C have different structures from the polymer compounds according to some embodiments, the same result is expected to be obtained when Ar⁷ in the structural unit (D) is a fluorene-derived group.

While this invention has been described in connection with what is presently considered to be practical example embodiments, it is to be understood that the invention is not limited to the disclosed embodiments. On the contrary, it is intended to cover various modifications and equivalent arrangements included within the spirit and scope of the appended claims.

### EXPLANATION OF SYMBOLS

100 . . . Electroluminescence device (EL element),
110 . . . substrate
120 . . . first electrode,
130 . . . hole injection layer,
140 . . . hole transport layer,
150 . . . light-emitting layer,
160 . . . electron transport layer,
170 . . . electron injection layer,
180 . . . second electrode

What is claimed is:

1. A polymer compound comprising a structural unit represented by formula (1), and at least one of structural units represented by formula (2) to formula (4): 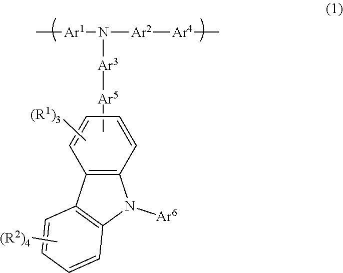
where in formula (1),
Ar¹ and Ar² are, each independently, a substituted or unsubstituted aromatic hydrocarbon group having 6 to 60 carbon atoms,
Ar³ is a substituted or unsubstituted aromatic hydrocarbon group having 6 to 120 carbon atoms,
Ar⁴ is a substituted or unsubstituted aromatic hydrocarbon group having 6 to 60 carbon atoms, or a substituted or unsubstituted aromatic heterocyclic group having 3 to 60 ring-forming atoms,
Ar⁵ is a single bond or a substituted or unsubstituted aromatic heterocyclic group having 3 to 60 ring-forming atoms,
Ar⁶ is a substituted or unsubstituted aromatic hydrocarbon group having 6 to 60 carbon atoms, or a substituted or unsubstituted aromatic heterocyclic group having 3 to 60 ring-forming atoms,
R¹ is a hydrogen atom, an alkyl group, a hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN), and
R² is a hydrogen atom, an alkyl group, an hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN); 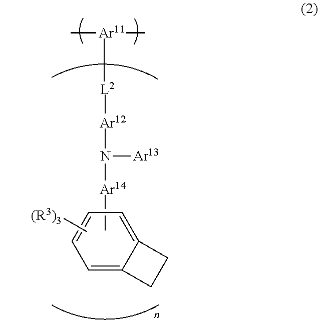
where in formula (2),
Ar¹¹ is a substituted or unsubstituted aromatic hydrocarbon group having 6 to 60 carbon atoms, or a substituted or unsubstituted aromatic heterocyclic group having 3 to 60 ring-forming atoms,
L² is a single bond or a saturated hydrocarbon group having 2 to 60 carbon atoms,
Ar¹² is a substituted or unsubstituted aromatic hydrocarbon group having 6 to 60 carbon atoms, or a substituted or unsubstituted aromatic heterocyclic group with 3 to 60 ring-forming atoms,
Ar¹³ is a substituted or unsubstituted aromatic hydrocarbon group having 6 to 60 carbon atoms, or a substituted or unsubstituted aromatic heterocyclic group having 3 to 60 ring-forming atoms,
Ar¹⁴ is a single bond, a substituted or unsubstituted aromatic hydrocarbon group having 6 to 60 carbon atoms, or a substituted or unsubstituted aromatic heterocyclic group having 3 to 60 ring-forming atoms,
R³ is a hydrogen atom, an alkyl group, an hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN), wherein R³ optionally forms a ring with another R³ or with a carbon atom in a benzene ring to which R³ is bonded, and
n is 1 or 2; 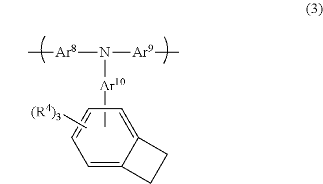
where in formula (3),
Ar⁸ and Ar⁹ are, each independently, a substituted or unsubstituted aromatic hydrocarbon group having 6 to 60 carbon atoms,
Ar¹⁰ is a single bond, a substituted or unsubstituted aromatic hydrocarbon group having 6 to 60 carbon atoms, or a substituted or unsubstituted aromatic heterocyclic group having 3 to 60 ring-forming atoms, and
R⁴ is a hydrogen atom, an alkyl group, a hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN), wherein R⁴ optionally forms a ring with another R⁴ or with a carbon atom in a benzene ring to which R⁴ is bonded; 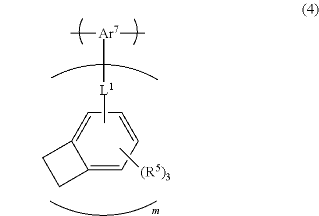
where in formula (4),
Ar⁷ is a substituted or unsubstituted aromatic hydrocarbon group having 6 to 60 ring atoms, or a substituted or unsubstituted aromatic heterocyclic group having 3 to 60 ring-forming atoms,
L¹ is a single bond or a saturated hydrocarbon group having 2 to 60 carbon atoms,
R⁵ is a hydrogen atom, an alkyl group, a hydroxyalkyl group, an alkoxygroup, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN), wherein R⁵ optionally forms a ring with another R⁵ or with a carbon atom in a benzene ring to which R⁵ is bonded, and
m is 1 or 2.

2. The polymer compound of claim 1, wherein the polymer compound comprises a structural unit represented by formula (1), and a structural unit represented by formula (2),
wherein in formula (2),
Ar¹¹ is a substituted or unsubstituted aromatic hydrocarbon group having 6 to 20 carbon atoms,
L² is a single bond, or a straight-chain or branched saturated hydrocarbon group having 4 to 12 carbon atoms,
Ar¹² is a substituted or unsubstituted aromatic hydrocarbon group having 6 to 20 carbon atoms,
Ar¹³ is a substituted or unsubstituted aromatic hydrocarbon group having 6 to 20 carbon atoms,
Ar¹⁴ is a single bond or a substituted or unsubstituted aromatic hydrocarbon group having 6 to 20 carbon atoms,
R³ is a hydrogen atom, an alkyl group, or an alkenyl group, wherein R³ optionally forms a ring with another R³ or with a carbon atom in a benzene ring to which R³ is bonded, and
n is 1 or 2.

3. The polymer compound of claim 1, wherein the polymer compound comprises a structural unit represented by formula (1), and a structural unit represented by formula (5) below: 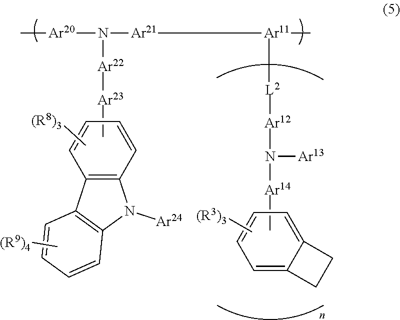
wherein in formula (5),
Ar¹¹, L², Ar¹², Ar¹³, Ar¹⁴, R³, and n are the same as defined in formula (2),
Ar²⁰ and Ar²¹ are, each independently, a substituted or unsubstituted aromatic hydrocarbon group having 6 to 60 carbon atoms,
Ar²² is a substituted or unsubstituted aromatic hydrocarbon group having 6 to 120 carbon atoms,
Ar²³ is a single bond, or a substituted or unsubstituted aromatic heterocyclic ring group having 3 to 60 ring-forming atoms,
Ar²⁴ is a substituted or unsubstituted aromatic hydrocarbon group having 6 to 60 carbon atoms, or a substituted or unsubstituted aromatic heterocyclic ring group having 3 to 60 ring-forming atoms,
R⁸ is a hydrogen atom, an alkyl group, a hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN),
R⁹ is a hydrogen atom, an alkyl group, a hydroxyalkyl group, an alkoxy group, an alkoxyalkyl group, an alkenyl group, an alkynyl group, an alkyl thio group, an alkoxy carbonyl group, a hydroxyl group (—OH), a carboxyl group (—COOH), a thiol group (—SH), or a cyano group (—CN).

4. The polymer compound of claim 1, wherein the polymer compound comprises a structural unit represented by formula (1), and a structural unit represented by formula (3),
wherein in formula (3), at least one of Ar⁸ or Ar⁹ comprises an aromatic hydrocarbon group having 6 to 60 carbon atoms, wherein the aromatic hydrocarbon group is substituted with an alkyl group having 9 to 60 carbon atoms.

5. The polymer compound of claim 1, wherein the polymer compound comprises a structural unit represented by formula (1), a structural unit represented by formula (3), and a structural unit represented by formula (6) below: 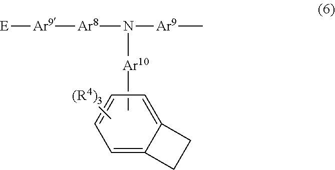
wherein in formula (6),
Ar⁸ to Ar¹⁰, and R⁴ are the same as defined in formula (3),
Ar^{9′} is a substituted or unsubstituted aromatic hydrocarbon group having 6 to 60 carbon atoms, and
E is a substituted or unsubstituted aromatic hydrocarbon group having 6 to 60 carbon atoms.

6. The polymer compound of claim 1, wherein the polymer compound comprises a structural unit represented by formula (1), and a structural unit represented by formula (7) below: 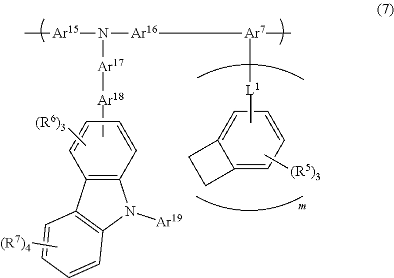
wherein in formula (7),
L¹, R⁵, and m are the same as defined in formula (4),
Ar⁷ is selected from Group (II) below: 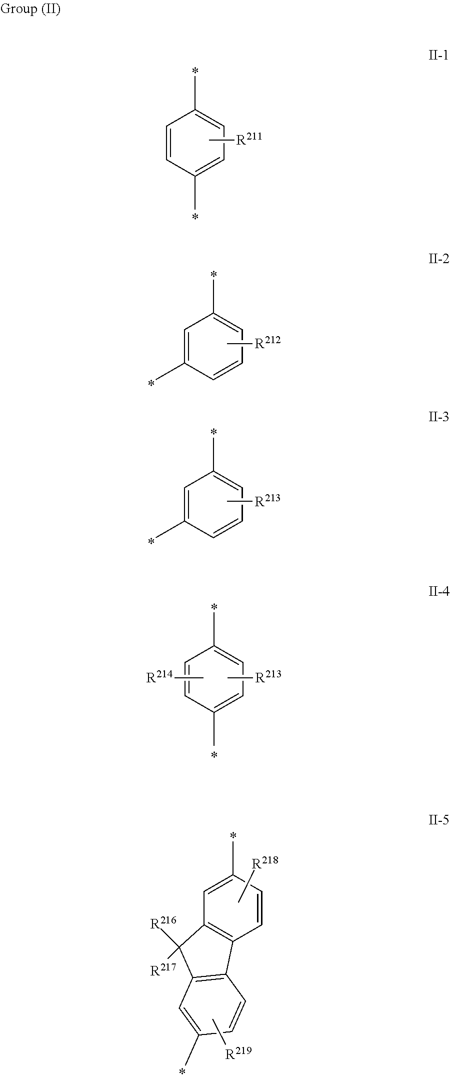 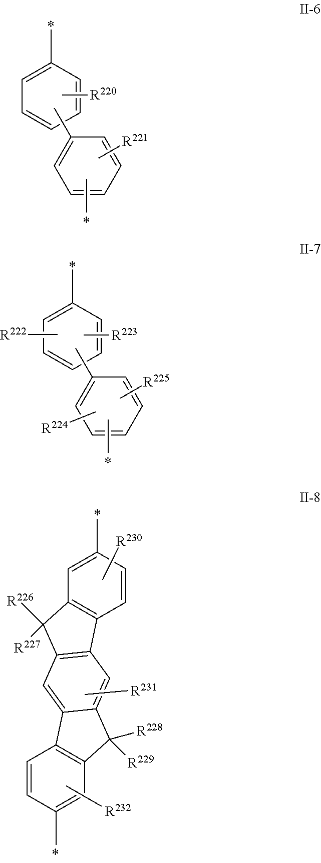
wherein in Group (II),
R²¹¹ to R²³² are, each independently, a hydrogen atom, a straight-chain or branched hydrocarbon group having 1 to 18 carbon atoms, or a group represented by formula (4′) below, and,
* indicates a bonding position with an adjacent atom: 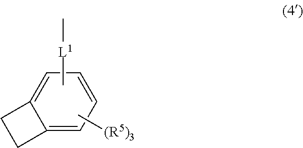
wherein in formula (4′),
L¹ and R⁵ are the same as in formula (4);
Ar¹⁵ and Ar¹⁶ are, each independently, a substituted or unsubstituted aromatic hydrocarbon group having 6 to 60 carbon atoms,
Ar¹⁷ is a substituted or unsubstituted aromatic hydrocarbon group having 6 to 120 carbon atoms,
Ar¹⁸ is a single bond, or a substituted or unsubstituted aromatic heterocyclic ring having 3 to 60 ring-forming atoms,
Ar¹⁹ is a substituted or unsubstituted aromatic hydrocarbon group having 6 to 60 carbon atoms, or a substituted or unsubstituted aromatic heterocyclic ring group having 3 to 60 ring-forming atoms,
R⁶ is a hydrogen atom, an alkyl group, a hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN), and
R⁷ is a hydrogen atom, an alkyl group, a hydroxyalkyl group, an alkoxy group, an alkoxyalkyl group, an alkenyl group, an alkynyl group, an alkylthio group, an alkoxycarbonyl group, a hydroxyl group (—OH), a carboxyl group (—COOH), a thiol group (—SH), or a cyano group (—CN).

7. The polymer compound of claim 1, wherein Ar³ in formula (1) is selected from group (I) below: 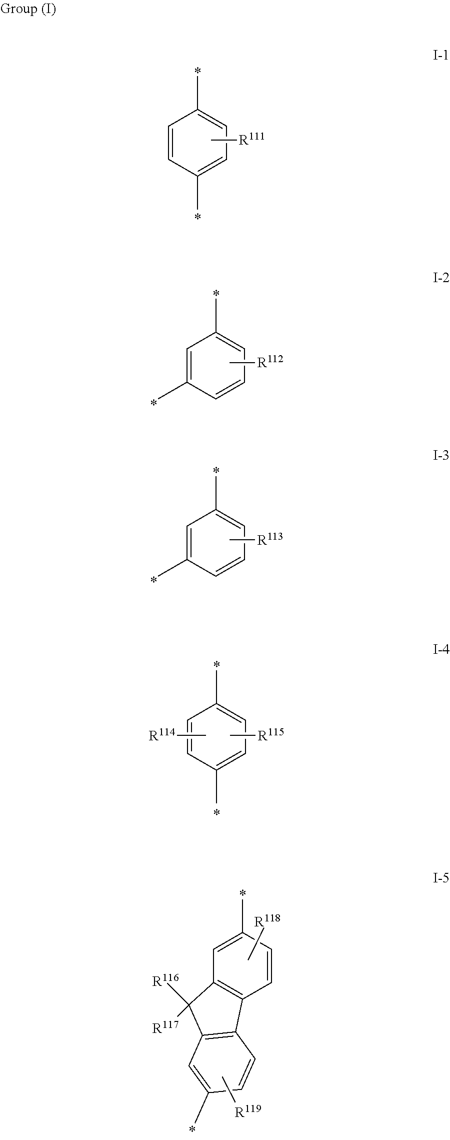 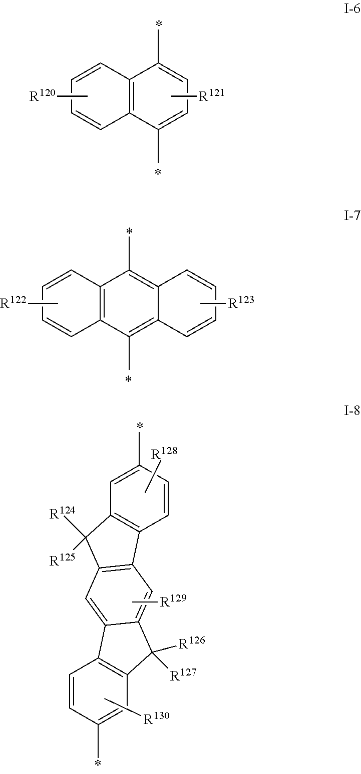
wherein in Group (1),
R¹¹¹ to R¹³⁰ are, each independently, a hydrogen atom, or a straight-chain or branched hydrocarbon group having 1 to 18 carbon atoms, and
* indicates a bonding position with an adjacent atom.

8. The polymer compound of claim 1, wherein Ar¹, Ar², and Ar⁴ in formula (1) are, each independently, selected from Group (II′) below: 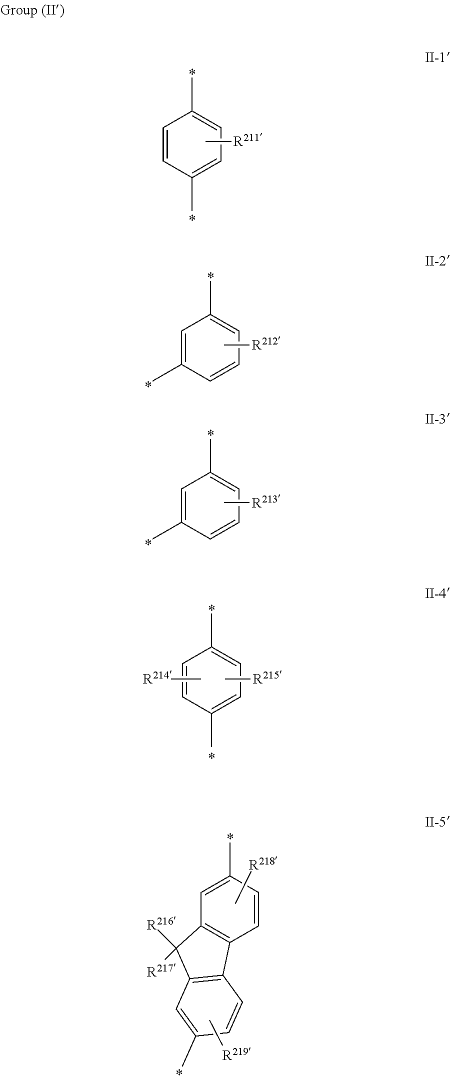 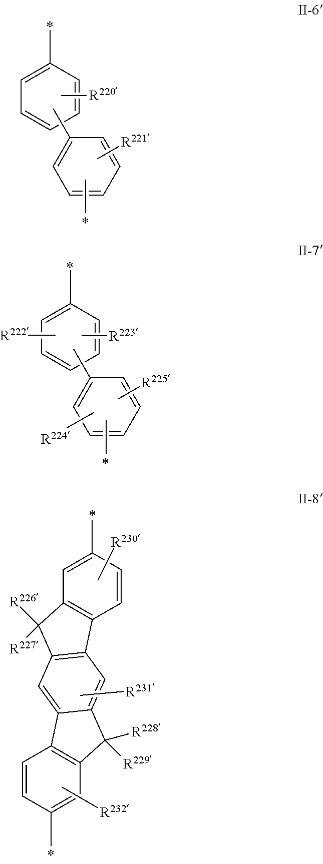
wherein in Group (II′),
R^{211′} to R^{232′} are, each independently, a hydrogen atom, or a straight-chain or branched hydrocarbon group having 1 to 18 carbon atoms, and
* indicates a bonding position with an adjacent atom.

9. The polymer compound of claim 1, wherein Ar⁶ in formula (1) is selected from Group (III) below: 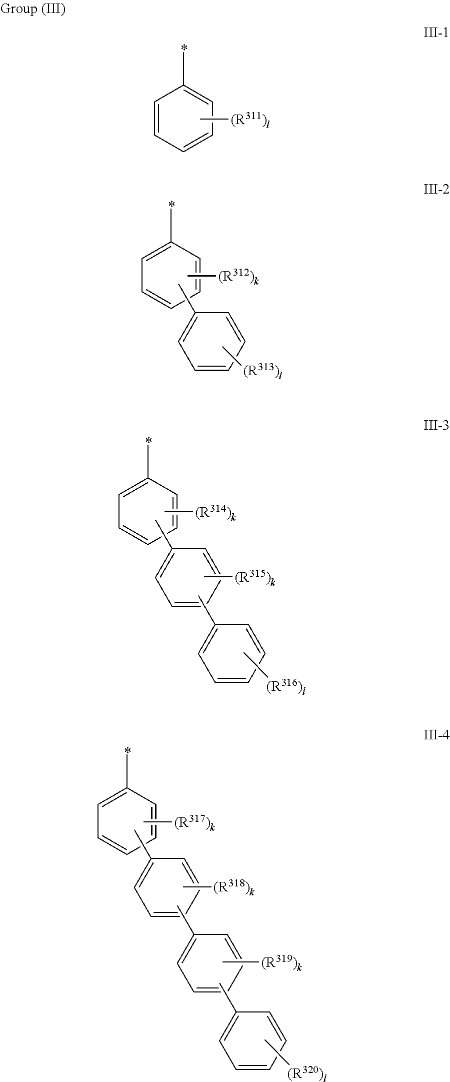 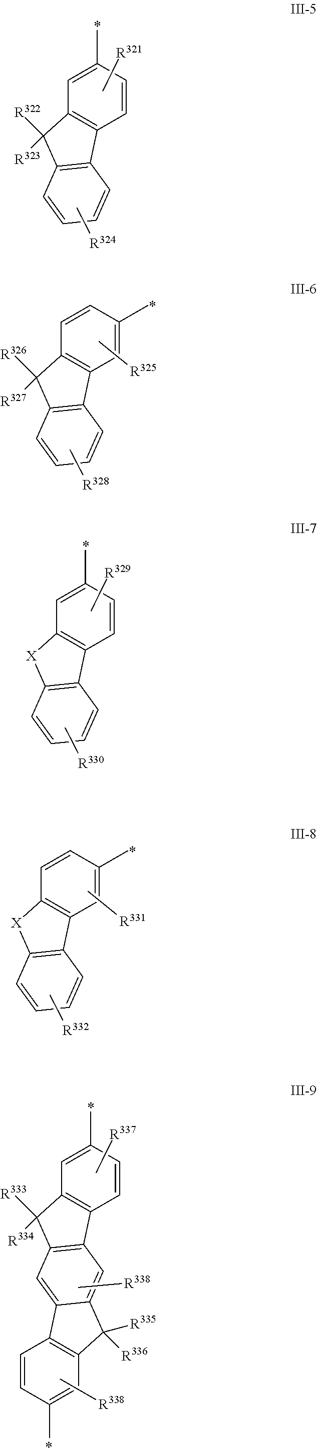
wherein in Group (III),
R³¹¹ to R³³⁹ are, each independently, a hydrogen atom, or a straight-chain or branched hydrocarbon group having 1 to 18 carbon atoms,
X indicates oxygen atom or sulfur atom, and
* indicates a bonding position with an adjacent atom.

10. The polymer compound of claim 1, wherein Ar⁴ in formula (1) is represented by formula (a) or formula (b): 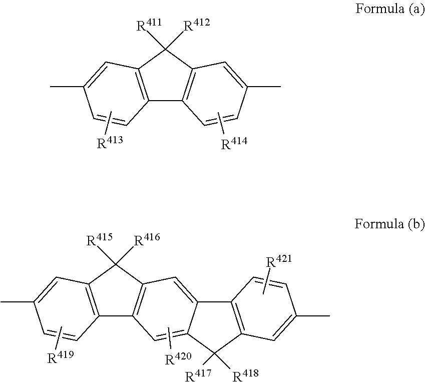
wherein in formula (a) and formula (b),
R⁴¹¹, R⁴¹², and R⁴¹⁵ to R⁴¹⁸ are, each independently, a hydrogen atom, or a hydrocarbon group having 1 to 30 carbon atoms, provided that one or more of R⁴¹¹ and R⁴¹², and one or more of R⁴¹⁵ to R⁴¹⁸, are, each independently, a straight-chain or branched alkyl group having 8 to 30 carbon atoms, and
R⁴¹³, R⁴¹⁴, and R⁴¹⁹ to R⁴²¹ are, each independently, a hydrogen atom, or a hydrocarbon group having 1 to 30 carbon atoms.

11. A composition comprising the polymer compound of claim 1, and a material comprising a hole transport material, an electron transport material, a luminescent material, or a combination thereof.

12. The composition of claim 11, wherein the luminescent material comprises an organic metal complex.

13. The composition of claim 11, wherein the luminescent material comprises semiconductor nanoparticles.

14. An organic film comprising the polymer compound of claim 1.

15. An electroluminescence device comprising a first electrode, a second electrode, and an organic film disposed between the first electrode and the second electrode,
wherein the organic film comprises one or more layers, and
wherein at least one of the one or more layers of the organic film comprises the polymer compound of claim 1.

16. The electroluminescence device of claim 15, wherein the at least one of the one or more layers of the organic film comprising the polymer compound is a hole transport layer or a hole injection layer.

17. The electroluminescence device of claim 15, wherein the organic film comprises two or more layers, and wherein at least one of the two or more layers of the organic film further comprises a light-emitting layer comprising semiconductor nanoparticles or organic metal complex.

18. A method of manufacturing an electroluminescence device comprising a first electrode, a second electrode, and an organic film disposed between the first electrode and the second electrode and comprising one or more layers, wherein the method comprising:
forming at least one of the one or more layers of the organic film by coating a solution comprising the polymer compound of claim 1 and a solvent to a layer adjacent to the at least one of the one or more layers of the organic film to form a coated layer, and removing the solvent from the coated layer.
